(19) United States
(12) Patent Application Publication
(10) Pub. No.: US 2026/0328809 A1
(43) Pub. Date: Oct. 22, 2026

(54) PROBE PIN, PROBE CARD COMPRISING PROBE PIN, AND METHODS FOR MANUFACTURING SAME

(71) Applicant: AMST CO., LTD., Suwon-si (KR)

(72) Inventors: Byung Chang SONG, Suwon-si (KR); Dong Il KIM, Seongnam-si (KR); Yun Hee SHIM, Suwon-si (KR); Soo Ho CHO, Hwaseong-si (KR)

(73) Assignee: AMST CO., LTD., Suwon-si (KR)

(21) Appl. No.: 19/123,012

(22) PCT Filed: Oct. 12, 2023
(86) PCT No.: PCT/KR2023/015749

§ 371 Date: Apr. 21, 2025

(30) Foreign Application Priority Data
Oct. 20, 2022 (KR) 10-2022-0135974

(51) Int. Cl. G01R 1/067; G01R 1/073; G01R 3/00; G01R 31/28

(52) U.S. Cl. CPC G01R 1/06733; G01R 1/06716; G01R 1/06761; G01R 1/07314; G01R 3/00; G01R 31/2886

(57) ABSTRACT

According to the present invention, the flexibility of a probe pin is adjusted by providing a vertical slit and/or a horizontal slit, thereby facilitating elastic deformation. In addition, according to the present invention, the sectional area of the probe pin is adjusted, thereby improving high-frequency signal characteristics thereof. In addition, according to the present invention, a probe pin can be easily inserted into upper and lower plates by using multiple spacing bodies which are spaced apart by a vertical slit and/or a horizontal slit, and the inserted probe pin is prevented from detaching.

### TECHNICAL FIELD

The present invention relates to a probe pin, a probe card comprising the probe pin, and a method for manufacturing the same, and more specifically, to a probe pin with flexibility controlled through a slit structure, a probe card comprising the probe pin, and a method for manufacturing the same.

### BACKGROUND

A probe card is equipment used to verify the characteristics of semiconductor devices at the wafer level before cutting for individual package production after manufacturing semiconductor wafer devices. The probe card comprises probe pins to input electrical signals and detect defects in the semiconductor devices based on the results.

The probe card is configured by comprising a plurality of probe pins. The probe pins contact the electrode pads of the semiconductor devices, and the contacted probe pins apply a certain pressure to the semiconductor devices. This process of contacting the probe pins to the electrode pads and applying pressure to the electrode pads is referred to as overdrive.

The probe pins are composed of materials capable of elastic deformation, thereby preventing damage to the probe pins and the semiconductor devices. To prevent damage to the semiconductor devices, various methods of adjusting the flexibility of the probe pins themselves have been attempted.

In this regard, prior art document registration number 10-1082459 discloses an “electrical contact element,” wherein the prior art document describes that the electrical contact element comprises a vertically oriented slot in the longitudinal direction penetrating the probe pin.

However, since the “electrical contact element” comprises one or more vertically oriented slots, it has the problem of increasing width in the direction where multiple vertically oriented slots are arranged. This limitation is evident in the current situation where the electrode pads are being miniaturized with narrower pitches due to the miniaturization of semiconductor devices.

### PRIOR ART DOCUMENTS

### Patent Documents

(Patent Document 1) Registration Number 10-1082459 Registered Patent Gazette

### SUMMARY

### Disclosure

### Technical Problem

To solve the aforementioned problems, the present invention aims to provide a probe pin and a method for manufacturing the probe pin, which utilize various forms of vertical slits and/or horizontal slits to adjust flexibility, thereby facilitating elastic deformation, implementing fine pitch of electrode pads, and maintaining excellent high-frequency signal characteristics by adjusting the cross-sectional area.

Additionally, the present invention aims to provide a probe pin and a method for manufacturing the probe pin, which utilize a plurality of separated bodies spaced apart by vertical slits and horizontal slits to reduce the skin effect even in high-frequency signals, thereby increasing the current-carrying capacity.

Furthermore, the present invention aims to provide a probe card comprising a probe pin, which utilizes a plurality of separated bodies spaced apart by vertical slits and/or horizontal slits to facilitate the insertion of the probe pin into the upper plate and lower plate and prevent its separation.

### Means for Solving the Problem

To achieve the aforementioned objectives, a probe pin according to an embodiment of the present invention comprises a body extending in one direction; and a slit formed by penetrating a part of the body; wherein the body comprises a first body constituting one side of the body, a second body extending from the first body and constituting a middle portion of the body, and a third body extending from the second body and constituting the other side of the body, and the slit may comprise a vertical slit formed in a vertical direction by penetrating a horizontal plane of the body, and a horizontal slit formed in a horizontal direction by penetrating a vertical plane of the body.

In addition, at least one of the vertical slit and the horizontal slit may be formed in the second body.

In addition, at least one of the vertical slit and the horizontal slit may extend from the second body to the end of the first body, and one side of the first body may be open.

In addition, the vertical slit and the horizontal slit may intersect each other.

In addition, the body may comprise a first separated body, a second separated body, a third separated body, and a fourth separated body, which are spaced apart from each other by the vertical slit and the horizontal slit, and at least one of the first separated body to the fourth separated body may comprise an over-spaced portion curved in a direction in which a separation distance from at least one of the others excluding the at least one increases, and the over-spaced portion may contact an upper plate into which the body is inserted to prevent separation of the body.

In addition, the body may comprise a first separated body, a second separated body, a third separated body, and a fourth separated body, which are spaced apart from each other by the vertical slit and the horizontal slit, and may further comprise a tie portion connecting an inner surface of the first separated body and an inner surface of at least one of the second separated body to the fourth separated body; and a recessed portion formed by being recessed in at least one of an outer surface facing the inner surface of the first separated body to which the tie portion is connected and an outer surface facing the inner surface of the at least one.

In addition, at least one of the vertical slit and the horizontal slit may be provided in plurality.

In addition, the vertical slit and the horizontal slit may have different widths or lengths.

In addition, the probe pin may further comprise a contact tip located in an end region of the third body and contacting an object to be inspected.

In addition, the contact tip may be made of a material different from that of the body.

In addition, the contact tip may comprise a rhodium layer composed of a material containing rhodium.

In addition, the contact tip may further comprise a protective layer located on the rhodium layer and composed of a material having a lower hardness than rhodium.

In addition, the thickness of the contact tip may be greater than the thickness of the horizontal slit.

In addition, the horizontal slit and the contact tip may be located at different heights and may not form an overlapping region.

In addition, the body may comprise a first separated body, a second separated body, a third separated body, and a fourth separated body, which are spaced apart from each other by the vertical slit and the horizontal slit, and may further comprise an insulating layer such that at least one of the first to fourth separated bodies is insulated from the others excluding the at least one, and the insulating layer may be formed on an inner surface of the at least one facing the others and may extend from the first body to the third body.

In addition, at least one of the first separated body to the fourth separated body may be curved or provided with a protrusion to serve as a ground pin and to be connected to a ground wire.

In addition, a probe pin according to an embodiment of the present invention may comprise a body extending in one direction; a vertical slit formed in a vertical direction by penetrating a horizontal plane of the body; a horizontal slit formed in a horizontal direction by penetrating a vertical plane of the body; and a contact tip formed on one side of the body.

In addition, the contact tip may be formed at a height closer to a lower surface of the body than to an upper surface of the body.

Meanwhile, a probe card according to an embodiment of the present invention comprises a probe pin comprising a body, a vertical slit formed in a vertical direction by penetrating a horizontal plane of the body, and a horizontal slit formed in a horizontal direction by penetrating a vertical plane of the body; an upper plate comprising an upper hole through which the probe pin passes; and a lower plate comprising a lower hole through which the probe pin passes, wherein the body may comprise a first body located in the upper hole, a third body located in the lower hole, and a second body formed between the first body and the third body.

In addition, the body may comprise a first separated body, a second separated body, a third separated body, and a fourth separated body, which are spaced apart from each other by the vertical slit and the horizontal slit, and at least one of the first separated body to the fourth separated body may comprise an over-spaced portion curved in a direction in which the separation distance from at least one of the others excluding the at least one increases, and the over-spaced portion may contact an upper plate into which the body is inserted to prevent the body from being separated.

In addition, the body may comprise a first separated body, a second separated body, a third separated body, and a fourth separated body, which are spaced apart from each other by the vertical slit and the horizontal slit, and may further comprise an insulating layer formed to insulate at least one of the first separated body to the fourth separated body from the others excluding the at least one, and the insulating layer may be formed on an inner surface of the at least one facing the others and may extend from the first body to the third body, and the upper plate may comprise a ground wire on an upper surface or a lower surface, and the at least one may be connected to the ground wire.

Meanwhile, a method for manufacturing a probe pin according to an embodiment of the present invention may comprise a process of preparing a base substrate; a process of providing a first body layer on the base substrate; a process of providing a second body layer comprising a connection portion and a horizontal slit on the first body layer; and a process of providing a third body layer on the second body layer.

In addition, the second body layer may further comprise a contact tip.

In addition, before the process of providing the second body layer, the method may further comprise a process of providing a first sacrificial layer around the first body layer; and the process of providing the second body layer may comprise a process of providing the connection portion on a partial region of the first body layer, and a process of providing the contact tip on a region including a boundary of the first body layer and the first sacrificial layer, and the contact tip may be made of a material different from that of the first body layer and the second body layer.

In addition, the process of providing the contact tip may comprise a process of providing a second metal and a process of providing a protective layer on the second metal, and the protective layer may be made of a material having a lower hardness than the second metal.

In addition, the first body layer, the second body layer, and the third body layer may comprise a vertical slit.

In addition, a method for manufacturing a probe pin according to an embodiment of the present invention may comprise a process of preparing a base substrate having a hill portion on an upper surface; a process of providing a contact tip on an upper surface of the hill portion; and a process of providing a body on at least a part of the contact tip and the base substrate.

In addition, the process of providing the body may comprise a process of providing a first body layer on at least a part of the contact tip and the base substrate, a process of providing a second body layer comprising a connection portion and a horizontal slit on the first body layer, and a process of providing a third body layer on the second body layer.

Meanwhile, a method for manufacturing a probe card according to an embodiment of the present invention may comprise a process of bringing an upper plate and a lower plate into proximity to overlap an upper hole of the upper plate and a lower hole of the lower plate; a process of passing a probe pin through the upper hole and the lower hole; and a process of raising the upper plate to bring an over-spaced portion of the probe pin into contact with the upper hole.

Furthermore, the method for manufacturing a probe card according to an embodiment of the present invention may comprise the process of bringing an upper plate and a lower plate into proximity to overlap an upper hole of the upper plate and a lower hole of the lower plate; the process of passing a probe pin through the upper hole and the lower hole; and the process of connecting a separated body, which includes a grounding layer among the first separated body to the fourth separated body spaced apart by a vertical slit and a horizontal slit, to a grounding wire.

### Effect of the Invention

The present invention can provide the effect of facilitating elastic deformation by adjusting the flexibility of the probe pin through the inclusion of vertical slits and horizontal slits.

In addition, the present invention can provide the effect of maintaining excellent high-frequency signal characteristics by adjusting the cross-sectional area of the probe pin.

Furthermore, the present invention can provide the effect of enabling easy insertion of the probe pin into the upper plate and lower plate and preventing the separation of the inserted probe pin by utilizing a plurality of separated bodies separated by vertical slits and/or horizontal slits.

### BRIEF DESCRIPTION OF DRAWINGS

FIG. 1 is a diagram illustrating a probe pin according to an embodiment of the present invention.

FIG. 2 is a diagram illustrating a probe card into which a probe pin according to an embodiment of the present invention is inserted.

FIGS. 3a and 3b are diagrams illustrating the operation of a probe card into which a probe pin according to an embodiment of the present invention is inserted.

FIGS. 4a and 4b are diagrams illustrating the front and side views of a probe pin according to an embodiment of the present invention.

FIGS. 5a and 5b are diagrams illustrating the front and side views of a probe pin according to an embodiment of the present invention.

FIGS. 6a, 6b, and 6c are diagrams illustrating the front, side, and overall views of a probe pin according to an embodiment of the present invention.

FIGS. 7a, 7b, and 7c are diagrams illustrating the front, side, and overall views of a probe pin according to an embodiment of the present invention.

FIGS. 8a to 8c are diagrams illustrating the process in which the upper plate contacts the over-spaced portion.

FIGS. 9a to 9c are diagrams illustrating the process in which the upper plate passes through the recessed portion.

FIGS. 10a to 10d are diagrams illustrating cross-sections of a probe pin according to various embodiments of the present invention.

FIGS. 11a to 11f are diagrams illustrating vertical slits and horizontal slits according to various embodiments of the present invention.

FIGS. 12a to 12f are diagrams illustrating vertical slits and horizontal slits according to various embodiments of the present invention.

FIGS. 13a to 15l are diagrams illustrating a method of manufacturing a probe pin according to an embodiment of the present invention.

FIGS. 16a to 18l are diagrams illustrating a method of manufacturing a probe pin according to an embodiment of the present invention.

FIGS. 19a to 20l are diagrams illustrating a method of manufacturing a probe pin according to an embodiment of the present invention.

FIGS. 21a to 22l are diagrams illustrating a method of manufacturing a probe pin according to an embodiment of the present invention.

FIGS. 23a to 26l are diagrams illustrating a method of manufacturing a probe pin according to an embodiment of the present invention.

FIGS. 27a and 27b are diagrams illustrating a probe pin according to an embodiment of the present invention.

FIGS. 28a to 30l are diagrams illustrating a method of manufacturing a probe pin according to an embodiment of the present invention.

FIGS. 31a to 31d are diagrams illustrating the insulating layer of a separated body according to an embodiment of the present invention.

FIGS. 32a and 32b are diagrams illustrating the front and side views of a probe pin with an insulating layer according to an embodiment of the present invention.

FIG. 32c is a diagram illustrating the end portion of the first body according to an embodiment of the present invention.

FIG. 32d is a diagram illustrating the connection state of the contact tip and the grounding wire according to an embodiment of the present invention.

FIGS. 33a and 33b are diagrams illustrating the front and side views of a probe pin with an insulating layer according to an embodiment of the present invention.

FIG. 33c is a diagram illustrating the end portion of the first body according to an embodiment of the present invention.

FIG. 33d is a diagram illustrating the connection state of the contact tip and the grounding wire according to an embodiment of the present invention.

FIGS. 34a and 34b are diagrams illustrating the front and side views of a probe pin with an insulating layer according to an embodiment of the present invention.

FIG. 34c is a diagram illustrating the end portion of the first body and the grounding wire according to an embodiment of the present invention.

FIG. 34d is a diagram illustrating the positional state of the grounding pin and the grounding wire according to an embodiment of the present invention.

FIG. 35 is a diagram illustrating a probe pin with a protrusion according to an embodiment of the present invention.

### DETAILED DESCRIPTION OF THE EMBODIMENTS

A person skilled in the art, even though not explicitly described or illustrated in this specification, can develop various devices that implement the principles of the invention and are included within the concept and scope of the invention. Furthermore, all conditional terms and embodiments listed in this specification are, in principle, explicitly intended only for the purpose of understanding the concept of the invention and should be understood as not being limited to the specifically listed embodiments and conditions.

The aforementioned objectives, features, and advantages will become more apparent through the following detailed description of the invention in connection with the accompanying drawings, and accordingly, a person skilled in the art to which the invention pertains will be able to easily implement the technical idea of the invention.

The embodiments described in this specification will be explained with reference to the ideal drawings of the present invention. The shapes of the exemplary drawings may be modified due to manufacturing techniques and/or tolerances. Therefore, the embodiments of the present invention are not limited to the specific forms shown but also include variations in form generated by the manufacturing process.

While describing various embodiments, components performing the same function will be assigned the same names and reference numerals for convenience, even if the embodiments differ. Furthermore, the configuration and operation already described in other embodiments will be omitted for convenience.

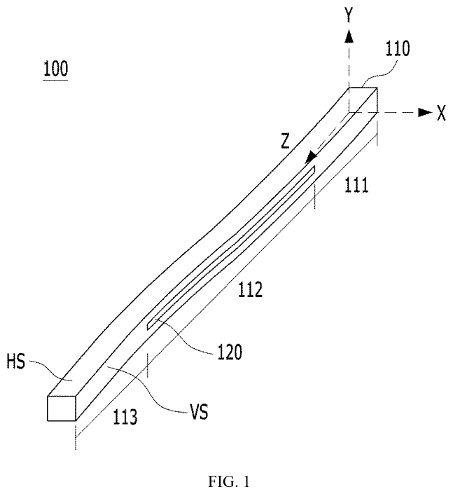

Hereinafter, the terms used in this specification will be briefly explained with reference to FIG. 1.

FIG. 1 is a diagram showing a probe pin 100 according to an embodiment of the present invention.

Referring to FIG. 1, the expression “at least one of A, B, and C” used in this specification means one, two, or all three of A, B, and C. Additionally, the expression “E provided on D” includes both cases where E is provided in direct contact with D and where E is provided in indirect contact with D with other configurations in between. Furthermore, width, height, and length are based on the x-axis, y-axis, and z-axis, respectively. Also, the horizontal direction and lateral direction are based on the x-axis, the vertical direction, upper surface direction, and lower surface direction are based on the y-axis, and the front direction and rear direction are based on the z-axis. However, for convenience of explanation, the width of the vertical slit and the height of the horizontal slit are unified as “width.” Hereinafter, the probe pin 100, the probe card 200 including the probe pin, and their manufacturing methods will be described.

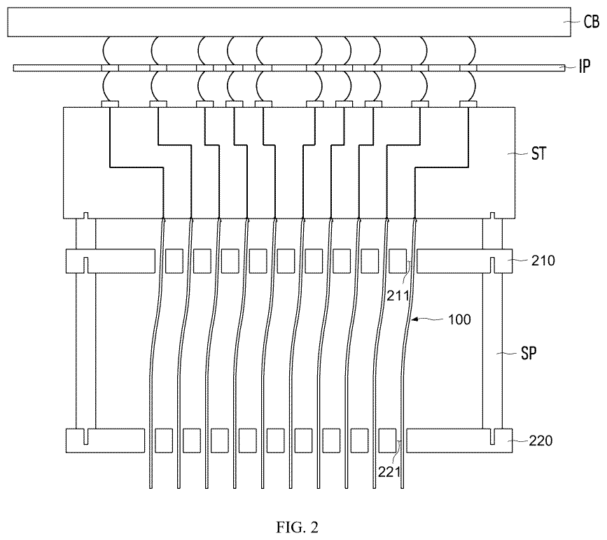

FIG. 2 is a diagram showing a probe card 200 into which a probe pin 100 is inserted according to an embodiment of the present invention.

First, the overall configuration of the probe pin 100 and the probe card 200 will be examined.

The probe card 200 may comprise the probe pin 100. At this time, the probe pin 100 may be electrically connected to a circuit board (not shown). The electrical signal flowing through the probe pin 100 may be used to inspect whether a semiconductor device is defective.

Referring to FIG. 2, the probe card 200 may comprise an upper plate 210 and a lower plate 220. At this time, the upper plate 210 may comprise an upper hole 211 through which the probe pin 100 passes, and the lower plate 220 may comprise a lower hole 221 through which the probe pin 100 passes.

The upper plate 210 and the lower plate 220 may be spaced apart from each other and may be coupled through a spacer SP provided at the spaced-apart position.

The probe card 200 may comprise a plurality of probe pins 100. At this time, the upper plate 210 may comprise a plurality of upper holes 211 through which the plurality of probe pins 100 can pass, and the lower plate 220 may comprise a plurality of lower holes 221 through which the plurality of probe pins 100 can pass.

The probe card 200 comprising a plurality of probe pins 100 may be positioned on a wafer, and the probe pins 100 may be brought into contact with electrode pads to apply pressure, reaching an overdrive state, and the defects of the semiconductor device may be identified.

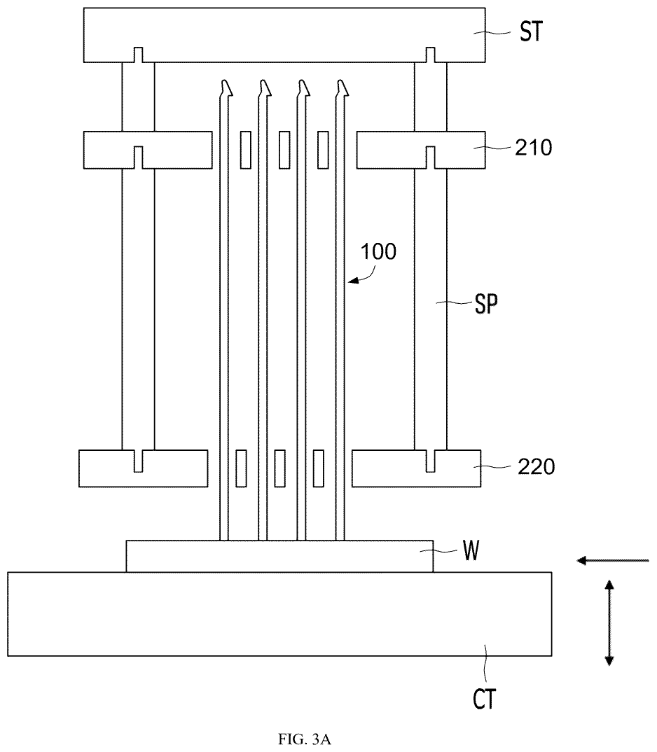

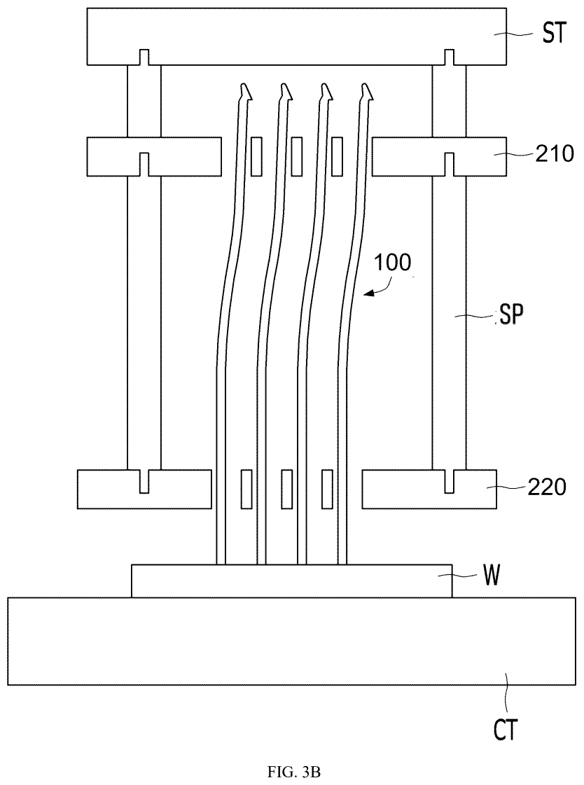

FIGS. 3a and 3b are diagrams showing the operation of a probe card into which a probe pin is inserted according to an embodiment of the present invention.

In FIGS. 3a and 3b, the probe card 200, the inspection target W, and the chuck table CT are schematically illustrated. The probe card manufacturing method according to an embodiment of the present invention may move the chuck table CT in the horizontal and vertical directions during the overdrive process. In this case, the plurality of probe pins 100 may be configured as straight pins.

FIG. 3a shows a state where the inspection target W is brought into contact with the lower end of the straight pin and then further raised toward the probe card 200 by the chuck table CT. In the state where the inspection target W is further raised by the chuck table CT, the chuck table CT may horizontally move to the left as an example. In FIG. 3a, the arrows shown around the inspection target W indicate the direction in which the chuck table CT moves horizontally, and the arrows shown around the chuck table CT indicate the direction in which the chuck table CT moves vertically.

Referring to FIG. 3b, the plurality of probe pins 100 configured as straight pins may be bent by the horizontal movement of the chuck table CT to the left.

The probe card manufacturing method according to an embodiment of the present invention may perform a process of controlling the behavior of the plurality of probe pins 100 by moving the chuck table CT in the horizontal and vertical directions. Therefore, the probe card manufacturing method according to an embodiment of the present invention may cause bending deformation in the straight pins through the chuck table CT when the plurality of probe pins 100 are configured as straight pins.

As described with reference to FIGS. 3a and 3b, the probe card manufacturing method according to an embodiment of the present invention may perform a process of controlling the behavior of the plurality of probe pins 100 by moving the chuck table CT in the horizontal and vertical directions. Therefore, the probe card manufacturing method according to an embodiment of the present invention may implement rapid assembly with the plates 210 and 220 by configuring the plurality of probe pins 100 as straight pins and may cause the intended bending deformation of the probe pins 100 through the chuck table CT.

Thus, the probe card manufacturing method according to an embodiment of the present invention may control the operation of the plurality of probe pins 100 through the chuck table CT, enabling efficient electrical characteristic testing of semiconductor devices while minimizing the issues of damage and breakage of the probe pins 100 and the scrubbing phenomenon.

Next, the probe pin 100 according to various embodiments of the present invention will be specifically examined.

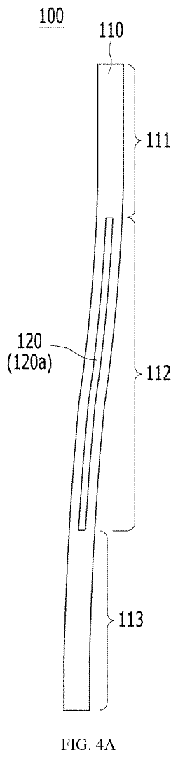

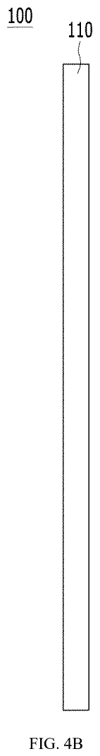

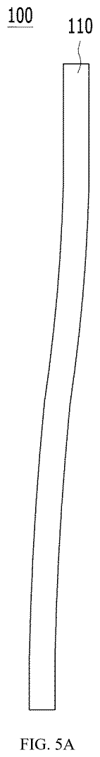

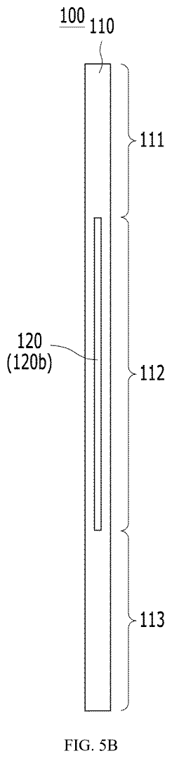

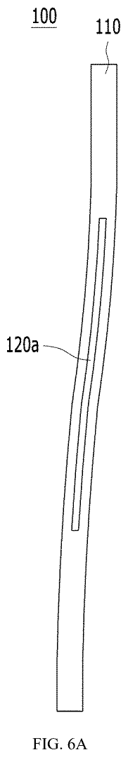

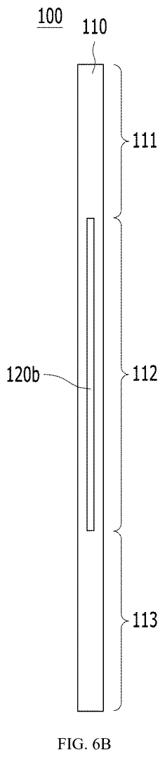

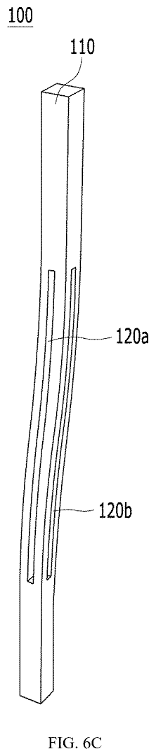

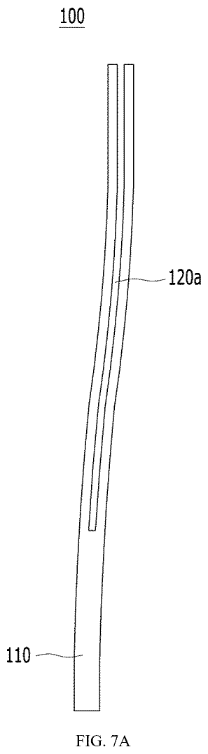

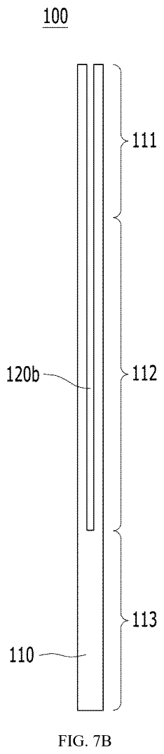

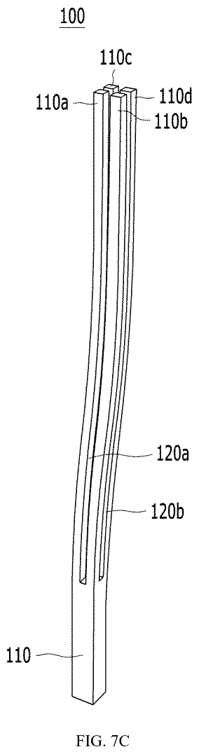

FIGS. 4a and 4b are diagrams showing the front and side views of the probe pin 100 according to an embodiment of the present invention. FIGS. 5a and 5b are diagrams showing the front and side views of the probe pin 100 according to an embodiment of the present invention. FIGS. 6a, 6b, and 6c are diagrams showing the front, side, and overall views of the probe pin 100 according to an embodiment of the present invention. FIGS. 7a, 7b, and 7c are diagrams showing the front, side, and overall views of the probe pin 100 according to an embodiment of the present invention.

Referring to FIGS. 4a and 4b, the probe pin 100 according to an embodiment of the present invention may comprise a body 110; and a slit 120 formed by penetrating a part of the body 110.

The probe pin 100 may be configured as a cobra pin, a straight pin, or a modified straight pin, but is not limited thereto. Therefore, the body 110 may be formed to extend in one direction. The body 110 may be straight and may comprise at least one bent portion bent in the horizontal direction.

The body 110 may comprise a first body 111 forming one side of the body 110, a second body 112 extending from the first body 111 to form the middle portion of the body 110, and a third body 113 extending from the second body 112 to form the other side of the body 110.

The slit 120 may comprise a vertical slit 120a formed in the vertical direction by penetrating the horizontal plane HS of the body 110.

The body 110 may comprise one or more curved portions bent in the horizontal direction. Here, the horizontal direction may mean the +x direction or the −x direction. That is, the body 110 may be formed in a curved shape. The body 110 may further elastically deform in the curved direction in an overdrive state. For example, if the body 110 is formed to be curved in the +x direction as it extends from the front to the rear, the rear portion of the body 110 may elastically deform in the +x direction.

Additionally, the body 110 may comprise a first body 111, a second body 112, and a third body 113. The first body 111 may constitute one side of the body 110 and may be connected to a circuit board. At this time, the connection may mean an electrical connection, which may include both direct and indirect connections.

The second body 112 may extend from the first body 111 and may constitute the middle portion of the body 110.

The third body 113 may extend from the second body 112 and may constitute the other side of the body 110. The third body 113 may deliver electrical signals by directly contacting electrode pads on a wafer or indirectly contacting them through a contact tip 130.

The body 110 may be composed of metal, and by using a metal with high electrical conductivity, the current carrying capacity (CCC, Current Carrying Capacity) may be improved.

The body 110 may comprise copper (Cu), silver (Ag), gold (Au), rhodium (Rd), platinum (Pt), iridium (Ir), palladium (Pd), nickel (Ni), manganese (Mn), tungsten (W), phosphorus (P), or alloys thereof. Additionally, the body 110 may comprise palladium-cobalt (PdCo) alloy, palladium-nickel (PdNi) alloy, nickel-phosphorus (NiP) alloy, nickel-manganese (NiMn) alloy, nickel-cobalt (NiCo) alloy, or nickel-tungsten (NiW) alloy. However, the material of the body 110 is not limited to the listed examples.

The slit 120 may be formed by penetrating a portion of the body 110. Additionally, the slit 120 may comprise a vertical slit 120a. The vertical slit 120a may be formed by penetrating the horizontal plane of the body 110. Specifically, the vertical slit 120a may extend from the upper surface to the lower surface of the body 110 and may be formed to extend in the longitudinal direction of the body 110. At this time, the vertical slit 120a may be formed to follow the curved shape of the body 110.

The vertical slit 120a may increase the flexibility of the body 110, enabling smooth elastic deformation in an overdrive state. Additionally, the vertical slit 120a may reduce the cross-sectional area perpendicular to the longitudinal direction of the body 110, preventing signal attenuation of high-frequency signals.

According to the skin effect, since alternating current flows concentrated on the surface of a conductor, increasing the surface area of the body 110 may prevent signal attenuation and enhance the current carrying capacity. Therefore, the vertical slit 120a and the horizontal slit 120b may increase the surface area of the body 110, thereby enhancing the current carrying capacity.

Referring to FIGS. 5a and 5b, the probe pin 100 according to an embodiment of the present invention may comprise the body 110 and the slit 120. The body 110 may comprise the first body 111, the second body 112, and the third body 113. The slit 120 may comprise a horizontal slit 120b formed by penetrating the vertical plane of the body 110. Here, the description of the same configuration as described above will be omitted.

The horizontal slit 120b may be formed by penetrating the vertical plane VS of the body 110. Specifically, the horizontal slit 120b may extend from the left side to the right side of the body 110 and may be formed to extend in the longitudinal direction of the body 110. At this time, the horizontal slit 120b may be formed to follow the shape of the body 110.

The horizontal slit 120b may increase the flexibility of the body 110, enabling smooth elastic deformation in an overdrive state. Additionally, the vertical slit 120a may reduce the cross-sectional area of the body 110, preventing signal attenuation of high-frequency signals.

Referring to FIGS. 6a, 6b, and 6c, the probe pin 100 according to an embodiment of the present invention may comprise the body 110 and the slit 120. The body 110 may comprise the first body 111, the second body 112, and the third body 113. The slit 120 may comprise the vertical slit 120a and the horizontal slit 120b. Here, the description of the same configuration as described above will be omitted.

Additionally, in the probe pin 100 according to an embodiment of the present invention, at least one of the vertical slit 120a and the horizontal slit 120b may be formed in the second body 112 The slit 120 may simultaneously comprise the vertical slit 120a and the horizontal slit 120b. At this time, the vertical slit 120a may be formed by penetrating the horizontal plane corresponding to the entire or partial length of the body 110, and the horizontal slit 120b may be formed by penetrating the vertical plane corresponding to the entire or partial length of the body 110 that the vertical slit 120a does not penetrate. That is, the vertical slit 120a and the horizontal slit 120b may be formed not to intersect.

Furthermore, the vertical slit 120a and the horizontal slit 120b may each be formed by penetrating the horizontal plane and the vertical plane of the second body 112.

The vertical slit 120a and the horizontal slit 120b may be simultaneously provided to further increase the flexibility of the body 110, enabling smooth elastic deformation in an overdrive state. Additionally, the vertical slit 120a and the horizontal slit 120b may be simultaneously provided to further reduce the cross-sectional area of the body 110, preventing signal attenuation of high-frequency signals.

Furthermore, the vertical slit 120a and the horizontal slit 120b may be simultaneously provided to achieve a fine-pitch effect. For example, if only the vertical slit 120a is provided, the flexibility of the body 110 may be insufficient, posing a risk of damaging the semiconductor device. Similarly, if only the horizontal slit 120b is provided, the flexibility of the body 110 may also be insufficient, posing a risk of damaging the semiconductor device.

If multiple vertical slits 120a are provided, the flexibility of the body 110 may increase, but the width of the body 110 (the arrangement direction of the multiple vertical slits 120a) may widen, making it difficult to achieve fine-pitch.

Therefore, the body 110 may simultaneously comprise the vertical slit 120a and the horizontal slit 120b to further increase the flexibility of the body 110 and simultaneously achieve a fine-pitch effect.

Referring to FIGS. 7a, 7b, and 7c, the probe pin 100 according to an embodiment of the present invention may comprise the vertical slit 120a and the horizontal slit 120b. At least one of the vertical slit 120a and the horizontal slit 120b may extend from the second body 112 to the end of the first body 111, opening one side of the first body 111.

The vertical slit 120a may extend from the second body 112 to the first body 111. The vertical slit 120a may open one side of the first body 111. That is, the vertical slit 120a may extend to the rear surface of the end, forming a vertical-shaped opening on the rear surface of the end.

The horizontal slit 120b may extend from the second body 112 to the first body 111. The horizontal slit 120b may open one side of the first body 111. That is, the horizontal slit 120b may extend to the rear surface of the end of the body 110, forming a horizontal-shaped opening on the rear surface of the end.

Furthermore, both the vertical slit 120a and the horizontal slit 120b may extend from the second body 112 to the first body 111. Both the horizontal slit 120b and the horizontal slit 120b may open one side of the first body 111. That is, the vertical slit 120a and the horizontal slit 120b may extend to the rear surface of the end of the body 110, forming a cross-shaped opening.

The vertical slit 120a and/or the horizontal slit 120b may extend to the rear surface of the end of the body 110, further increasing the flexibility of the body 110, enabling smooth elastic deformation in an overdrive state, and further reducing the cross-sectional area of the body 110, preventing signal attenuation of high-frequency signals. At the same time, a fine-pitch effect may be achieved.

Additionally, since the vertical slit 120a and/or the horizontal slit 120b are formed to extend to the first body 111, the flexibility of the first body 111 may be further increased. That is, while increasing the flexibility of the body 110, the flexibility of the third body 113 may be relatively maintained at a lower level. As a result, the deformation of the third body 113 may be reduced, thereby reducing the force applied to the lower hole 221 of the lower plate 220, minimizing wear of the lower hole 221, and enabling more accurate contact with the semiconductor device.

Additionally, the vertical slit 120a and the horizontal slit 120b according to an embodiment of the present invention may intersect with each other.

For example, the body 110 may be implemented in a form where the vertical slit 120a is provided in the second body 112, and the horizontal slit 120b is provided in the first body 111. In this case, since the vertical slit 120a and the horizontal slit 120b do not intersect, the cross-sectional areas of the second body 112 and the first body 111 may be consistently maintained. Nevertheless, the second body 112 may have greater lateral flexibility due to the provision of the vertical slit 120a.

In contrast, the body 110 may be implemented in a form comprising the vertical slit 120a and the horizontal slit 120b in the second body 112, the body 110 may be implemented in a form comprising the vertical slit 120a and the horizontal slit 120b in the first body 111, and the body 110 may be implemented in a form comprising the vertical slit 120a and the horizontal slit 120b in both the second body 112 and the first body 111. The vertical slit 120a and the horizontal slit 120b are provided to intersect each other, thereby significantly reducing the overall cross-sectional area of the body 110 and further increasing flexibility.

Next, the probe pin 100 comprising the over-spaced portion 116 according to various embodiments of the present invention and the method for manufacturing the probe card 200 comprising the probe pin 100 will be described.

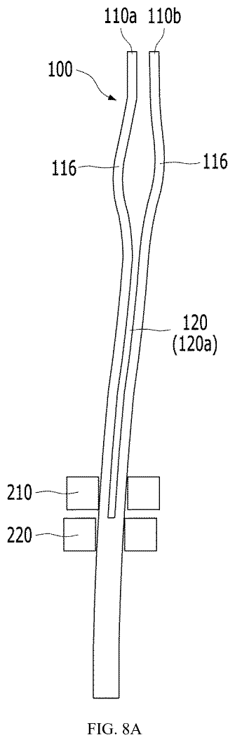

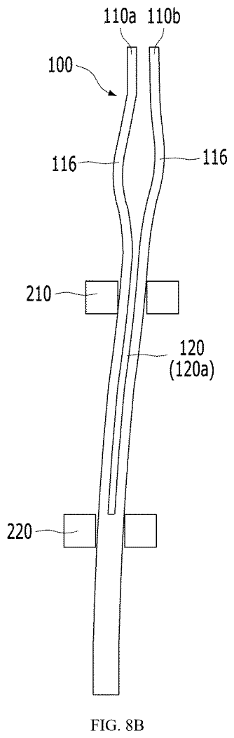

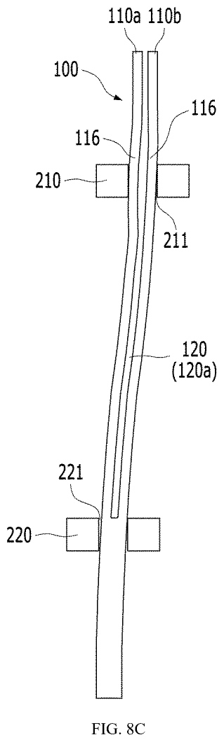

FIGS. 8a to 8c are diagrams illustrating a process in which the upper plate 210 and the over-spaced portion 116 come into contact.

Referring to FIGS. 8a to 8c, the probe pin 100 according to an embodiment of the present invention may comprise the body 110 and the vertical slit 120a. At this time, the body 110 may comprise the first separated body 110a and the second separated body 110b spaced apart from each other by the vertical slit 120a.

The first separated body 110a to the eighth separated body 110h described in the present invention correspond to concepts divided for convenience to explain a plurality of separated bodies, and their positions are not limited to the drawings and embodiments. For example, the first separated body 110a may refer to any one of the plurality of separated bodies.

The plurality of separated bodies may be formed in the first body 111 and the second body 112. In this case, since the slit 120 is not formed in the third body 113, the body 110 is not divided.

In other words, the first body 111 and the second body 112 may comprise separated bodies, but the third body 113 may be integrally formed.

At least one of the first separated body 110a and the second separated body 110b may comprise an over-spaced portion 116 curved in a direction in which the spacing distance from the other separated body increases. In addition, the first separated body 110a and the second separated body 110b may each comprise an over-spaced portion 116 curved in a direction in which the spacing distance increases.

That is, only the first separated body 110a may comprise the over-spaced portion 116, only the second separated body 110b may comprise the over-spaced portion 116, and each of the first separated body 110a and the second separated body 110b may comprise the over-spaced portion 116. Since the vertical cross-sectional area of the first separated body 110a along the longitudinal direction may remain the same, the first separated body 110a may be bent to protrude in the lateral (+x) direction by comprising the over-spaced portion 116. In addition, since the vertical cross-sectional area of the second separated body 110b along the longitudinal direction may remain the same, the second separated body 110b may be bent to protrude in the lateral (−x) direction by comprising the over-spaced portion 116.

The probe card 200 may comprise the upper plate 210 comprising the upper hole 211 and the lower plate 220 comprising the lower hole 221. The upper hole 211 and the lower hole 221 of the probe card 200 may allow the body 110 to pass through, and the first body 111 may be located in the upper hole 211, and the third body 113 may be located in the lower hole 221.

Furthermore, the probe card 200 may further comprise an intermediate plate (not shown) comprising an intermediate hole. The intermediate hole (not shown) of the probe card 200 may allow the body 110 to pass through, and the second body 112 may be located in the intermediate hole.

Unlike FIGS. 8a to 8b, the over-spaced portion 116 may be located in at least one of the first body 111, the second body 112, and the third body 113. The over-spaced portion 116 of the first body 111 may contact the upper hole 211 to be fixed to the upper plate 210, and the over-spaced portion 116 of the second body 112 may contact the intermediate hole to be fixed to the intermediate plate.

The probe pin 100 and/or the body 110 may be fixed to the probe card 200 through the over-spaced portion 116, thereby providing the effect of preventing separation from the probe card 200.

Meanwhile, referring again to FIGS. 7a to 7c, the probe pin 100 according to an embodiment of the present invention may comprise the body 110 and the horizontal slit 120b. At this time, the body 110 may comprise the first separated body 110a and the second separated body 110b spaced apart from each other by the horizontal slit 120b.

That is, the first separated body 110a and the second separated body 110b are not limited to being spaced apart by the vertical slit 120a but also include being spaced apart by the horizontal slit 120b. The effects of the first separated body 110a and the second separated body 110b spaced apart by the horizontal slit 120b are as described above.

On the other hand, referring again to FIGS. 7a to 8c, the probe pin 100 according to an embodiment of the present invention may comprise the body 110, the vertical slit 120a, and the horizontal slit 120b. At this time, the body 110 may comprise the first separated body 110a, the second separated body 110b, the third separated body 110c, and the fourth separated body 110d spaced apart from each other by the vertical slit 120a and the horizontal slit 120b.

At least one of the first separated body 110a to the fourth separated body 110d may comprise an over-spaced portion 116 curved in a direction in which the spacing distance from at least one of the remaining separated bodies increases.

Specifically, the first separated body 110a and the second separated body 110b may each comprise an over-spaced portion 116b curved in a direction in which the spacing distance from the third separated body 110c and the fourth separated body 110d increases. Alternatively, the first separated body 110a and the third separated body 110c may each comprise an over-spaced portion 116 curved in a direction in which the spacing distance from the second separated body 110b and the fourth separated body 110d increases.

That is, at least one of the first separated body 110a to the fourth separated body 110d may comprise the over-spaced portion 116. At this time, the separated body comprising the over-spaced portion 116 may be curved in a direction in which the spacing distance from the separated body not comprising the over-spaced portion 116 increases.

As described above, the over-spaced portion 116 may be located in at least one of the first body 111, the second body 112, and the third body 113.

The body 110 or the probe pin 100 comprising the over-spaced portion 116 may be provided in the probe card 200.

Referring again to FIGS. 8a to 8c, the method for manufacturing the probe card 200 according to an embodiment of the present invention may comprise the process of bringing the upper plate 210 and the lower plate 220 into proximity to overlap the upper hole 211 of the upper plate 210 and the lower hole 221 of the lower plate 220; the process of passing the probe pin 100 through the upper hole 211 and the lower hole 221; and the process of raising the upper plate 210 to bring the over-spaced portion 116 of the probe pin 100 into contact with the upper hole 211.

First, the process of bringing the upper plate 210 and the lower plate 220 of the probe card 200 into proximity to overlap the upper hole 211 of the upper plate 210 and the lower hole 221 of the lower plate 220 may be performed.

The upper plate 210 may move downward to come into proximity with the lower plate 220. At this time, the upper hole 211 and the lower hole 221 may overlap each other to form a continuous single hole vertically aligned. In this case, the probe pin 100 and/or the body 110 may comprise the over-spaced portion 116 in the first body 111.

Subsequently, the process of passing the probe pin 100 through the upper hole 211 and the lower hole 221 may be performed.

In the overlapped state where the upper plate 210 moves downward, the body 110 or the probe pin 100 may pass through the upper hole 211 and the lower hole 221.

Subsequently, the process of raising the upper plate 210 to bring the over-spaced portion 116 of the probe pin 100 into contact with the upper hole 211 may be performed.

When the upper plate 210 moves upward, the first separated body 110a and the second separated body 110b may have a smaller thickness than the upper hole 211 as the spacing distance between them decreases. This phenomenon may temporarily occur during the movement of the upper plate 210.

The upper plate 210 may move upward to contact the over-spaced portion 116. That is, the over-spaced portion 116 may contact the upper hole 211 to be fixed to the probe card 200. At this time, the over-spaced portion 116 may be deformed by receiving an inward force from the upper hole 211, and the first separated body 110a and the second separated body 110b may come into contact with each other.

The sum of the widths of the first separated body 110a, the second separated body 110b, and the slit 120 between them may be greater than the upper hole 211. Thus, the first separated body 110a and the second separated body 110b may be fixed by receiving force from the upper hole 211.

The body 110 may be configured to comprise the first separated body 110a and the second separated body 110b spaced apart from each other, or to comprise the first separated body 110a to the fourth separated body 110d spaced apart from each other. The separated bodies having a spaced structure may be deformed inward even when the upper plate 210 rises, thereby easily positioning the upper hole 211 of the upper plate 210 in the first body 111.

Next, the probe pin 100 comprising the tie portion 117 and the recessed portion 117a according to various embodiments of the present invention will be described.

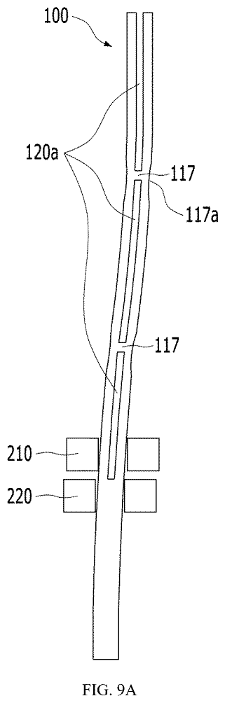

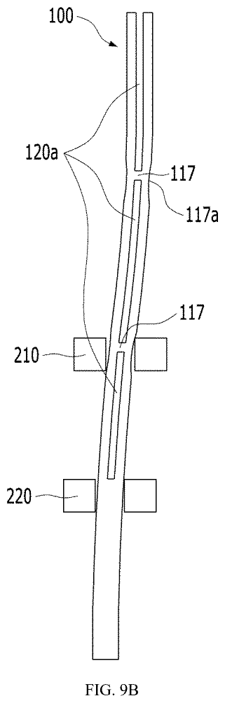

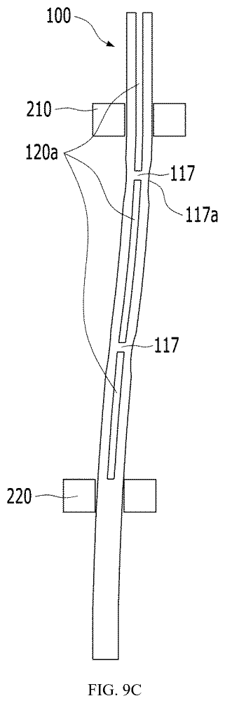

FIGS. 9a to 9c are diagrams illustrating a process in which the upper plate 210 passes through the recessed portion 117a.

Referring to FIGS. 9a to 9c, the probe pin 100 according to an embodiment of the present invention may comprise the body 110, the vertical slit 120a, and the tie portion 117, and may further comprise the recessed portion 117a. At this time, the body 110 may comprise the first separated body 110a and the second separated body 110b spaced apart by the vertical slit 120a.

The tie portion 117 may connect the inner surface of the first separated body 110a and the inner surface of the second separated body 110b. When the probe pin 100 includes only the vertical slit 120a, the tie portion 117 may be formed to extend in the horizontal direction to connect the first separated body 110a and the second separated body 110b. Here, the inner surface may refer to the surface facing inward or the surfaces facing each other in the first separated body 110a and the second separated body 110b.

On the other hand, when the probe pin 100 includes only the horizontal slit 120b, the tie portion 117 may be formed to extend in the vertical direction to connect the first separated body 110a and the second separated body 110b.

The recessed portion 117a may be formed only on the outer surface of the first separated body 110a or only on the outer surface of the second separated body 110b. Furthermore, the recessed portion 117a may be formed on the outer surfaces of both the first separated body 110a and the second separated body 110b. Here, the outer surface may refer to the surface exposed on the outer part of the body 110 and may mean the surface opposite to the inner surface.

Specifically, the recessed portions 117a may be formed on the outer surfaces of the first separated body 110a and the second separated body 110b, respectively, and the tie portion 117 may be formed on the inner surfaces.

Meanwhile, the body 110 may comprise the first separated body 110a, the second separated body 110b, the third separated body 110c, and the fourth separated body 110d, which are separated by the vertical slit 120a and the horizontal slit 120b.

The tie portion 117 may connect the inner surface of the first separated body 110a and the inner surface of at least one of the second separated body 110b to the fourth separated body 110d.

The recessed portion 117a may be recessedly formed on the outer surface of the first separated body 110a opposite to the inner surface of the first separated body 110a where the tie portion 117 is connected, and on the outer surface of at least one of the second separated body 110b to the fourth separated body 110d opposite to the inner surface of the at least one. Additionally, the recessed portion 117a may be recessedly formed on the outer surface of the first separated body 110a or the outer surface of the at least one.

The tie portion 117 may be formed to connect at least two of the first separated body 110a to the fourth separated body 110d. The tie portion 117 may be formed to extend in the horizontal direction to connect the first separated body 110a and the second separated body 110b and the third separated body 110c and the fourth separated body 110d, and may be formed to extend in the vertical direction to connect the first separated body 110a and the third separated body 110c and the second separated body 110b and the fourth separated body 110d.

The tie portion 117 may divide the slit 120 into multiple sections. The tie portion 117 has the effect of reducing the flexibility of the body 110. Additionally, the tie portion 117 may allow the multiple separated bodies to deform in one direction in an overdrive state. Thus, the possibility of the multiple separated bodies formed in one probe pin 100 bending in different directions can be blocked. The tie portion 117 may prevent the multiple separated bodies from deforming in different directions due to the slit 120, thereby preventing a short circuit with adjacent probe pins 100.

The multiple separated bodies having a separated structure may deform inward even when the upper plate 210 rises, making it easier to position the upper hole 211 of the upper plate 210 on the first body 111.

At this time, the recessed portion 117a may be provided on the outer surface of the body 110 and recessed inward, making it easier for the upper hole 211 of the upper plate 210 to pass through.

The tie portion 117 guides the multiple separated bodies to deform in one direction during the overdrive process.

However, during the process of assembling the probe pin 100 to the upper plate 210 and the lower plate 220, when the upper hole 211 passes through the tie portion 117, it may hinder the inward deformation of the multiple separated bodies, thereby obstructing the movement of the upper plate 210. At this time, the recessed portion 117a may play a role in complementing the tie portion 117 by allowing the upper hole 211 of the upper plate 210 to easily pass through the body 110.

Next, the probe pin 100 comprising multiple vertical slits 120a and horizontal slits 120b according to the embodiment of the present invention will be described.

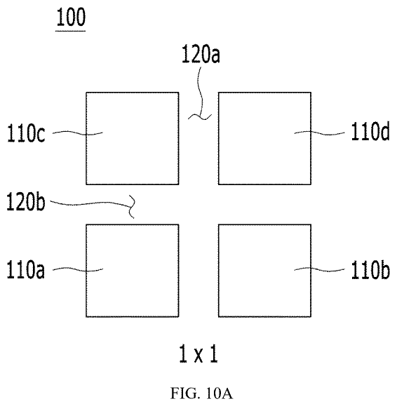

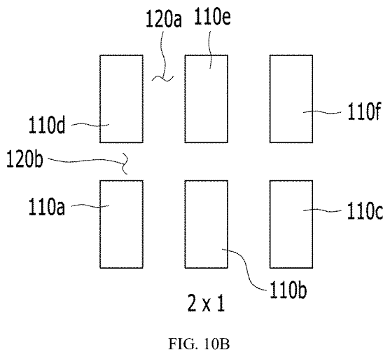

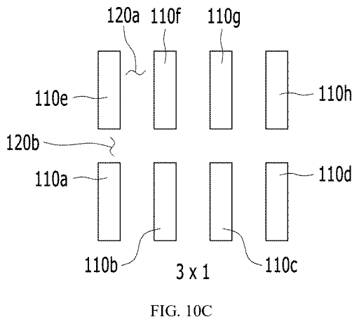

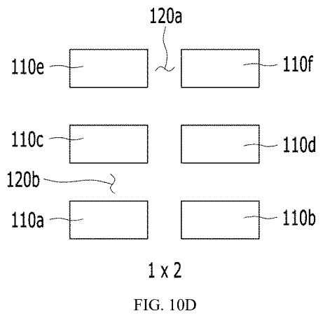

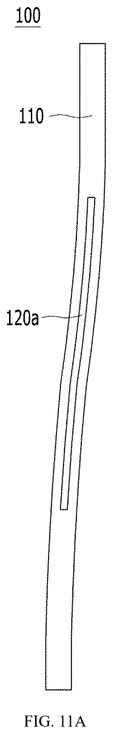

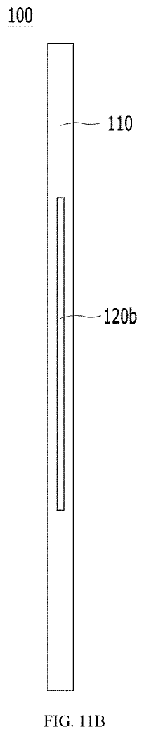

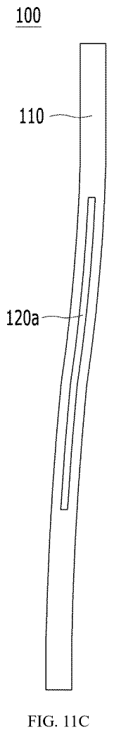

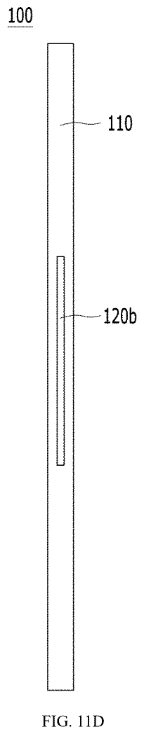

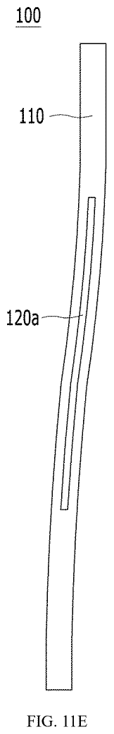

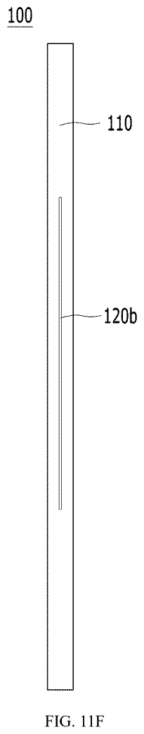

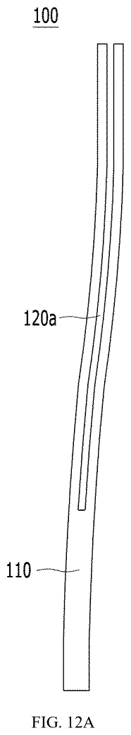

FIGS. 10a to 10d illustrate cross-sectional views of the probe pin 100 according to various embodiments of the present invention.

Referring to FIGS. 10a to 10d, the probe pin 100 according to the embodiment of the present invention may comprise the vertical slit 120a and the horizontal slit 120b. At this time, at least one of the vertical slit 120a and the horizontal slit 120b may be provided in multiple numbers.

The probe pin 100 may comprise the slit 120, and the slit 120 may comprise one or multiple vertical slits 120a. Additionally, the slit 120 may comprise one or multiple horizontal slits 120b. Furthermore, the slit 120 may comprise multiple vertical slits 120a and multiple horizontal slits 120b.

FIG. 10a shows the end surface of multiple separated bodies separated by one vertical slit 120a and one horizontal slit 120b. At this time, the body 110 may comprise the first separated body 110a to the fourth separated body 110d.

FIG. 10b shows the end surface of multiple separated bodies separated by two vertical slits 120a and one horizontal slit 120b. At this time, the body 110 may comprise the first separated body 110a to the sixth separated body 110f.

FIG. 10c shows the end surface of multiple separated bodies separated by three vertical slits 120a and one horizontal slit 120b. At this time, the body 110 may comprise the first separated body 110a to the eighth separated body 110h.

FIG. 10d shows multiple separated bodies separated by one vertical slit 120a and two horizontal slits 120b. At this time, the body 110 may comprise the first separated body 110a to the sixth separated body 110f.

When the body 110 comprises multiple separated bodies, one side of the body 110 may be formed in a split shape. The more slits 120 the probe pin 100 includes, the higher flexibility it may have.

Based on FIGS. 10a to 10d, if the thickness (vertical) of the separated body is greater than its width (horizontal), the side flexibility of the body 110 and/or the probe pin 100 may increase. Conversely, if the thickness of the separated body is smaller than its width, the side flexibility of the body 110 and/or the probe pin 100 may decrease.

Additionally, if only the number of vertical slits 120a is increased, the width of the body 110 may increase, making it impossible to achieve narrow pitch. Therefore, the body 110 may comprise the horizontal slit 120b to further increase flexibility. Meanwhile, in an overdrive state, if the long edge of the cross-section of the separated body is placed in the deformation direction of the pin, flexibility may further increase.

The present invention can change the shape of the probe pin 100, the body 110, and the multiple separated bodies by varying the number of vertical slits 120a and horizontal slits 120b, thereby adjusting the flexibility of the probe pin 100.

Next, various forms of the vertical slit 120a and the horizontal slit 120b according to the embodiment of the present invention will be described.

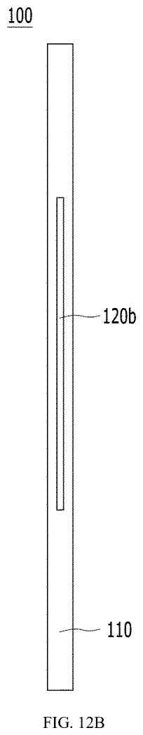

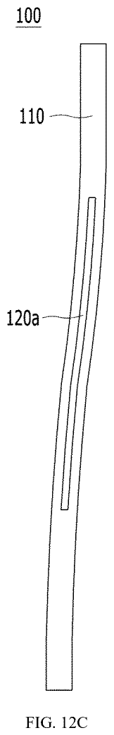

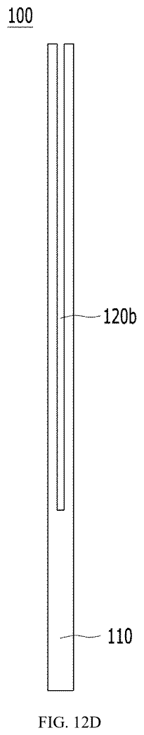

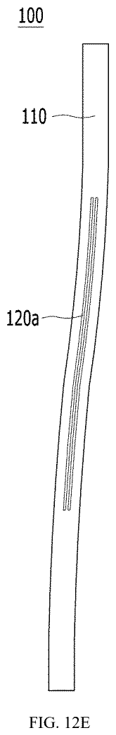

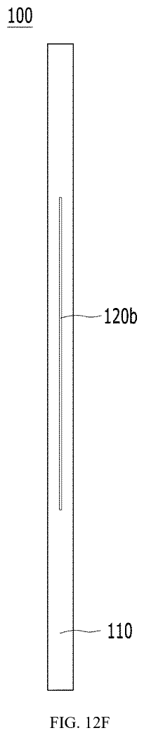

FIGS. 11a to 11f and FIGS. 12a to 12f illustrate the vertical slit 120a and the horizontal slit 120b according to various embodiments of the present invention.

Referring to FIGS. 11a to 12f, the probe pin 100 according to the embodiment of the present invention may have vertical slits 120a and horizontal slits 120b with different widths or lengths.

Referring to FIGS. 11a and 11b, the probe pin 100 may comprise vertical slits 120a and horizontal slits 120b of the same width and length.

Referring to FIGS. 11c and 11d, the probe pin 100 may comprise vertical slits 120a and horizontal slits 120b of the same width. Additionally, the probe pin 100 may comprise vertical slits 120a and horizontal slits 120b of different lengths.

Referring to FIGS. 11e and 11f, the probe pin 100 may comprise vertical slits 120a and horizontal slits 120b of different widths. Additionally, the probe pin 100 may comprise vertical slits 120a and horizontal slits 120b of the same length.

Referring to FIGS. 12a to 12d, the probe pin 100 may comprise vertical slits 120a and horizontal slits 120b of the same width. Additionally, the probe pin 100 may comprise vertical slits 120a and horizontal slits 120b in the second body 112. Furthermore, the probe pin 100 may extend at least one slit 120 of the vertical slit 120a and the horizontal slit 120b in the first body 111, and the at least one slit 120 may extend to the end surface of the first body 111 to form an opening.

Referring to FIGS. 12e and 12f, the probe pin 100 may comprise vertical slits 120a and horizontal slits 120b in different numbers. At this time, the width and length of the vertical slits 120a and horizontal slits 120b are not limited to being the same and may be selectively adopted from the aforementioned forms.

The probe pin 100 can adjust the flexibility of the probe pin 100 and/or the body 110 by varying the number and shape of the vertical slit 120a and the horizontal slit 120b, and can achieve the effect of maintaining high-frequency characteristics by reducing the cross-sectional area of the probe pin 100 and/or the body 110.

Next, the probe pin 100 comprising the contact tip 130 according to the embodiment of the present invention, and the manufacturing method of the probe pin 100 will be described.

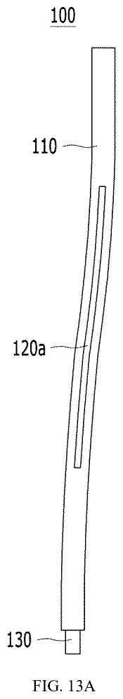

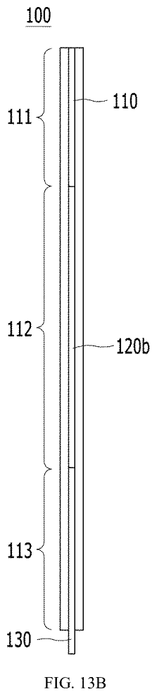

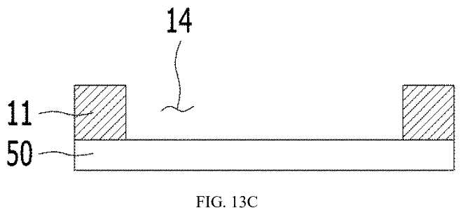

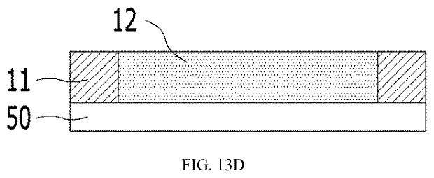

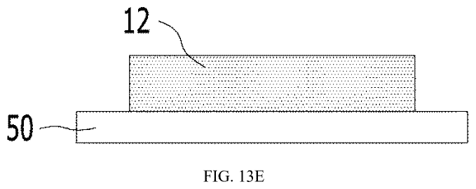

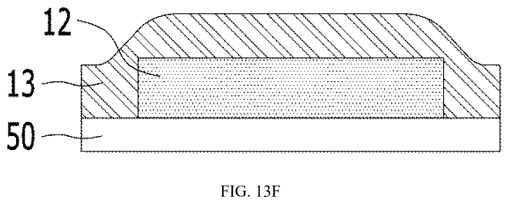

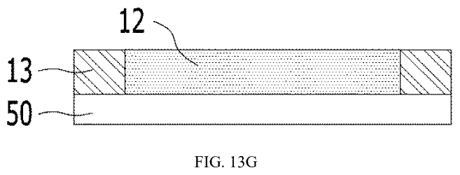

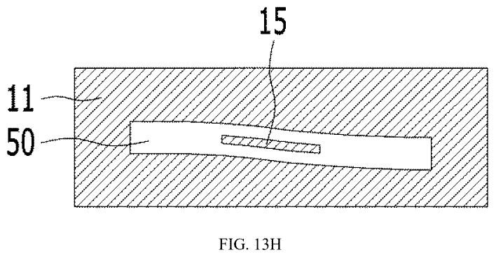

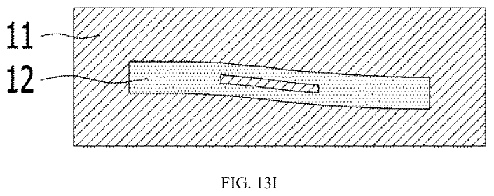

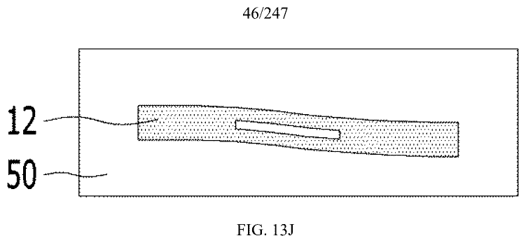

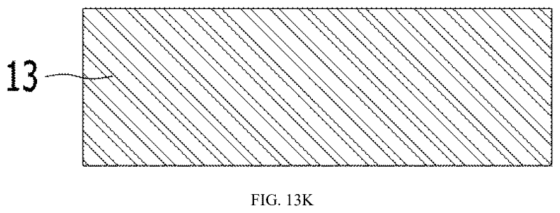

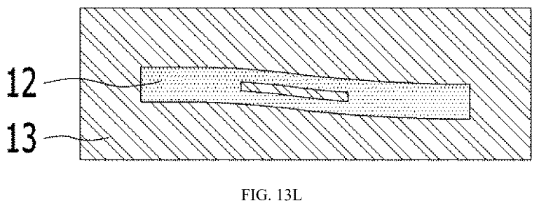

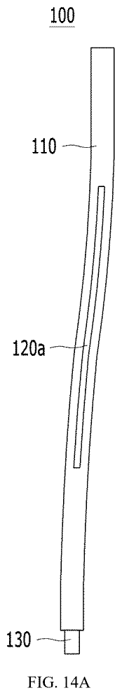

FIGS. 13a to 15l illustrate the manufacturing method of the probe pin 100 according to the embodiment of the present invention.

Referring to FIGS. 13a to 15l, the probe pin 100 according to the embodiment of the present invention may comprise a body 110 and a slit 120. The body 110 may comprise a first body 111 to a third body 113, and the slit 120 may comprise a vertical slit 120a and a horizontal slit 120b. Furthermore, the probe pin 100 may further comprise a contact tip 130 located at the end region of the third body 113 and in contact with the object to be inspected.

The contact tip 130 may be made of the same or different material as the body 110. Additionally, the contact tip 130 may comprise a rhodium layer 130a, 22a, 32a made of a material containing rhodium. Furthermore, the contact tip 130 may be formed of a single metal layer or may be configured by laminating multiple metal layers.

The contact tip 130 may be located at the end region of the third body 113. The contact tip 130 may directly contact the object to be inspected. Therefore, the contact tip 130 may be formed of a metal with higher wear resistance and/or hardness than the body 110, and may be formed of a metal with higher electrical conductivity than the body 110. This allows the probe pin 100 to maintain high wear resistance and/or hardness and to increase the current carrying capacity.

The contact tip 130 may be configured to include copper (Cu), silver (Ag), gold (Au), rhodium (Rd), platinum (Pt), iridium (Ir), palladium (Pd), nickel (Ni), manganese (Mn), tungsten (W), phosphorus (P), or alloys thereof. Additionally, the body 110 may be configured to include a palladium-cobalt (PdCo) alloy, a palladium-nickel (PdNi) alloy, a nickel-phosphorus (NiP) alloy, a nickel-manganese (NiMn) alloy, a nickel-cobalt (NiCo) alloy, or a nickel-tungsten (NiW) alloy. However, the material of the contact tip 130 is not limited to the listed examples.

The contact tip 130, if too thin, may lack strength, and thus, it is preferably formed with a thickness of about 10 μm.

The probe pin 100 can be manufactured by a method of constructing a mold and plating. At this time, the probe pin 100 may be manufactured in a vertical direction and may comprise a first body layer 10, a second body layer 20, and a third body layer 30.

The first body layer 10 may constitute the lower layer of the probe pin 100. The second body layer 20 may be located on the first body layer 10 and may include the horizontal slit 120b. The third body layer 30 may be located on the second body layer 20 and may constitute the upper layer. The distinction between each layer is based on the horizontal slit 120b.

In the drawings related to the manufacturing method of the probe pin 100 described below, (a) represents the front view of the probe pin 100, (b) represents the side view of the probe pin 100, (c) represents the side view of the probe pin 100, and (d) represents the front view of the probe pin 100 Referring to FIGS. 13a and 13b, the probe pin 100 may comprise a body 110, a horizontal slit 120b, and a contact tip 130, and may further comprise a vertical slit 120a.

Referring to FIGS. 13c to 13l, FIGS. 14c to 14l, and FIGS. 15c to 15l, the manufacturing method of the probe pin 100 according to the embodiment of the present invention may comprise the steps of: providing a base substrate 50; forming a first body layer 10 on the base substrate 50; forming a second body layer 20 on the first body layer 10; forming a third body layer 30 on the second body layer 20; and separating the first body layer 10 to the third body layer 30.

The base substrate 50 provides a space for forming the body 110, which is a component of the probe pin 100, and can be separated after the manufacturing of the probe pin 100.

First, the step of forming the first body layer 10 on the base substrate 50 may be performed.

The first body layer 10 may represent the lower layer of the probe pin 100. Specifically, the first body layer 10 may represent the layer located below the horizontal slit 120b. Since the probe pin 100 has a horizontally bent shape, the first body layer 10 may have a horizontally bent shape. That is, the first body layer 10 may include at least one bent portion bent in the horizontal direction.

Referring to FIGS. 13c to 13e and FIGS. 13h to 13j, the step of forming the first body layer 10 may comprise the steps of forming a first mold 11, forming a first metal 12, and removing the first mold 11.

The step of forming the first mold 11 may be performed through the steps of providing a PR layer, exposure, and development. At this time, the PR layer may be a photoresist layer used as a mold for plating the first metal 12. Exposure may determine the area for removing a part of the PR layer. Development may remove the PR layer in the determined area. The first mold 11 may form an opening 14 where the first metal 12 is to be plated through the steps of providing the PR layer, exposure, and development. The first mold 11 may include an opening 14 corresponding to the first body layer 10. Additionally, the first mold 11 may include a vertical portion 15 corresponding to the vertical slit 120a.

The step of forming the first metal 12 may comprise the steps of plating the first metal 12 and performing a CMP process. The first metal 12 may be formed by plating in the opening 14 of the first mold 11. The plating material may be the same as the material constituting the body 110 as described above. Subsequently, the first metal 12 may be planarized through chemical mechanical polishing (CMP).

The step of removing the first mold 11 may be performed by removing the remaining PR on the side of the first metal 12 after forming the first metal 12. This allows the first body layer 10 to be formed. At this time, the first body layer 10 may include the vertical slit 120a.

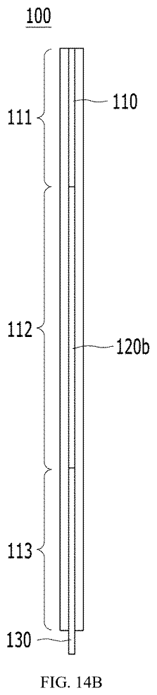

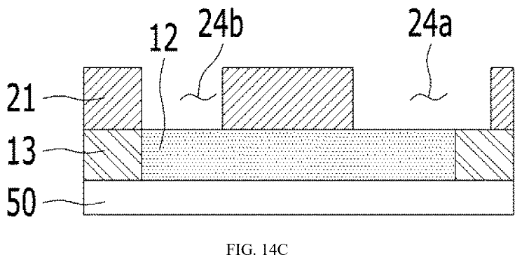

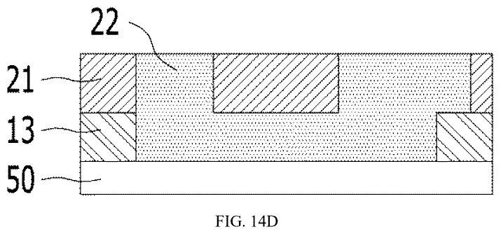

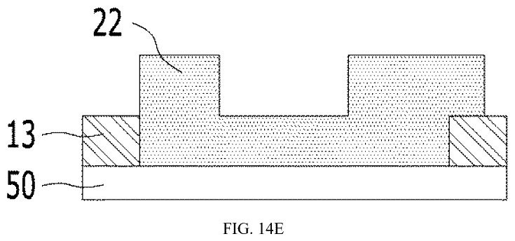

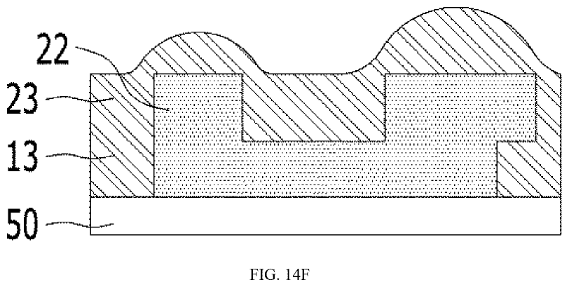

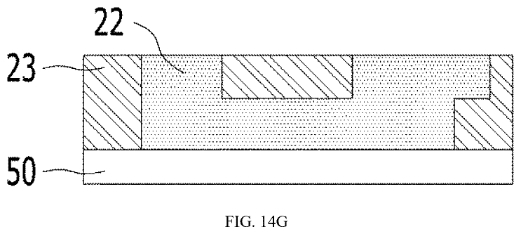

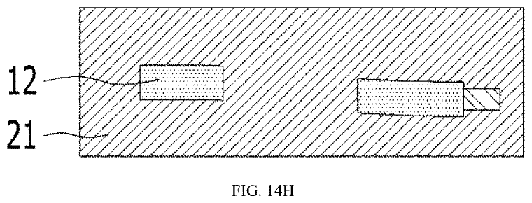

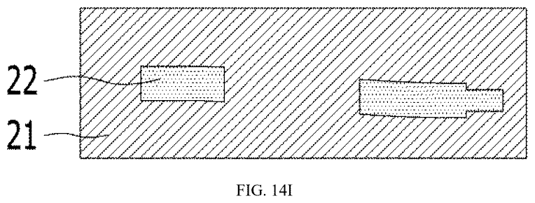

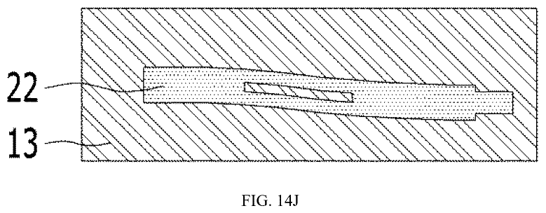

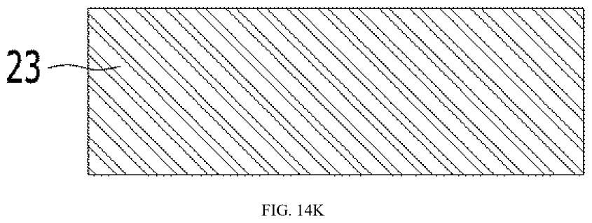

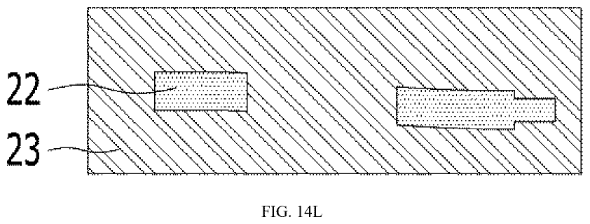

Referring to FIGS. 13f to 13g, FIGS. 13k to 13l, FIGS. 14c to 14e, and FIGS. 14h to 14j, the step of forming the second body layer 20 may comprise the steps of forming a first sacrificial layer 13, forming a second mold 21, forming a second metal 22, and removing the second mold 21.

The step of forming the first sacrificial layer 13 may comprise the steps of plating the first sacrificial layer 13 and performing a CMP process. The first sacrificial layer 13 may be provided to form the second mold 21 on the upper part. The first sacrificial layer 13 may be formed by plating to cover the side and upper surface of the first body layer 10. The first sacrificial layer 13 may be formed with a partially protruding shape as shown in FIG. 13f. Subsequently, the first sacrificial layer 13 and/or the first body layer 10 may be planarized through chemical mechanical polishing. The first sacrificial layer 13 may be made of a different metal material than the first body layer 10 to the third body layer 30. The first sacrificial layer 13 may be made of a material that can be selectively etched, such as copper (Cu) or a material containing copper. The same applies to the second sacrificial layer 23 described later.

The step of forming the second mold 21 may be performed through the steps of providing a PR layer, exposure, and development. Here, the second mold 21 may include at least one opening 24 corresponding to the second body layer 20. Since the second body layer 20 includes the horizontal slit 120b, the opening 24 may be formed as two or more separated parts. The opening 24 of the second mold 21 may be an area for forming the connection part and the contact tip 130.

The first opening 24a of the second mold 21 may be located on the first body layer 10 in the region of the third body 113. In this case, the first opening 24a may be formed to correspond to the second body layer 20 forming the region of the third body 113. This allows the connection part and/or the contact tip 130 forming the second body layer 20 to be formed on the first body layer 10.

Additionally, the first opening 24a of the second mold 21 may extend beyond the region of the third body 113 and be located on the first sacrificial layer 13. In this case, the first opening 24a may be formed to correspond to the contact tip 130.

The second opening 24b of the second mold 21 may be located on the first body layer 10 in the region of the first body 111. In this case, the second opening 24b may be formed to correspond to the second body layer 20 forming the region of the first body 111. At this time, since the connection part is formed in the second opening 24b, a probe pin 100 having an isolated slit 120 as shown in FIGS. 6a to 6c can be manufactured.

The second mold 21 may only comprise the first opening 24a. In this case, since the connection part is not formed, a probe pin 100 having an open slit 120 as shown in FIGS. 7a to 7c can be manufactured.

The process of comprising the second metal 22 may comprise a plating process of the second metal 22 and a CMP process. The second metal 22 may be formed by being plated in at least one opening 24 of the second mold 21. The material for plating may be the same as or different from the aforementioned first metal 12, but is not limited thereto. Subsequently, the second metal 22 may be planarized through chemical mechanical polishing.

The process of removing the second mold 21 may be performed by forming the second metal 22 and removing the remaining PR left on the side of the second metal 22. As a result, the second body layer 20 may be formed. At this time, the second body layer 20 may comprise the contact tip 130 and the horizontal slit 120b, and may further comprise the vertical slit 120a.

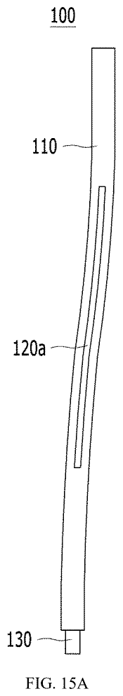

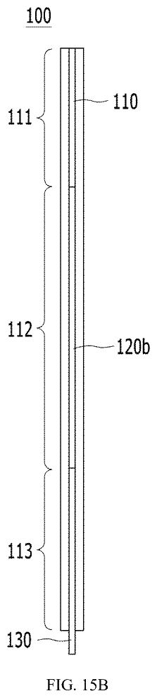

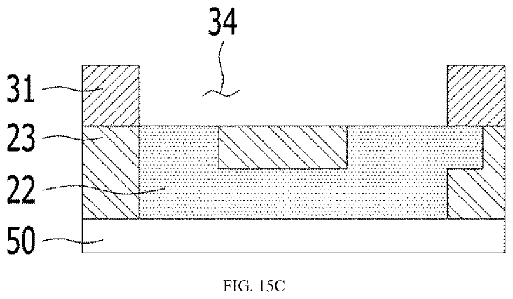

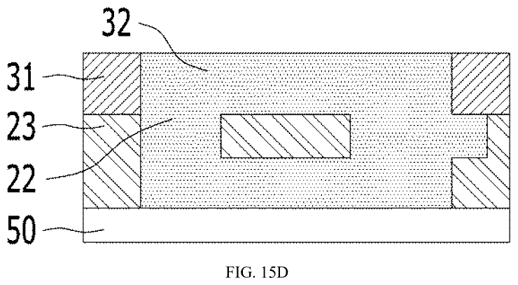

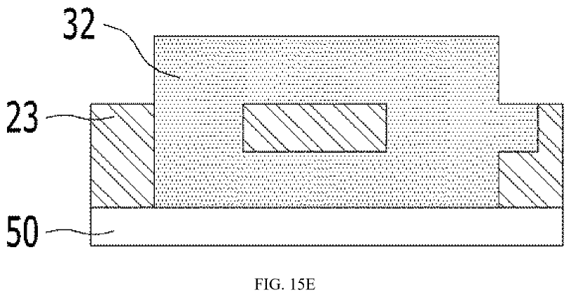

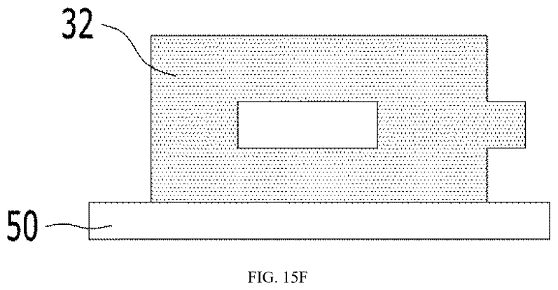

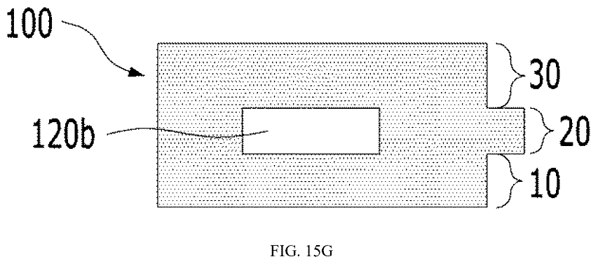

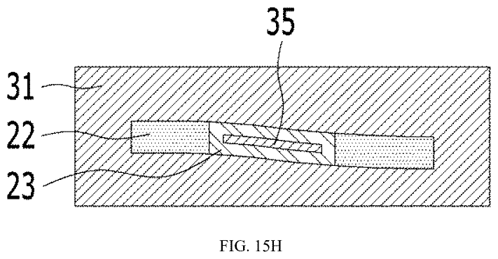

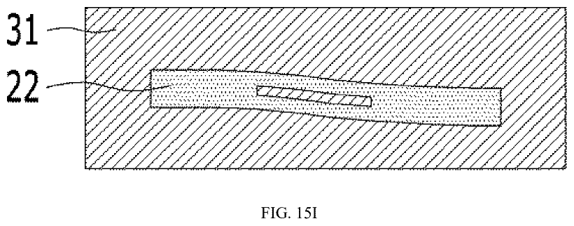

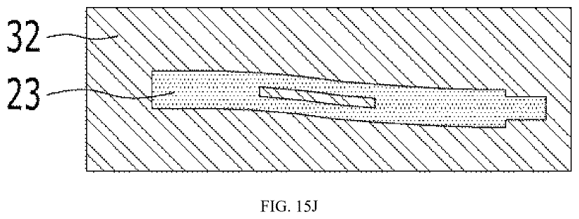

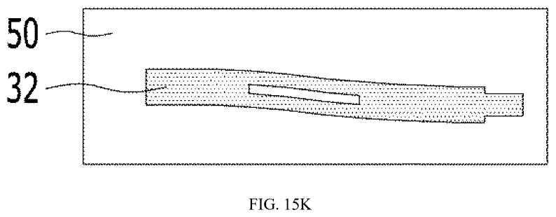

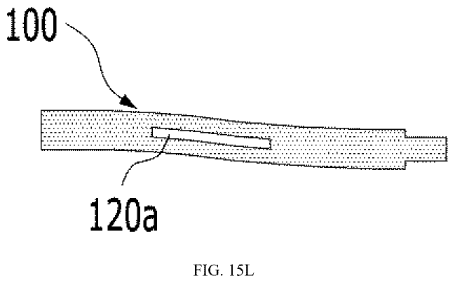

Referring to FIGS. 14f to 14g, FIGS. 14k to 14l, FIGS. 15c to 15e, and FIGS. 15h to 15j, the process of comprising the third body layer 30 may comprise the process of comprising the second sacrificial layer 23, the process of comprising the third mold 31, the process of comprising the third metal 32, and the process of removing the third mold 31.

The process of comprising the second sacrificial layer 23 may comprise a plating process of the second sacrificial layer 23 and a CMP process. The second sacrificial layer 23 may be provided to form the third mold 31 on the upper part. The second sacrificial layer 23 may be formed by plating to cover the side and upper surface of the second body layer 20. The second sacrificial layer 23 may be formed with a portion protruding as shown in FIG. 14f. Subsequently, the second sacrificial layer 23 and/or the second body layer 20 may be planarized through chemical mechanical polishing.

The process of comprising the third mold 31 may be performed through the process of comprising the PR layer, the exposure process, and the development process. Here, the third mold 31 may comprise an opening 34 corresponding to the third body layer 30. In addition, the third mold 31 may comprise a vertical portion 35 corresponding to the vertical slit 120a.

The process of comprising the third metal 32 may comprise a plating process of the third metal 32 and a CMP process. The third metal 32 may be formed by being plated in the opening 34 of the third mold 31. The material for plating may be the same as the aforementioned first metal 12 and/or the second metal 22, but is not limited thereto. Subsequently, the third metal 32 may be planarized through chemical mechanical polishing.

The process of removing the third mold 31 may be performed by forming the third metal 32 and removing the remaining PR left on the side of the third metal 32. As a result, the third body layer 30 may be formed. At this time, the third body layer 30 may comprise the vertical slit 120a.

Referring to FIGS. 15f to 15g, and FIGS. 15k to 15l, the process of separating the first body layer 10 to the third body layer 30 may comprise the process of removing the sacrificial layer and the process of removing the base substrate 50.

The process of removing the sacrificial layer may be performed by removing the first sacrificial layer 13 located on the side of the first body layer 10 and the second sacrificial layer 23 located on the side and horizontal slit 120b of the second body layer 20.

The process of removing the base substrate 50 may be performed by removing the base substrate 50 located under the first body layer 10. In addition, the process of removing the sacrificial layer and the process of removing the base substrate 50 may be performed simultaneously. As a result, the manufacturing process of the probe pin 100 may be completed.

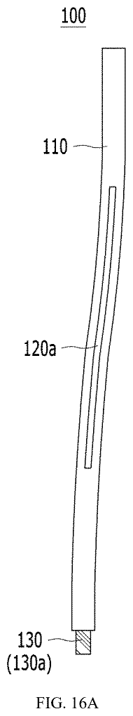

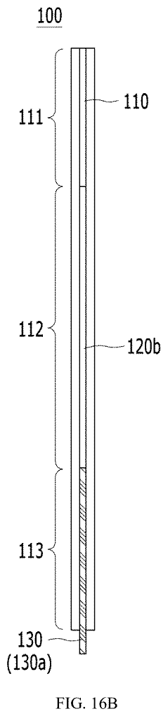

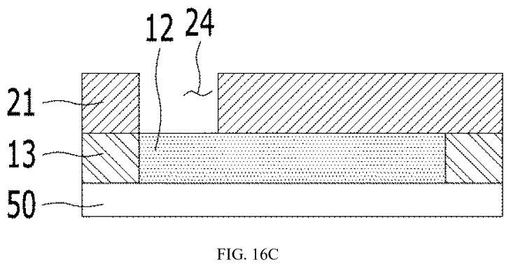

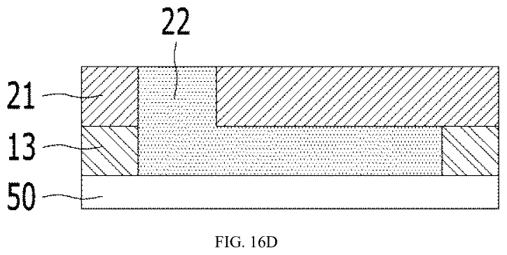

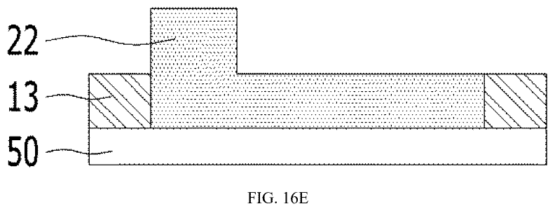

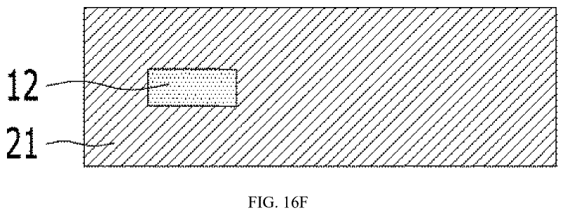

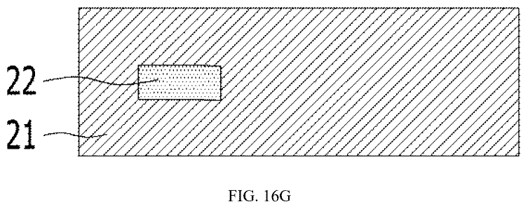

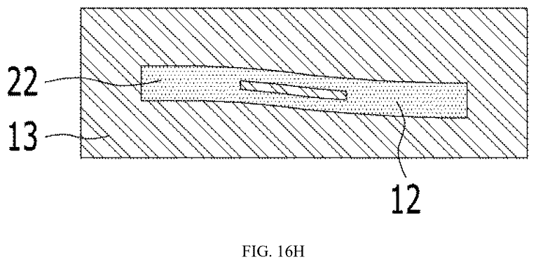

FIGS. 16a to 18l are diagrams showing the manufacturing method of the probe pin 100 according to the embodiment of the present invention.

Referring to FIGS. 16a and 16b, the probe pin 100 according to the embodiment of the present invention may comprise the body 110 and the slit 120. The body 110 may comprise the first body 111 to the third body 113, and the slit 120 may comprise the vertical slit 120a and the horizontal slit 120b. The probe pin 100 may further comprise a contact tip 130 located in the end region of the third body 113 and contacting the object to be inspected. Furthermore, the contact tip 130 may be made of a material different from the body 110 or may comprise a rhodium layer 130a, 22a made of a material comprising rhodium.

Referring to FIGS. 16c to 16h, FIGS. 17c to 17l, and FIGS. 18c to 18l, the manufacturing method of the probe pin 100 according to the embodiment of the present invention may comprise the process of preparing the base substrate 50; the process of comprising the first body layer 10 on the base substrate 50; the process of comprising the second body layer 20 on the first body layer 10; the process of comprising the third body layer 30 on the second body layer 20; and the process of separating the first body layer 10 to the third body layer 30.

In this embodiment, the process of comprising the first body layer 10 is the same as the aforementioned process, so the description will be omitted.

Referring to FIGS. 13f to 13g, FIGS. 13k to 13l, FIGS. 16c to 16h, FIGS. 17c to 17e, and FIGS. 17h to 17j, the process of comprising the second body layer 20 may comprise the process of comprising the first sacrificial layer 13, the process of comprising the second-1 mold 21, the process of comprising the connection part 22, the process of removing the second-1 mold 21, the process of comprising the second-2 mold 21, the process of comprising the contact tip 130, and the process of removing the second-2 mold 21.

The process of comprising the first sacrificial layer 13 may comprise a plating process of the first sacrificial layer 13 and a CMP process. The first sacrificial layer 13 may be provided to form the second mold 21 on the upper part. The first sacrificial layer 13 may be formed by plating to cover the side and upper part of the first body layer 10. The first sacrificial layer 13 may be formed with a portion protruding as shown in FIG. 13f. Subsequently, the first sacrificial layer 13 and/or the first body layer 10 may be planarized through chemical mechanical polishing.

The process of comprising the second-1 mold 21 may be performed through the process of comprising the PR, the exposure process, and the development process. Here, the second-1 mold 21 may comprise an opening 24 corresponding to the second body layer 20. The opening 24 of the second-1 mold 21 may be a region for forming the connection part 22.

The opening 24 of the second-1 mold 21 may be located on the first body layer 10 in the region of the first body 111. In this case, the opening 24 may be formed to correspond to the second body layer 20 forming the region of the first body 111. As a result, the connection part 22 forming the second body layer 20 may be formed on the first body layer 10.

The process of comprising the connection part 22 may comprise a plating process of the connection part and a CMP process. The connection part 22 may be formed by being plated in the opening 24 of the second-1 mold 21. The material for plating may be the same as or different from the aforementioned first metal 12, but is not limited thereto. Subsequently, the connection part may be planarized through chemical mechanical polishing.

The process of removing the second-1 mold 21 may be performed by forming the connection part 22 and removing the remaining PR left on the side of the connection part 22. As a result, the connection part 22 of the second body layer 20 may be formed.

The process of comprising the second-2 mold 21 may be performed through the process of comprising the PR layer, the exposure process, and the development process. Here, the second-2 mold 21 may comprise an opening 24 corresponding to the second body layer 20. The opening 24 of the second-2 mold 21 may be a region for forming the contact tip 130, 22a.

The opening 24 of the second-2 mold 21 may be located on the first body layer 10 in the region of the third body 113. In this case, the opening 24 may be formed to correspond to the second body layer 20 forming the region of the third body 113. As a result, the contact tip 130 forming the second body layer 20 may be formed on the first body layer 10.

In addition, the opening 24 of the second-2 mold may extend beyond the region of the third body 113 and be located on the first sacrificial layer 13. In this case, the opening 24 may be formed to correspond to the contact tip 130. That is, the contact tip 130 may be provided on the region including the boundary of the first body layer 10 and the first sacrificial layer 13. As a result, the contact tip 130 forming the second body layer 20 may be formed to protrude beyond the cross-section of the first body layer 10 on the first body layer 10.

The process of providing the contact tip 130 may include a plating process for the contact tip 130 and a CMP process. The contact tip 130 may be formed by plating in the opening 24 of the second mold 21. The plating material may be different from the aforementioned first metal 12. Additionally, it may also differ from the material of the connection part 22. Specifically, the plating material may be a material with high hardness, such as rhodium. That is, the contact tip 130 may include a rhodium layer 22a. Conversely, the plating material may be the same as the first metal 12 and/or the connection part 22. In other words, the plating material is not limited to a specific material.

The process of removing the second mold 21 may be performed by forming the contact tip 130 and removing the remaining PR on the side of the contact tip 130. As a result, the contact tip 130 of the second body layer 20 may be formed. That is, the second body layer 20 may be completed.

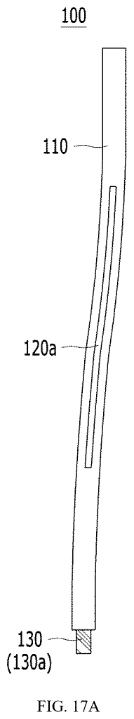

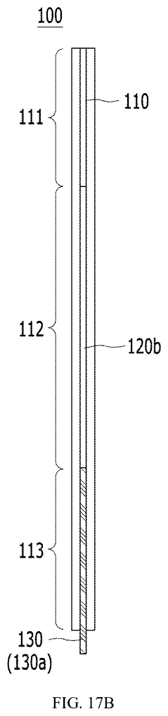

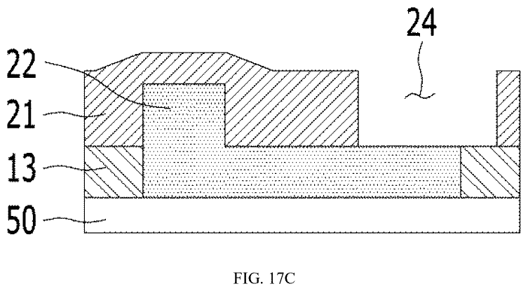

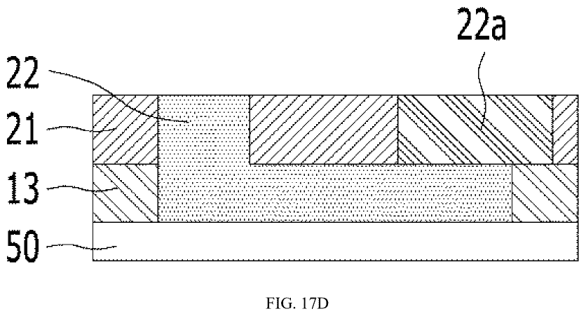

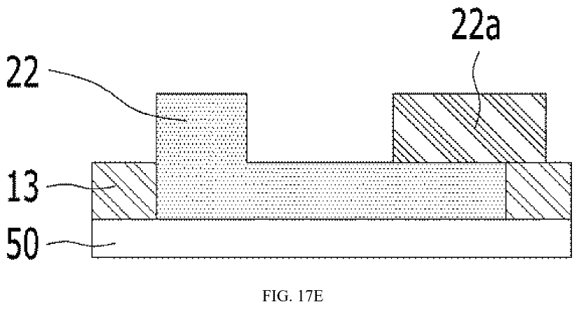

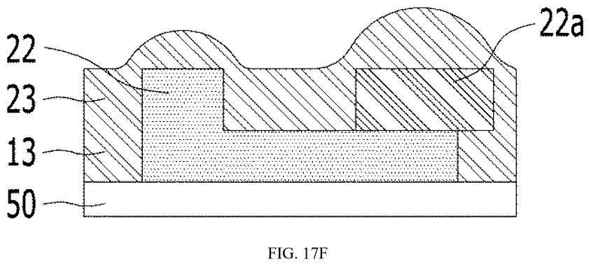

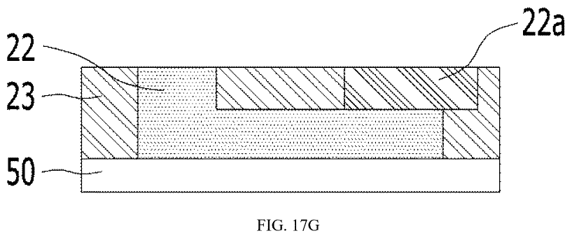

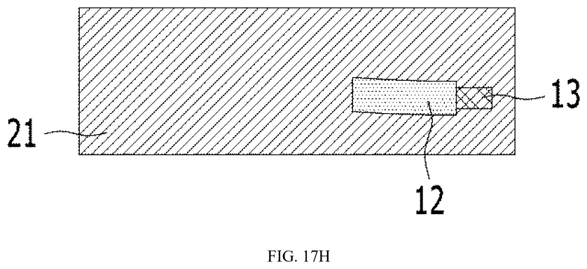

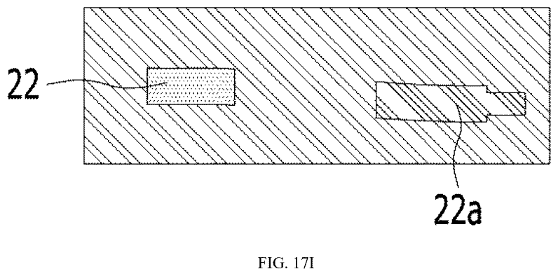

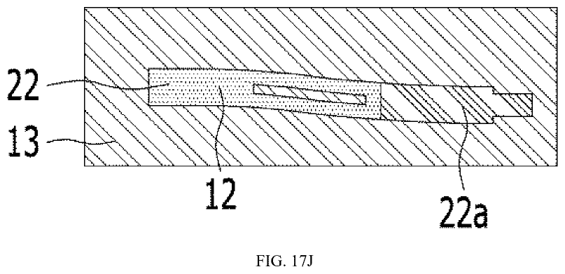

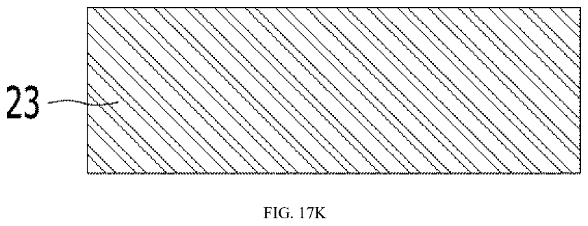

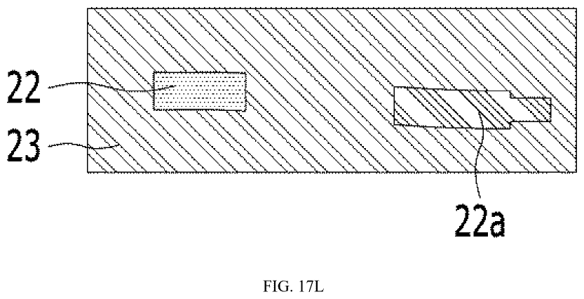

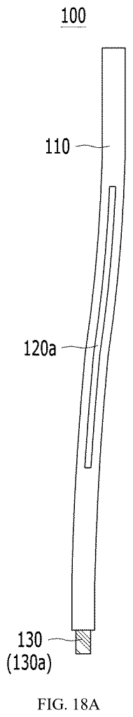

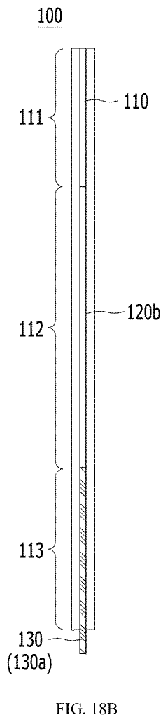

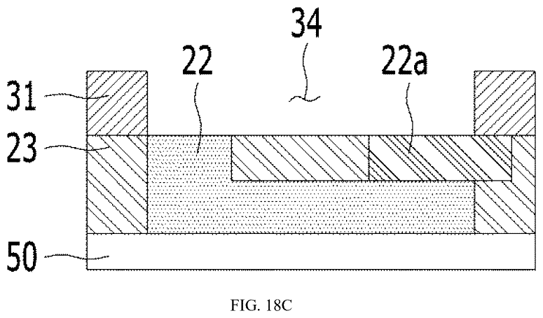

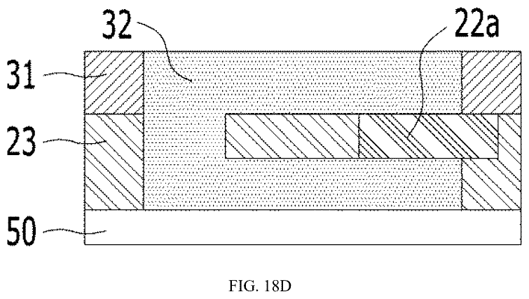

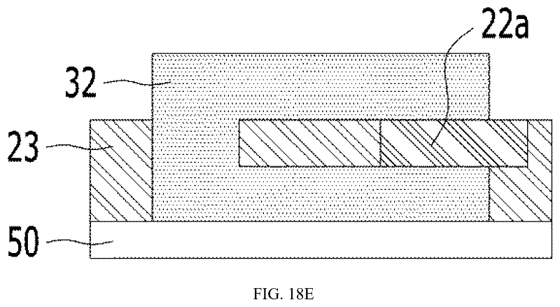

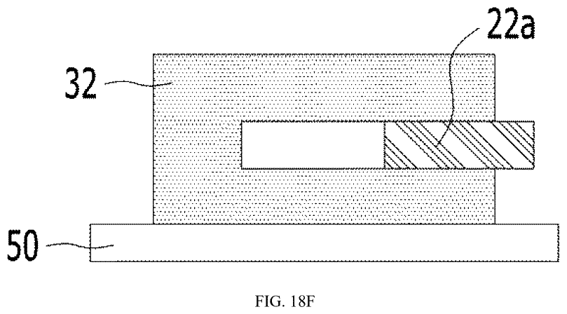

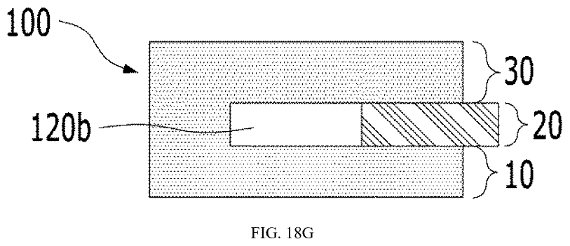

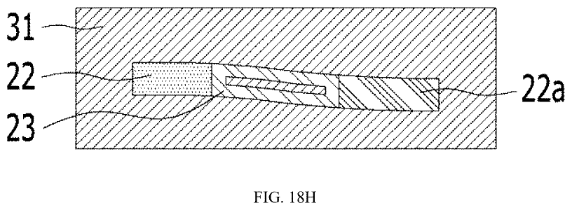

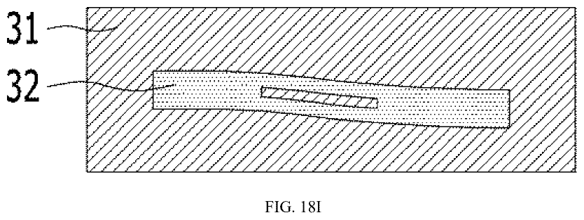

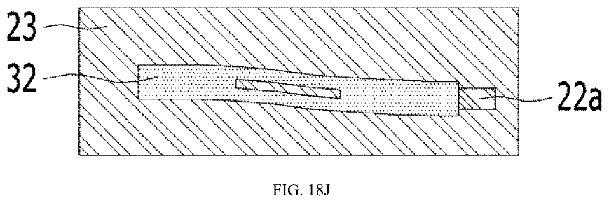

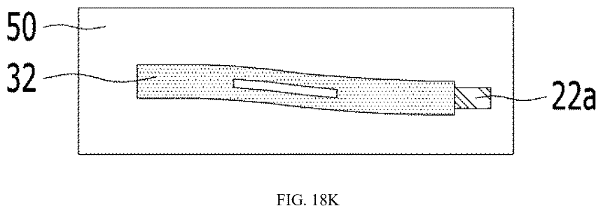

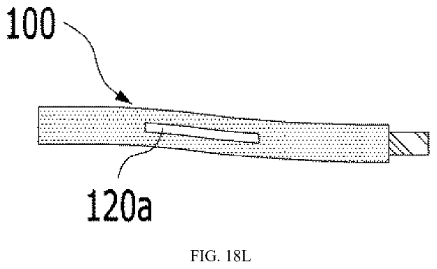

Referring to FIGS. 17f to 17g, FIGS. 17k to 17l, and FIGS. 18c to 18l, the process of providing the third body layer 30 and the process of separating the first body layer 10 to the third body layer 30 are the same as the aforementioned processes, and thus their description will be omitted.

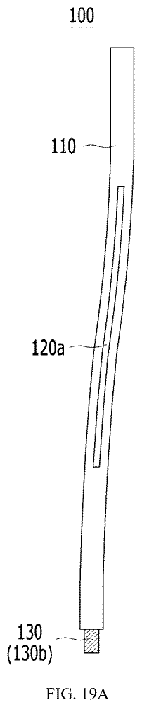

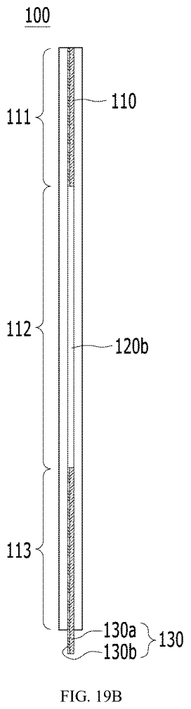

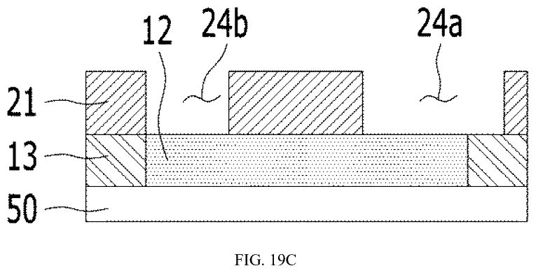

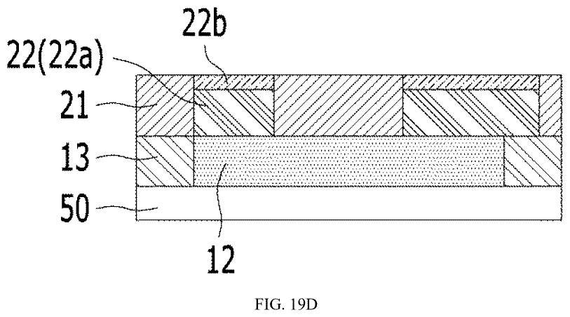

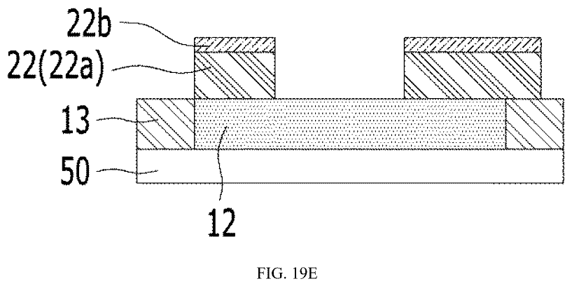

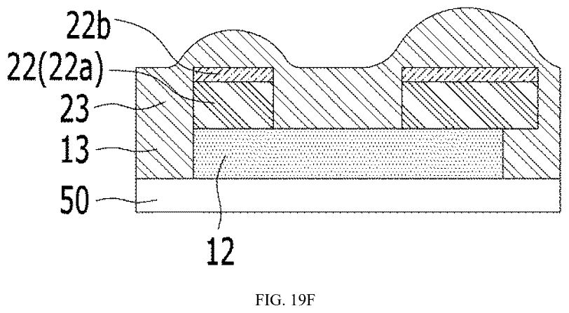

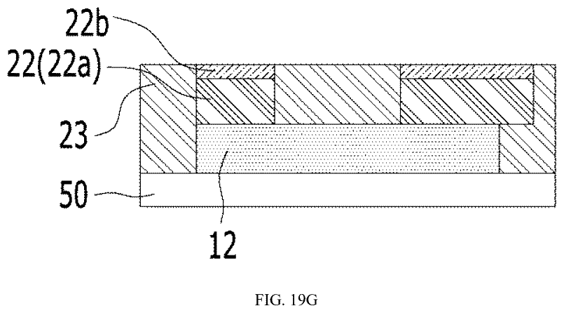

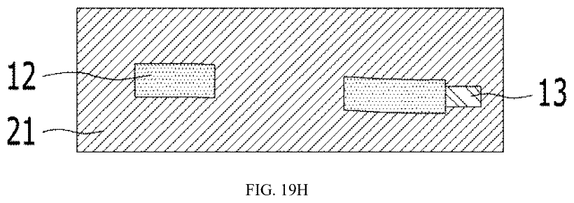

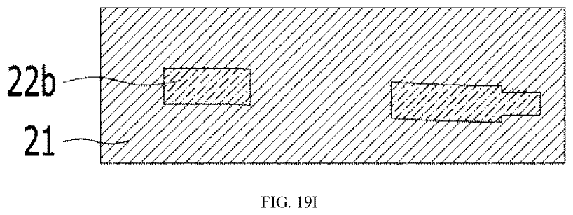

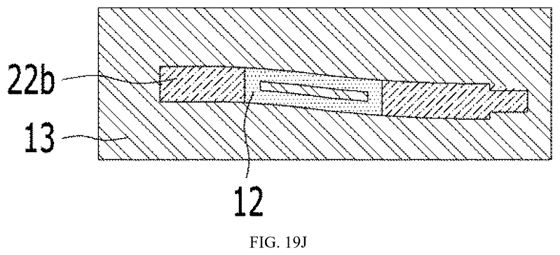

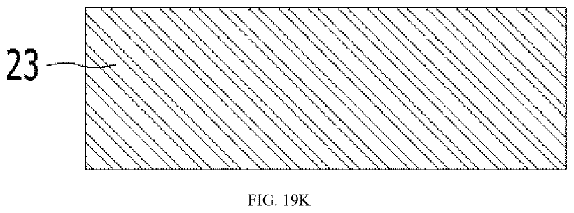

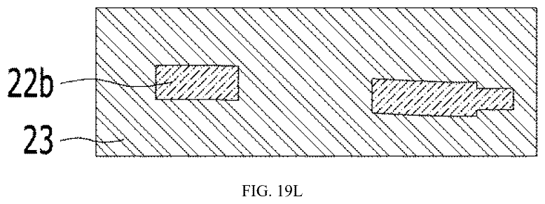

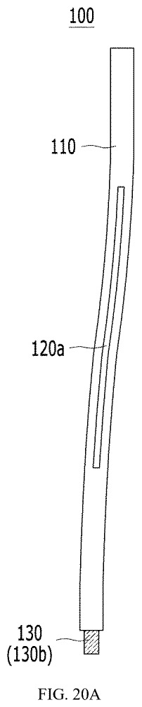

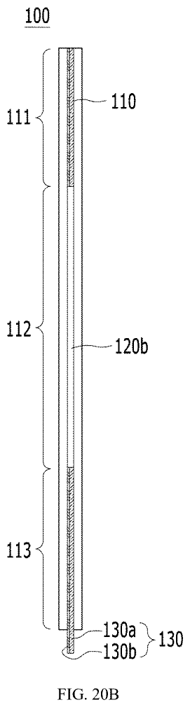

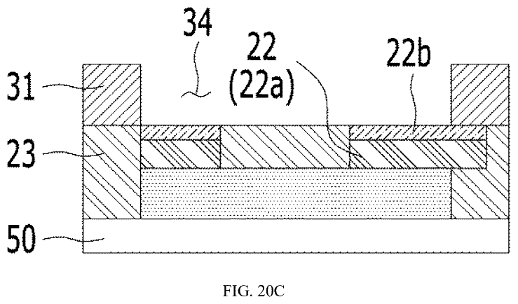

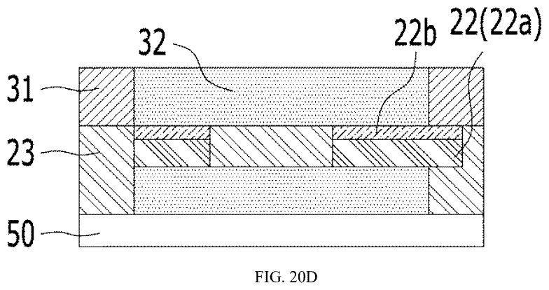

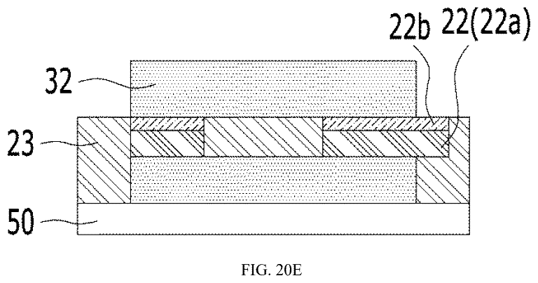

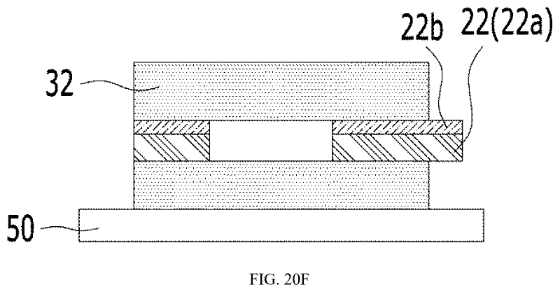

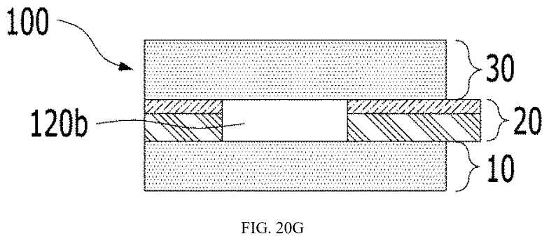

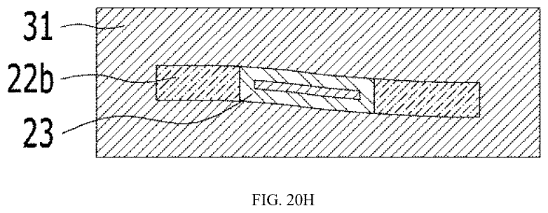

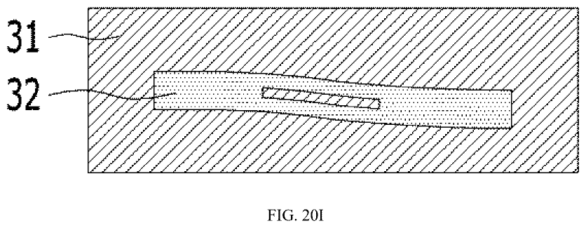

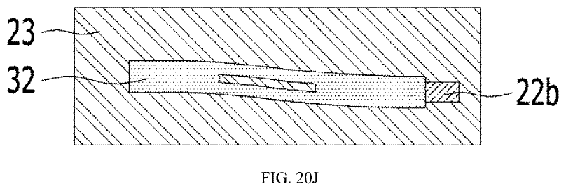

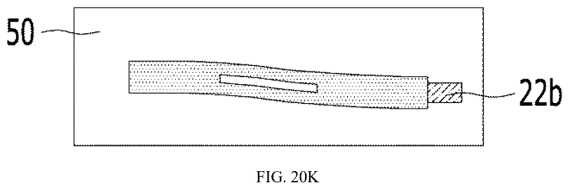

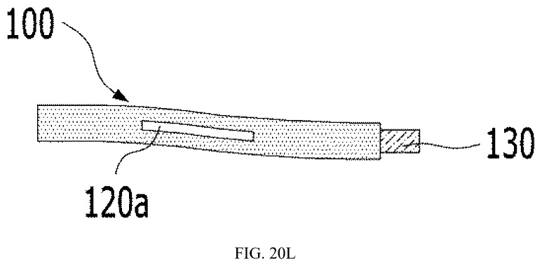

FIGS. 19a to 20l illustrate the manufacturing method of the probe pin 100 according to an embodiment of the present invention.

Referring to FIGS. 19a and 19b, the probe pin 100 according to an embodiment of the present invention may comprise a body 110 and a slit 120. The body 110 may comprise the first body 111 to the third body 113, and the slit 120 may comprise a vertical slit 120a and a horizontal slit 120b. The probe pin 100 may further comprise a contact tip 130 located in the end region of the third body 113. Furthermore, the contact tip 130 may be made of a material different from the body 110. For example, the contact tip 130 may include a rhodium layer 130a, 22a and a protective layer 130b, 22b provided on the rhodium layer 130a, 22a.

Referring to FIGS. 19c to 19l and FIGS. 20c to 20l, the manufacturing method of the probe pin 100 according to an embodiment of the present invention may comprise the process of providing a base substrate 50; the process of providing the first body layer 10 on the base substrate 50; the process of providing the second body layer 20 on the first body layer 10; the process of providing the third body layer 30 on the second body layer 20; and the process of separating the first body layer 10 to the third body layer 30.

In this embodiment, the process of providing the first body layer 21 is the same as the aforementioned process, and thus its description will be omitted.

Referring to FIGS. 13f to 13g, FIGS. 13k to 13l, FIGS. 19c to 19e, and FIGS. 19h to 19j, the process of providing the second body layer 20 may comprise the process of providing the first sacrificial layer 13, the process of providing the second mold 21, the process of providing the second metal 22, the process of providing the protective layer 22b, and the process of removing the second mold 21.

The process of providing the first sacrificial layer 13 may include a plating process for the first sacrificial layer 13 and a CMP process. The first sacrificial layer 13 may be provided to form the second mold 21 on its upper part. The first sacrificial layer 13 may be formed by plating to cover the side and upper parts of the first body layer 10. The first sacrificial layer 13 may be formed with a partially protruding portion as shown in FIG. 13f. Subsequently, the first sacrificial layer 13 and/or the first body layer 10 may be planarized through chemical mechanical polishing.

The process of providing the second mold 21 may be performed through a PR providing process, an exposure process, and a development process. Here, the second mold 21 may include at least one opening 24 corresponding to the second body layer 20. The opening 24 of the second mold 21 may be a region for forming the connection part 22, 22a, 22b and the contact tip 130, 130a, 130b, 22a, 22b.

The first opening 24a of the second mold 21 may be formed to correspond to the second body layer 20 forming the region of the third body 113. As a result, the connection part 22, 22a, 22b and/or the contact tip 130, 130a, 130b, 22a, 22b forming the second body layer 20 may be formed on the first body layer 10.

Additionally, the first opening 24a of the second mold 21 may extend beyond the region of the third body 113 to be positioned on the first sacrificial layer 13. In this case, the first opening 24a may be formed to correspond to the contact tip 130.

The second opening 24b of the second mold 21 may be formed to correspond to the second body layer 20 forming the region of the first body 111. At this time, since the connection part 22, 22a, 22b is formed in the second opening 24b, a probe pin 100 having an isolated slit 120 as shown in FIGS. 6a to 6c may be manufactured.

The second mold 21 may include only the first opening 24a. In this case, since the connection part 22, 22a, 22b is not formed, a probe pin 100 having an open slit 120 as shown in FIGS. 7a to 7c may be manufactured.

The process of providing the second metal 22 may include a plating process for the second metal 22 and may further include a CMP process. The second metal 22 may be formed by plating in at least one opening 24 of the second mold 21. The plating material may be of a different type from the aforementioned first metal 12, but its type is not limited. Subsequently, a CMP process may be performed, but it may be omitted depending on the material of the second metal 22. For example, the second metal 22 may be a rhodium material or a material containing rhodium. That is, the second metal 22 may be formed as a rhodium layer 130a, 22a.

The first opening 24a and the second opening 24b are not always filled with the same metal. That is, the second metal 22, 22a formed in the first opening 24a may have higher electrical conductivity than the second metal 22, 22a formed in the second opening 24b.

The process of providing the protective layer 22b may include a protective metal plating process and a CMP process. The protective metal may be formed by plating in at least one opening 24 of the second mold 21. The plating material may be of a different type from the second metal 22. Preferably, the protective metal may be made of a material with lower hardness than the second metal 22, but it is not limited thereto. Subsequently, the protective layer 22b may be planarized through chemical mechanical polishing.

The contact tip 130 may include the second metal 22 and the protective layer 22b positioned on the second metal 22.

When the second metal 22 includes rhodium or a rhodium layer 22a, the protective layer 22b may be provided on the second metal 22 before the CMP process due to the high risk of breakage during the polishing process. That is, the second metal 22 may be plated, and the protective metal may be plated without a planarization process.

By providing the protective layer 22b on the second metal 22 including rhodium or a rhodium layer 22a without planarizing the second metal 22, and planarizing the protective layer 22b, the second metal 22 including rhodium or a rhodium layer 22a may be protected. Since rhodium has high strength and high electrical conductivity, when used as the contact tip 130, it can increase the current carrying capacity of the probe pin 100. Furthermore, a probe pin 100 including a rhodium layer 22a can be easily manufactured.

The process of removing the second mold 21 may be performed by forming the second metal 22 and the protective layer 22b and removing the remaining PR on the side of the second metal 22 and the protective layer 22b. As a result, the second body layer 20 may be formed. At this time, the second body layer 20 may include the contact tip 130 and the horizontal slit 120b.

Referring to FIGS. 19f to 19g, FIGS. 19k to 191, FIGS. 20c to 20e, and FIGS. 20h to 20j, the process of providing the third body layer 30 may include the process of providing the second sacrificial layer 23, the process of providing the third mold 31, the process of providing the third metal 32, and the process of removing the third mold 31. The process of providing the third body layer 30 is the same as the aforementioned process, and thus its description will be omitted.

Referring to FIGS. 20f to 20g and FIGS. 20k to 20l, the process of separating the first body layer 10 to the third body layer 30 may include a sacrificial layer removal process and a base substrate 50 removal process. The process of separating the first body layer 10 to the third body layer 30 is the same as the aforementioned process, and thus its description will be omitted.

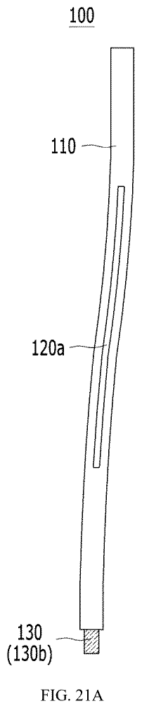

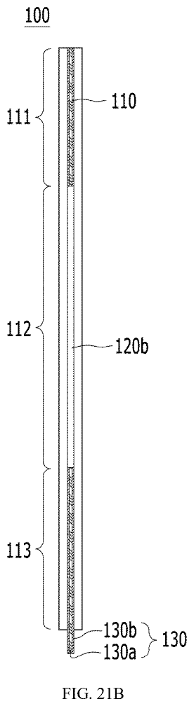

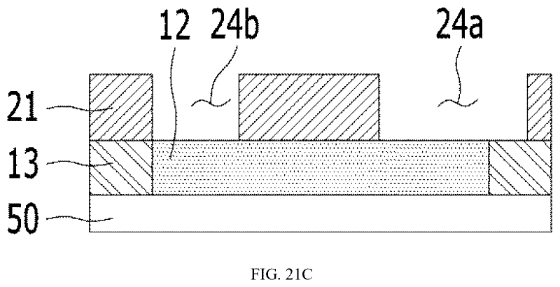

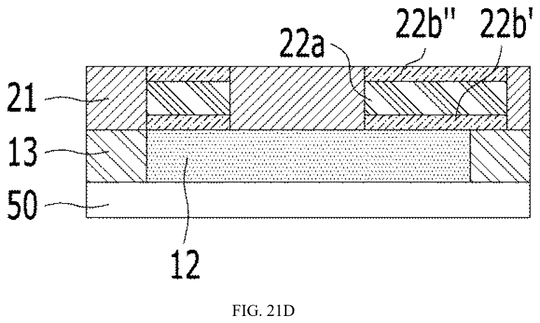

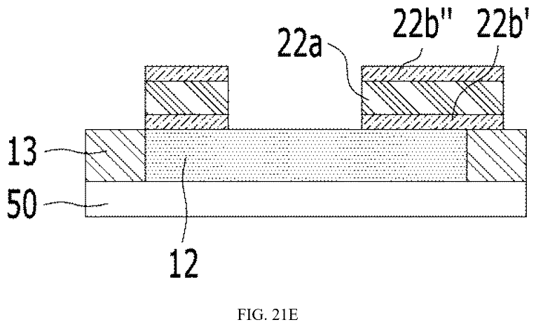

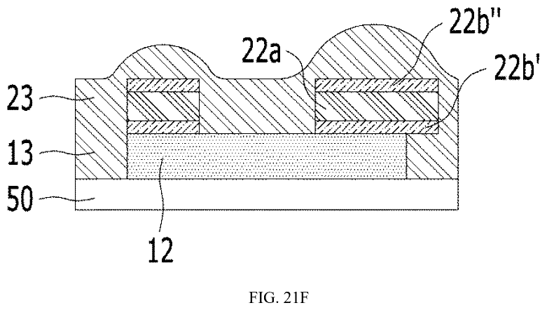

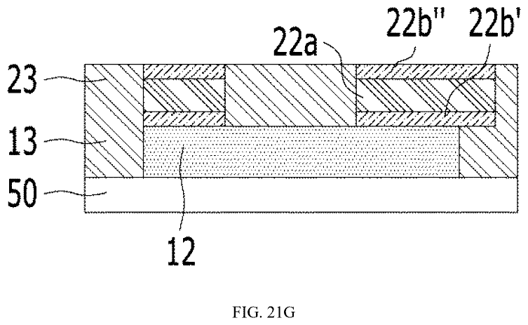

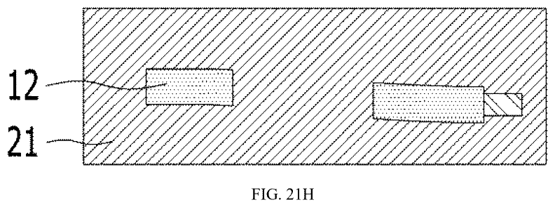

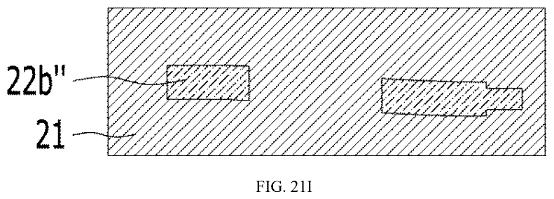

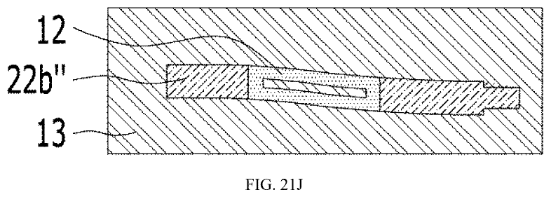

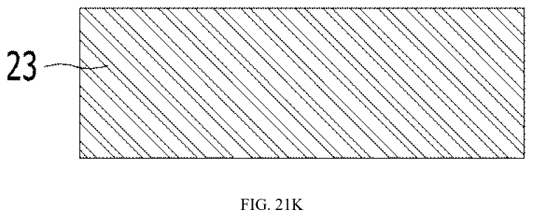

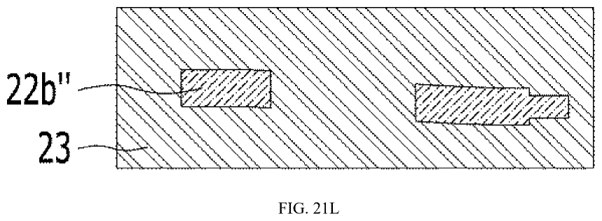

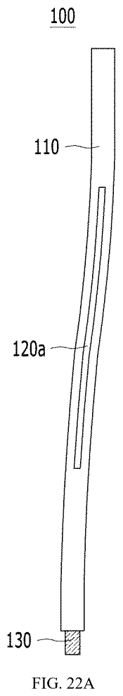

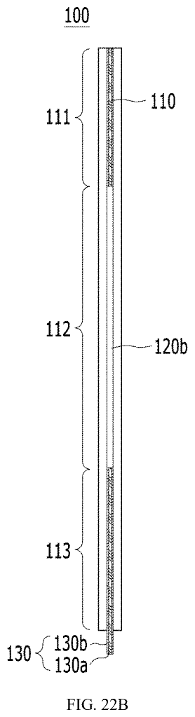

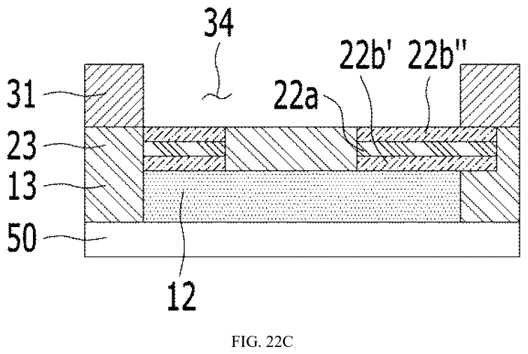

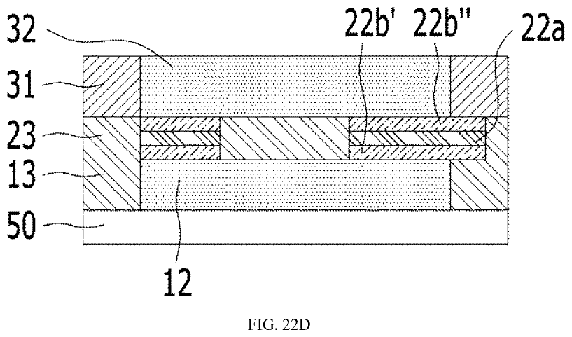

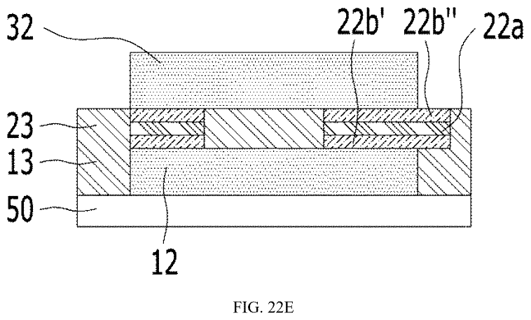

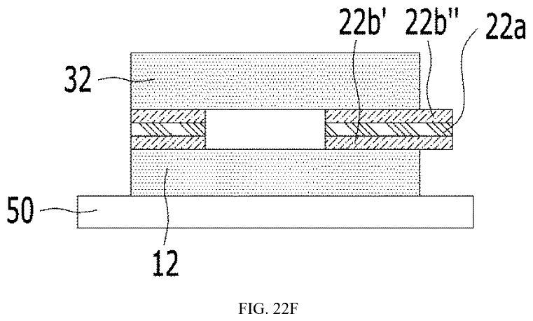

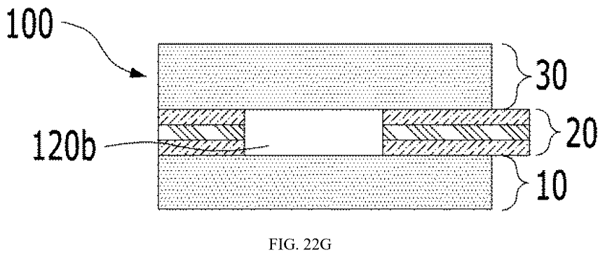

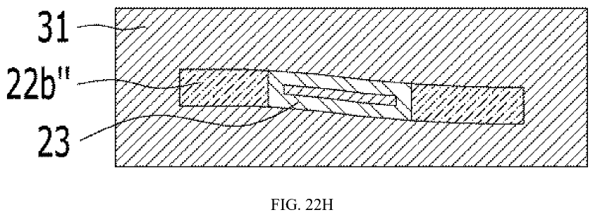

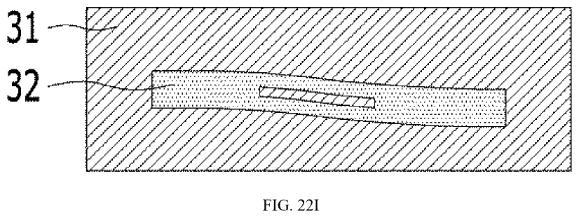

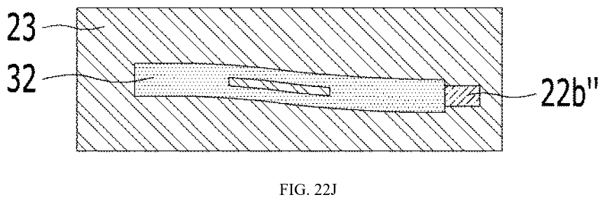

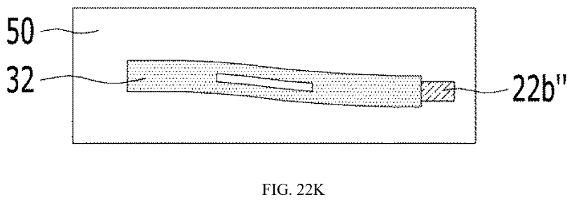

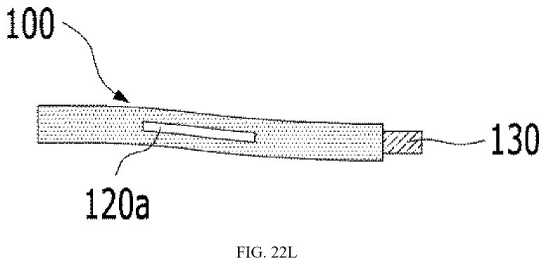

FIGS. 21a to 22l illustrate the manufacturing method of the probe pin 100 according to an embodiment of the present invention.

Referring to FIGS. 21a and 21b, the probe pin 100 according to an embodiment of the present invention may comprise a body 110 and a slit 120. The body 110 may comprise a first body 111 to a third body 113, and the slit 120 may comprise a vertical slit 120a and a horizontal slit 120b. The probe pin 100 may further comprise a contact tip 130 located in the end region of the third body 113. Furthermore, the contact tip 130 may be made of a material different from the body 110. For example, the contact tip 130 may comprise a first protective layer 22b′, a rhodium layer 22a provided on the first protective layer 22b′, and a second protective layer 22b″ provided on the rhodium layer 22a.

Referring to FIGS. 21c to 21l and FIGS. 22c to 22l, the method for manufacturing the probe pin 100 according to an embodiment of the present invention may comprise the steps of: preparing a base substrate 50; providing a first body layer 10 on the base substrate 50; providing a second body layer 20 on the first body layer 10; providing a third body layer 30 on the second body layer 20; and separating the first body layer 10 to the third body layer 30.

In this embodiment, the step of providing the first body layer 10 is the same as the above-described process, so the description will be omitted.

Referring to FIGS. 13f to 13g, FIGS. 13k to 13l, FIGS. 21c to 21e, and FIGS. 21h to 21j, the step of providing the second body layer 20 may comprise the steps of: providing a first sacrificial layer 13, providing a second mold 21, providing a first protective layer 22b′, providing a second metal 22, providing a second protective layer 22b″, and removing the second mold 21.

The step of providing the first sacrificial layer 13 may comprise a plating process for the first sacrificial layer 13 and a CMP process. The first sacrificial layer 13 may be provided to form the second mold 21 on its upper part. The first sacrificial layer 13 may be formed by plating to cover the side and upper parts of the first body layer 10. The first sacrificial layer 13 may be formed with a portion protruding as shown in FIG. 13f. Subsequently, the first sacrificial layer 13 and/or the first body layer 10 may be planarized through chemical mechanical polishing.

The step of providing the second mold 21 may be performed through a PR providing process, an exposure process, and a development process. Here, the second mold 21 may comprise at least one opening 24 corresponding to the second body layer 20. The opening 24 of the second mold 21 may be a region for forming the connection part 22a, 22b and the contact tip 22a, 22b.

The second mold 21 may form a first opening 24a and/or a second opening 24b. Regarding this, the description is the same as above, so it will be omitted.

The step of providing the first protective layer 22b′ may comprise a first protective metal plating process and may further comprise a CMP process. The first protective layer 22b′ may be formed by plating in at least one opening 24 of the second mold 21. The plating material may be the same as or different from the above-described first metal 12, but is not limited to the type. Subsequently, a CMP process may be performed, but it may also be omitted.

The step of providing the second metal 22 may comprise a second metal plating process and may further comprise a CMP process. The second metal 22 may be formed by plating in at least one opening 24 of the second mold 21. The plating material may be the same as or different from the first metal 12, but is not limited to the type. Subsequently, a CMP process may be performed, but it may also be omitted depending on the material of the second metal 22. The second metal 22 may be made of a rhodium layer 22a.

The first opening 24a and the second opening 24b are not always filled with the same metal, and the second metal 22 formed in the first opening 24a may have higher electrical conductivity than the second metal 22 formed in the second opening 24b.

The step of providing the second protective layer 22b″ may comprise a second protective metal plating process and a CMP process. The second protective metal may be formed by plating in at least one opening of the second mold 21. The plating material may be of a type different from the second metal 22. Preferably, it may be made of a material with a lower hardness than the second metal 22, but it is not limited thereto. Subsequently, the second protective layer 22b″ may be planarized through chemical mechanical polishing.

As described above, when the second metal 22 comprises rhodium, the second metal 22 may be protected by providing the second protective layer 22b″ on the second metal 22 without planarizing the second metal 22 and planarizing the second protective layer 22b″.

Rhodium has high strength and high electrical conductivity, so when used as the contact tip 130, it can increase the current carrying capacity of the probe pin 100. Furthermore, the probe pin 100 comprising the rhodium layer 22a can be easily manufactured.

Meanwhile, the protective layer 22b, the first protective layer 22b′, and the second protective layer 22b″ can increase the thickness of the contact tip 130 without increasing the thickness of the rhodium layer 22a. Increasing the thickness of the contact tip 130 can widen the width of the horizontal slit 120b, thereby increasing the flexibility of the body 110. However, rhodium is a relatively expensive material and may not be suitable for unlimited thickness increase. Therefore, by providing the first protective layer 22b′ and/or the second protective layer 22b″ below and/or above the rhodium layer 22a, the consumption of rhodium can be reduced while widening the width of the horizontal slit 120b and increasing the flexibility of the body 110. Additionally, when the first protective layer 22b′ and the second protective layer 22b″ are provided above and below the rhodium layer 22a, respectively, the rhodium layer 22a can be positioned at the center of the probe pin 100.

The step of removing the second mold 21 may be performed by removing the residual PR remaining on the sides of the first protective layer 22b′, the second metal 22, 22a, and the second protective layer 22b″ after forming the first protective layer 22b′, the second metal 22, 22a, and the second protective layer 22b″. Thus, the second body layer 20 can be formed. At this time, the second body layer 20 may comprise the contact tip 130 and the horizontal slit 120b.

Referring to FIGS. 21f to 21g, FIGS. 21k to 21l, FIGS. 22c to 22e, and FIGS. 22h to 22j, the step of providing the third body layer 30 may comprise the steps of: providing a second sacrificial layer 23, providing a third mold 31, providing a third metal 32, and removing the third mold 31. The step of providing the third body layer 30 is the same as described above, so the description will be omitted.

Referring to FIGS. 22f to 22g and FIGS. 22k to 22l, the step of separating the first body layer 10 to the third body layer 30 may comprise a sacrificial layer removal process and a base substrate 50 removal process. The step of separating the first body layer 10 to the third body layer 30 is the same as described above, so the description will be omitted.

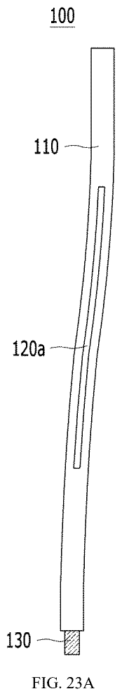

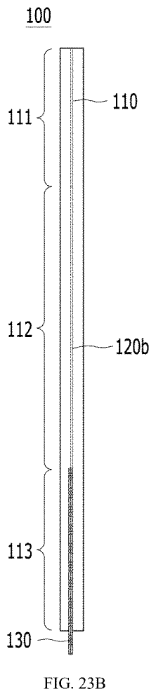

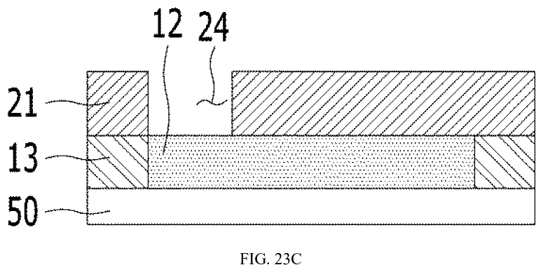

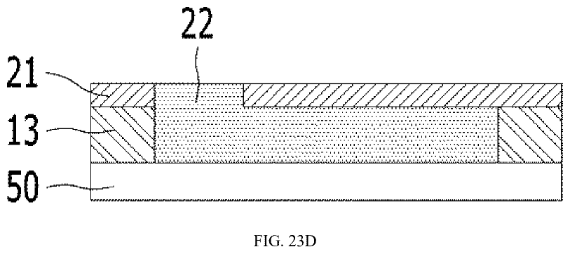

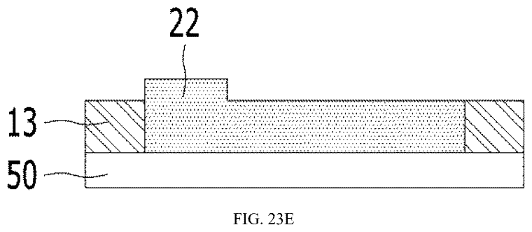

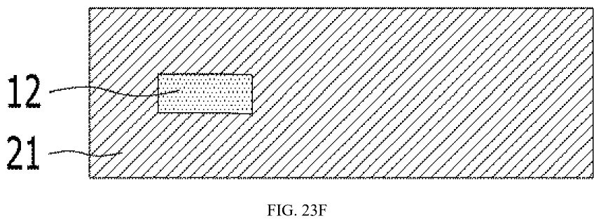

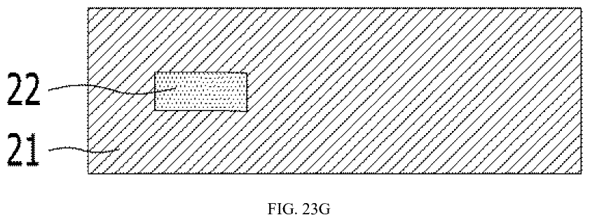

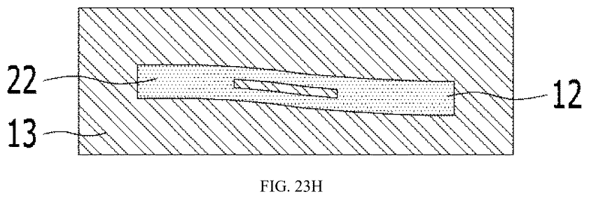

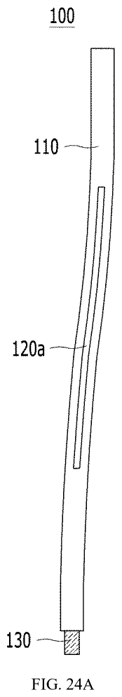

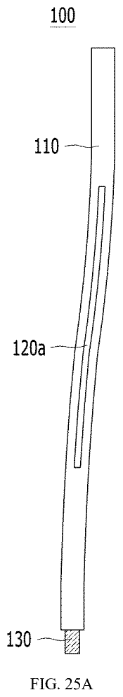

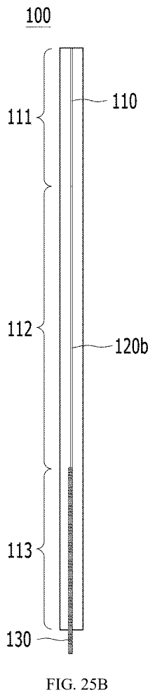

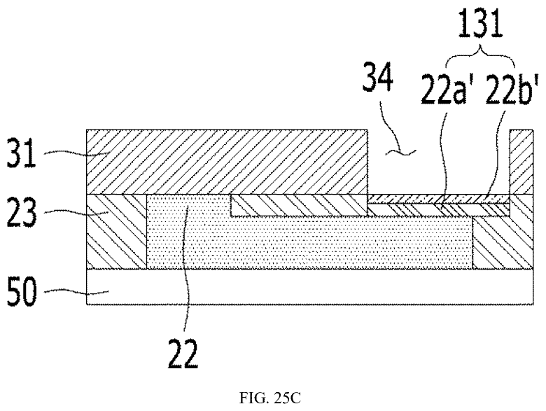

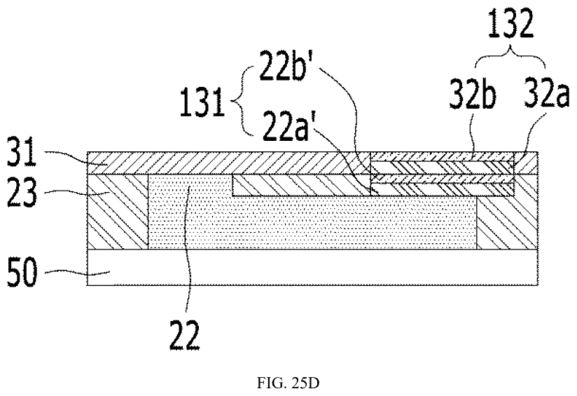

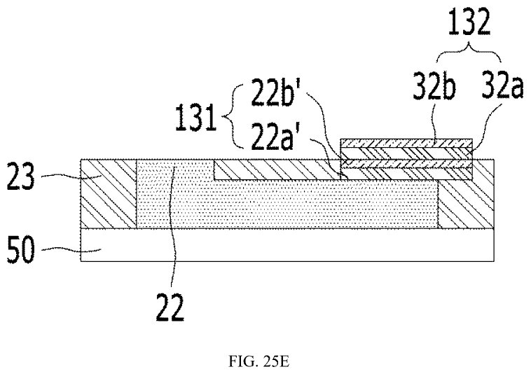

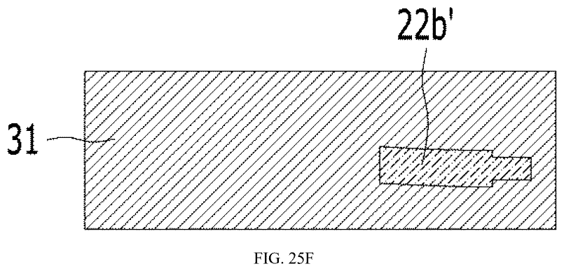

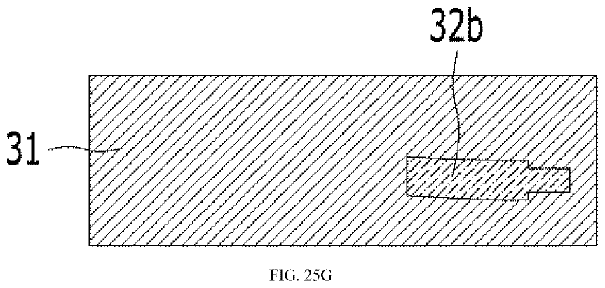

FIGS. 23a to 26l illustrate the method for manufacturing the probe pin 100 according to an embodiment of the present invention.

Referring to FIGS. 23a to 26l, the probe pin 100 according to an embodiment of the present invention may comprise a body 110 and a slit 120. The body 110 may comprise a first body 111 to a third body 113, and the slit 120 may comprise a vertical slit 120a and a horizontal slit 120b. The probe pin 100 may further comprise a contact tip 130 located in the end region of the third body 113. Furthermore, the contact tip 130 may be made of a material different from the body 110. For example, the contact tip 130 may comprise a first rhodium layer, a first protective layer 22b′, a second rhodium layer, and a second protective layer 32b. Here, the vertical width (thickness) of the horizontal slit 120b may be smaller than the height (thickness) of the contact tip 130.

Referring to FIGS. 23c to 23h, FIGS. 24c to 24l, FIGS. 25c to 25h, and FIGS. 26c to 26l, the method for manufacturing the probe pin 100 according to an embodiment of the present invention may comprise the steps of: preparing a base substrate 50; providing a first body layer 10 on the base substrate 50; providing a second body layer 20 on the first body layer 10; providing a third body layer 30 on the second body layer 20; and separating the first body layer 10 to the third body layer 30.

At this time, the contact tip 130 may comprise a first contact tip 131 provided in the second body layer 20 and a second contact tip 132 provided in the third body layer 30. Here, the thickness of the first contact tip 131 131 may be the same as the vertical width (thickness) of the horizontal slit 120b, and the thickness of the second contact tip 132 may be smaller than the thickness of the third body layer 30, but it is not limited to such a structure. At this time, the first contact tip 131 may comprise a first protective layer 22a and a first protective layer 22b′, and the second contact tip 132 may comprise a second protective layer 32a and a second protective layer 32b.

In this embodiment, the process up to providing the first body layer 10 is the same as the aforementioned process, and thus, the description will be omitted.

Referring to FIGS. 13f to 13g, FIGS. 13k to 13l, FIGS. 23c to 23h, FIGS. 24c to 24e, and FIGS. 24 h to 24 j, the process of providing the second body layer 20 may comprise the process of providing the first sacrificial layer 13, the process of providing the second-1 mold 21, the process of providing the connection part 22, the process of removing the second-1 mold 21, the process of providing the second-2 mold 21, the process of providing the first contact tip 131, and the process of removing the second-2 mold 21.

The process of providing the first sacrificial layer 13 may comprise a plating process and a CMP process for the first sacrificial layer 13. The first sacrificial layer 13 may be provided to form the second mold 21 on its upper part. The first sacrificial layer 13 may be formed by plating to cover the side and upper parts of the first body layer 10. The first sacrificial layer 13 may be formed with a portion protruding, as shown in FIG. 13f. Subsequently, the first sacrificial layer 13 and/or the first body layer 10 may be planarized through chemical mechanical polishing.

The process of providing the second-1 mold 21 may be performed through the processes of providing a PR layer, exposure, and development. Here, the second-1 mold may include an opening 24 corresponding to the second body layer 20. The opening 24 of the second-1 mold 21 may be an area for forming the connection part.

The opening 24 of the second-1 mold may be located on the first body layer 10 in the area of the first body 111. In this case, the opening 24 may be formed to correspond to the second body layer 20 forming the area of the first body 111. Thus, the connection part 22 forming the second body layer 20 may be formed on the first body layer 10.

The process of providing the connection part 22 may comprise a plating process and a CMP process for the connection part. The connection part 22 may be formed by plating in the opening 24 of the second-1 mold 21. The plating material may be the same as the aforementioned first metal 12, but is not limited thereto. Subsequently, the connection part 22 may be planarized through chemical mechanical polishing.

The process of removing the second-1 mold 21 may be performed by forming the connection part and removing the remaining PR left on the side of the connection part. Thus, the connection part 22 of the second body layer 20 may be formed.

The process of providing the second-2 mold 21 may be performed through the processes of providing a PR layer, exposure, and development. Here, the second-2 mold 21 may include an opening 24 corresponding to the second body layer 20. The opening 24 of the second-2 mold 21 may be an area for forming the first contact tip 131.

The opening 24 of the second-2 mold 21 may be located on the first body layer 10 in the area of the third body 113. In this case, the opening 24 may be formed to correspond to the second body layer 20 forming the area of the third body 113. Thus, the first contact tip 131 forming the second body layer 20 may be formed on the first body layer 10.

Additionally, the opening 24 of the second-2 mold 21 may extend beyond the area of the third body 113 to be located on the first sacrificial layer 13. In this case, the opening 24 may be formed to correspond to the contact tip 130. Thus, the first contact tip 131 forming the second body layer 20 may be formed to protrude beyond the cross-section of the first body layer 10.

The process of providing the first contact tip 131 may comprise a plating process for the first protective layer 22a, a plating process for the first protective layer 22b′, and a CMP process.

The first protective layer 22a may be formed by plating in the opening 24 of the second-2 mold 21. The plating material may include rhodium but is not limited thereto.

The first protective layer 22b′ may be formed by plating in the opening 24 of the second-2 mold 21. The plating material may be of a different type from the first protective layer 22a. Preferably, the first protective layer 22b′ may be made of a material with a lower hardness than the first protective layer 22a, but is not limited thereto. Subsequently, the first protective layer 22b′ may be planarized through chemical mechanical polishing.

When the first protective layer 22a includes a rhodium layer 22a, the first protective layer 22b′ may be provided on the first protective layer 22a before the CMP process due to the high risk of breakage during the polishing process. That is, the first protective layer 22a may be plated, and the first protective layer 22b′ may be plated without a planarization process.

The process of removing the second-2 mold 21 may be performed by forming the connection part 22 and the first contact tip 131 and removing the remaining PR left on the sides of the connection part 22 and the first contact tip 131. Thus, the second body layer 20 may be formed. At this time, the second body layer 20 may include the first contact tip 131 and the horizontal slit 120b.

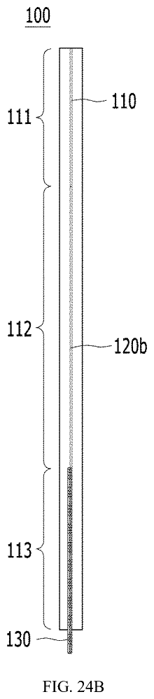

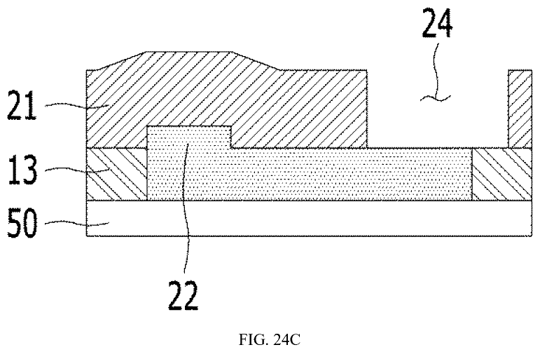

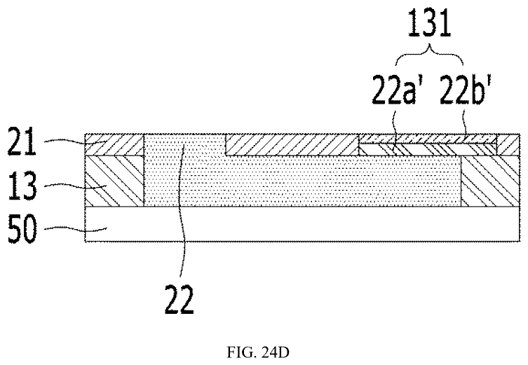

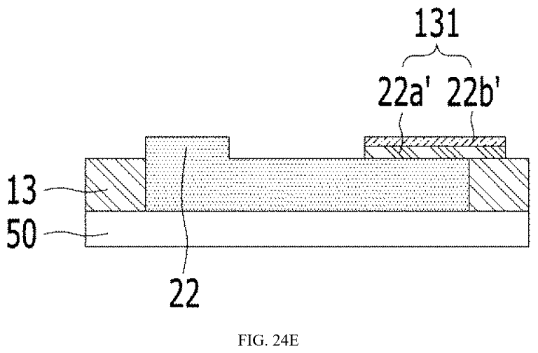

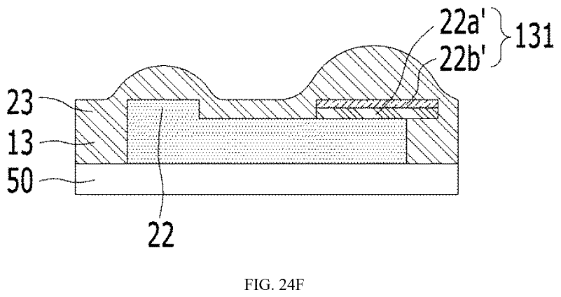

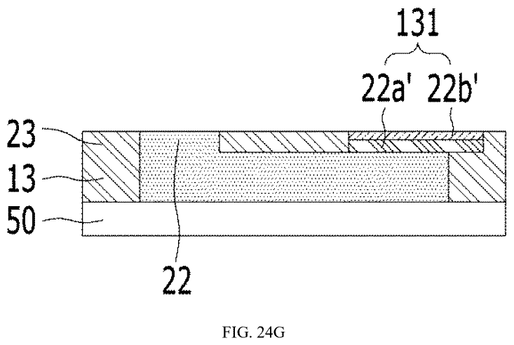

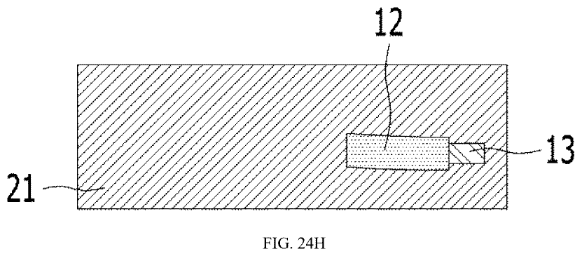

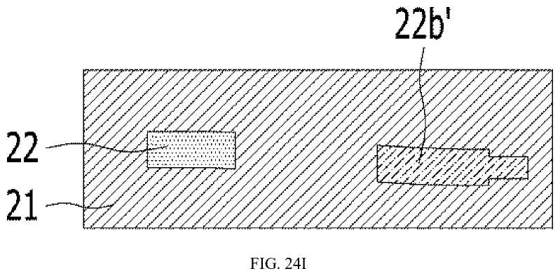

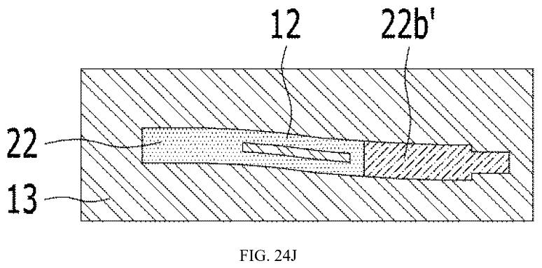

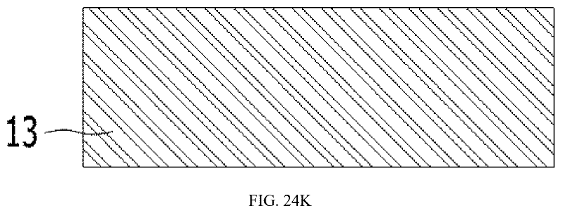

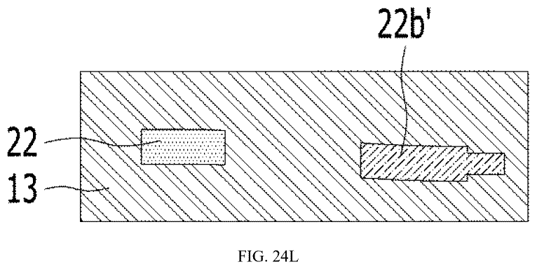

Referring to FIGS. 24f to 24g, FIGS. 24k to 24l, FIGS. 25c to 25h, FIGS. 26c to 26d, and FIGS. 26h to 26i, the process of providing the third body layer 30 may comprise the process of providing the second sacrificial layer 23, the process of providing the third-1 mold 31, the process of providing the second contact tip 132, the process of removing the third-1 mold 31, the process of providing the third-2 mold 31, the process of plating the third metal 32, and the process of removing the third-2 mold 31.

The process of providing the second sacrificial layer 23 is the same as described above, and thus, the description will be omitted.

The process of providing the third-1 mold 31 may be performed through the processes of providing a PR layer, exposure, and development. Here, the third-1 mold 31 may include an opening 34 corresponding to the second contact tip 132. The opening 34 of the third-1 mold 31 may be provided to be located above the first contact tip 131 of the second body layer 20. Thus, the second contact tip 132 may be formed without creating a step on the first contact tip 131.

The process of providing the second contact tip 132 may comprise a plating process for the second protective layer 32a, a plating process for the second protective layer 32b, and a CMP process.

The second protective layer 32a may be formed by plating in the opening 34 of the third-1 mold 31. The plating material may include rhodium but is not limited thereto.

The second protective layer 32b may be formed by plating in the opening 34 of the third-1 mold 31. The plating material may be of a different type from the second protective layer 32a. Preferably, the second protective layer 32b may be made of a material with a lower hardness than the second protective layer 32a, but is not limited thereto. Subsequently, the second protective layer 32b may be planarized through chemical mechanical polishing.

When the second protective layer 32a includes a rhodium layer 32a, the second protective layer 32b may be provided on the second protective layer 32a before the CMP process due to the high risk of breakage during the polishing process. That is, the second protective layer 32a may be plated, and the second protective layer 32b may be plated without a planarization process.

The process of removing the third-1 mold 31 may be performed by forming the second contact tip 132 and removing the remaining PR left on the sides of the second contact tip 132. Thus, the third body layer 30 may include a portion of the second contact tip 132. Additionally, the first contact tip 131 and the second contact tip 132 may be integrated to form a single contact tip 130.

The process of providing the third-2 mold 31 may be performed through the processes of providing a PR layer, exposure, and development. Here, the third-2 mold 31 may include an opening 34 corresponding to the third body layer 30. The opening 34 of the third-2 mold 31 may be provided to be located above the connection part 22, the horizontal slit 120b, and a portion of the second contact tip 132 of the second body layer 20. Thus, the third body layer 30 may be formed above the connection part 22, the horizontal slit 120b, and a portion of the second contact tip 132.

The process of providing the third metal 32 may comprise a plating process for the third metal 32 and a CMP process. The third metal 32 may be formed by plating in the opening 34 of the third-2 mold 31. The plating material may be the same as or different from the aforementioned first metal 12 and/or second metal 22, but is not limited thereto. Subsequently, the third metal 32 may be planarized through chemical mechanical polishing.

The process of removing the third-2 mold 31 may be performed by forming the second contact tip 132 and the third metal 32 and removing the remaining PR left on the sides of the second contact tip 132 and the third metal 32. Thus, the third body layer 30 may be formed. At this time, the third body layer 30 may include the vertical slit 120a.

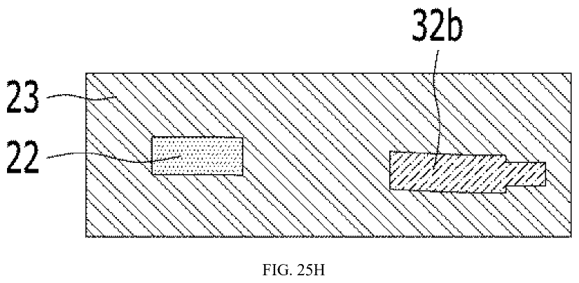

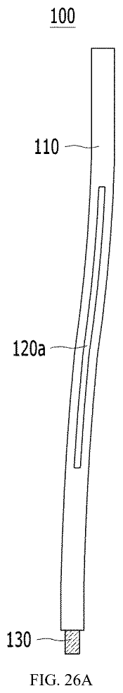

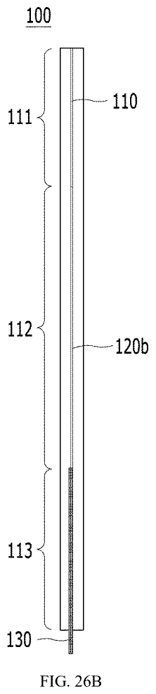

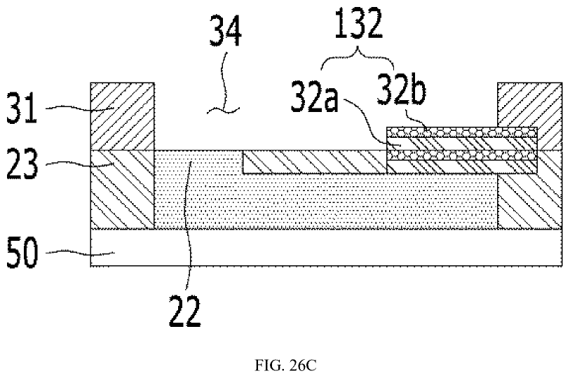

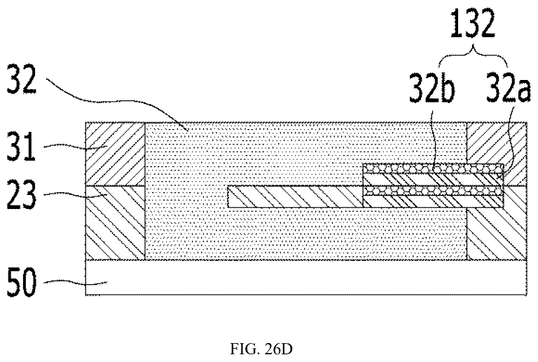

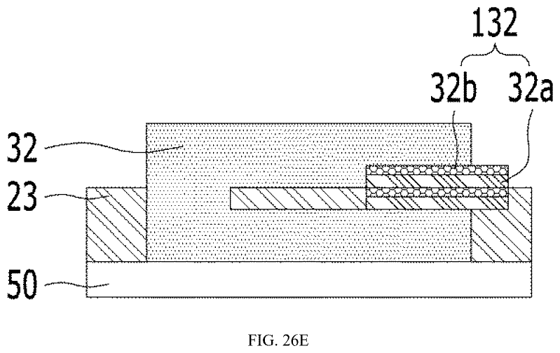

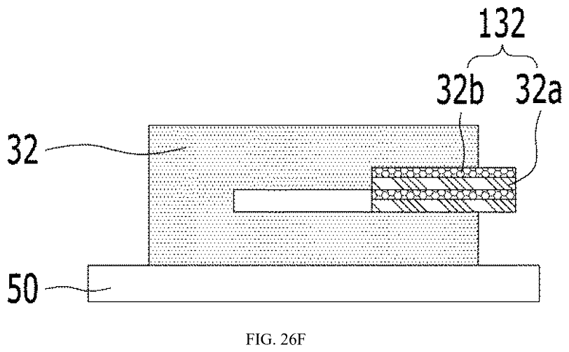

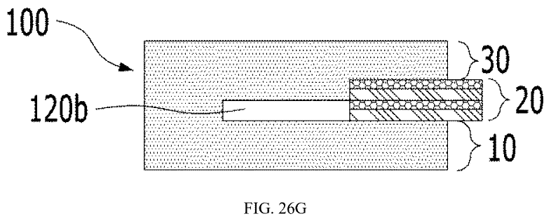

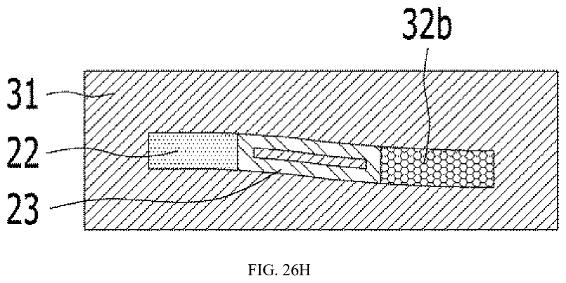

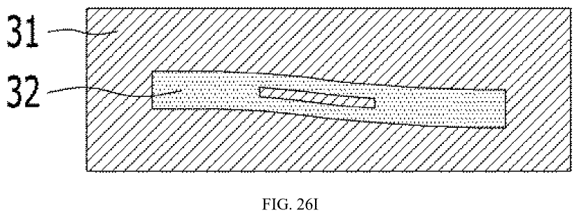

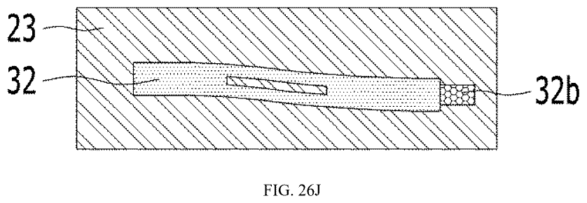

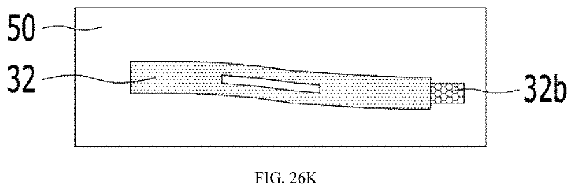

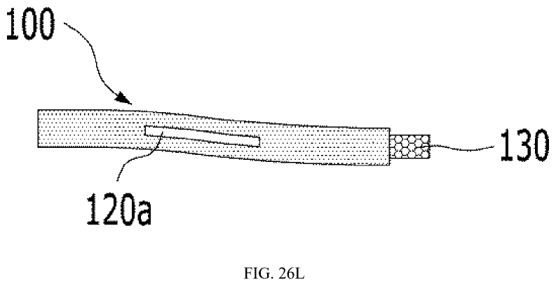

Referring to FIGS. 26f to 26g and FIGS. 26k to 26l, the process of separating the first body layer 10 to the third body layer 30 may comprise the process of removing the sacrificial layer and the process of removing the base substrate 50. The process of separating the first body layer 10 to the third body layer 30 is the same as described above, and thus, the description will be omitted.

The probe pin 100 in the above-described embodiment may include the horizontal slit 120b in the second body layer 20 and the vertical slit 120a formed across the first body layer 10, the second body layer 20, and the third body layer 30.

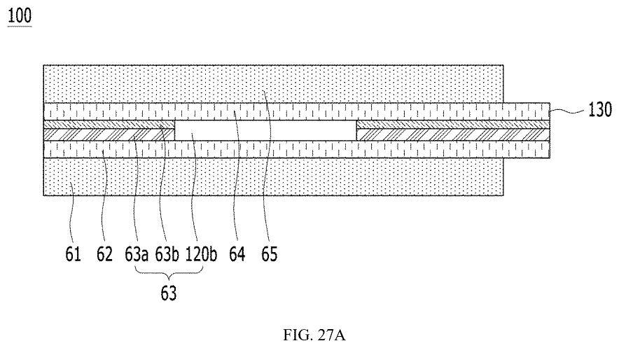

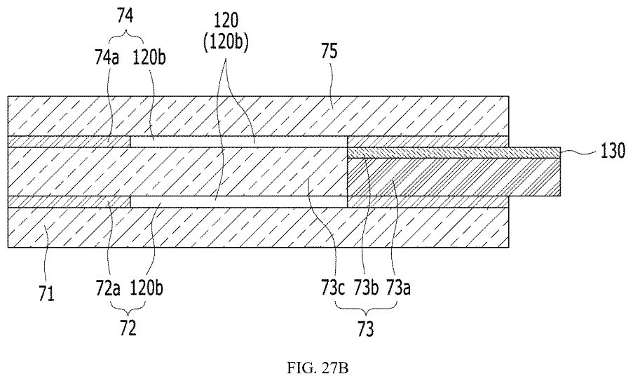

FIGS. 27a and 27b are diagrams illustrating the probe pin 100 according to the embodiment of the present invention.

Referring to FIG. 27a, the probe pin 100 according to an embodiment of the present invention may comprise a body, a vertical slit 120a, a horizontal slit 120b, and a contact tip 130. In another aspect, the probe pin 100 may comprise a first body layer 61 at the bottom, a second body layer 62 provided on the first body layer 61, a third body layer 63 provided on the second body layer 62, a fourth body layer 64 provided on the third body layer 63, and a fifth body layer 65 provided on the fourth body layer 64. At this time, the third body layer 30 may comprise a third-1 body layer 63a forming the lower part and a third-2 body layer 63b forming the upper part. Here, the lower part refers to the left side based on FIG. 27a, and the upper part refers to the right side based on FIG. 27a.

The first body layer 61 and the fifth body layer 65 may be made of the same material, but are not necessarily limited thereto. The second body layer 62 and the fourth body layer 64 may be made of the same material, but are not necessarily limited thereto. At this time, the first body layer 61 and the second body layer 62 may be made of different materials, but are not necessarily limited thereto. Furthermore, the body 110 is not necessarily composed of the first body layer 61 to the fifth body layer 65 and may be composed of more or fewer layers. The third-1 body layer 63a and the third-2 body layer 63b may be made of different materials, but are not necessarily limited thereto. Additionally, the first body layer 61 and the fifth body layer 65 may be formed thicker than the other layers.

The second body layer 62 may extend beyond the first body layer 61 to form a first contact tip, the third body layer 63 may extend beyond the first body layer 61 to form a second contact tip, and the fourth body layer 64 may extend beyond the first body layer 61 to form a third contact tip. Furthermore, the second body layer 62, the third body layer 63, and the fourth body layer 64 may be of the same length, forming an integrally formed contact tip 130 comprising the first contact tip, the second contact tip, and the third contact tip.

The third body layer 63 may comprise a horizontal slit 120b. The third body layer 63 may comprise a connection part 22, 63a, 63b in the first body 111 region, a horizontal slit 120b in the second body 112 region, and a contact tip 130 in the third body 113 region.

The second contact tip may comprise a second-1 contact tip forming the lower part and a second-2 contact tip forming the upper part. The second-1 contact tip may be made of a rhodium layer 63a, and the second-2 contact tip may be made of a metal layer 63b with a lower hardness than rhodium. This structure facilitates the manufacturing of the contact tip 130 comprising the rhodium layer 63a by polishing the second-2 contact tip in the probe pin 100 manufacturing method.

Additionally, the contact tip 130 may be configured as part of the third body layer 63 comprising the rhodium layer and the horizontal slit 120b, and parts of the second body layer 62 and the fourth body layer 64, thereby increasing the thickness of the contact tip 130. That is, the thickness of the contact tip 130 can be increased while reducing the width of the horizontal slit 120b. As a result, the contact tip 130 can distribute the force applied to the semiconductor device in an overdrive state, preventing damage to the semiconductor device and increasing the strength of the contact tip 130.

Referring to FIG. 27b, the probe pin 100 according to an embodiment of the present invention may comprise a first body layer 710 at the bottom, a second body layer 72 provided on the first body layer 71, a third body layer 73 provided on the second body layer 72, a fourth body layer 74 provided on the third body layer 73, and a fifth body layer 75 provided on the fourth body layer 74. At this time, the second body layer 72 may comprise a first connection part 72a and a first horizontal slit 120b, and the fourth body layer 74 may comprise a second connection part 74a and a second horizontal slit 120b. Here, the lower part refers to the left side based on FIG. 27b, and the upper part refers to the right side based on FIG. 27b.

The first body layer 71, the third body layer 73, and the fifth body layer 75 may be made of the same material, but are not necessarily limited thereto. The second body layer 72 and the fourth body layer 74 may be made of the same material, but are not necessarily limited thereto. Furthermore, as described above, the body 110 is not necessarily composed of the first body layer 71 to the fifth body layer 75.

Here, the first body layer 71 and the fifth body layer 75 may be formed thinner than the third body layer 73.

The third body layer 73 may extend beyond the second body layer 72 to form the contact tip 130. Here, the third body layer 73 may comprise a first contact tip in the lower part of the third body 113 region and a second contact tip in the upper part of the third body 113 region. The first contact tip may be a rhodium layer, and the second contact tip may be composed of the first contact tip or a metal layer with a lower hardness than rhodium.

The horizontal slit 120b and the contact tip 130 may be located at different heights or on different layers, thereby not forming an overlapping region.

Forming the second contact tip with a lower hardness than the first contact tip on the first contact tip has the same effect as described above. Since an excessively large width of the horizontal slit 120b may prevent maintaining the strength of the probe pin 100, this structure allows securing the thickness of the contact tip 130 without significantly increasing the width of the horizontal slit 120b.

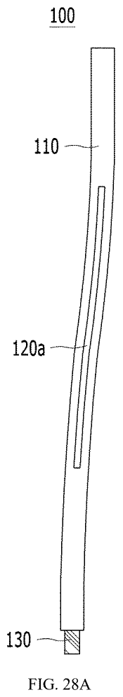

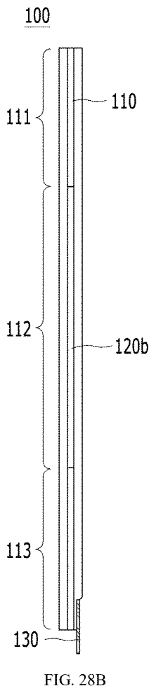

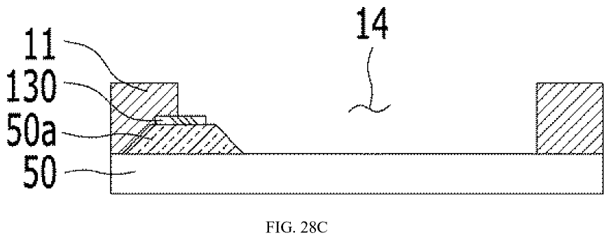

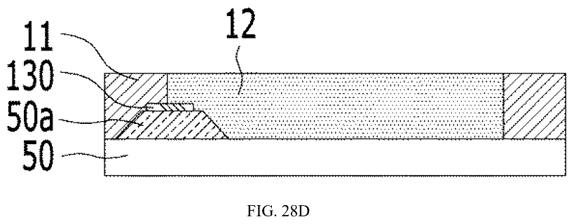

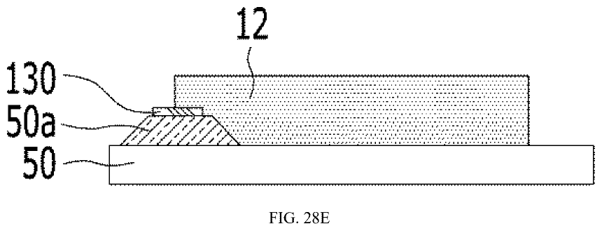

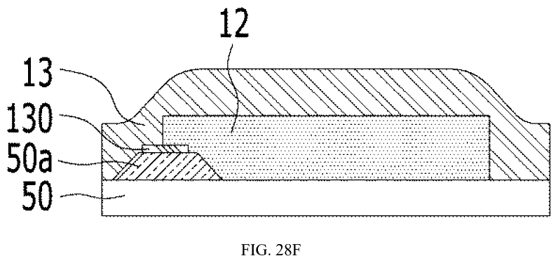

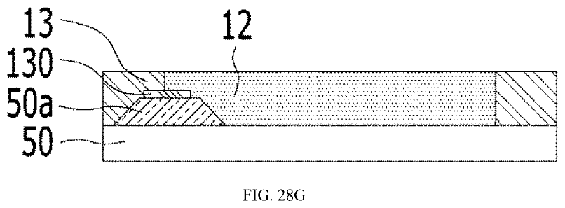

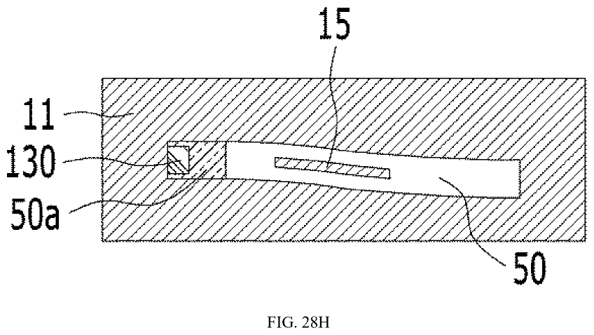

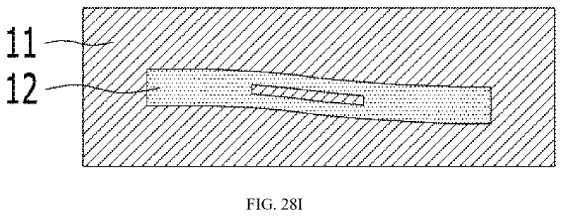

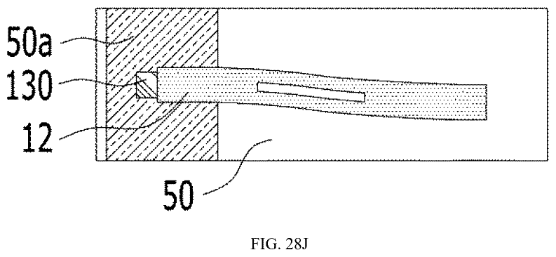

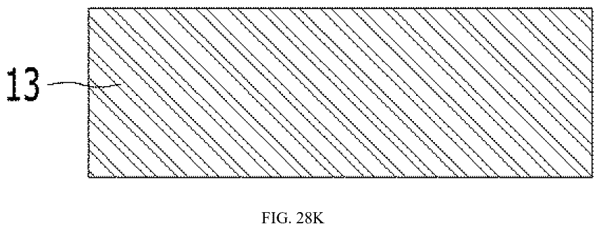

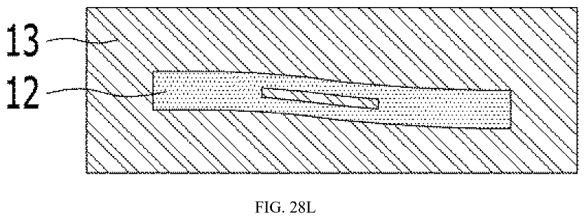

FIGS. 28a to 30l illustrate the manufacturing method of the probe pin 100 according to an embodiment of the present invention.

Referring to FIGS. 28a and 28b, the probe pin 100 according to an embodiment of the present invention may comprise a body 110 and a slit 120. The body 110 may comprise a first body 111 to a third body 113, and the slit 120 may comprise a vertical slit 120a and a horizontal slit 120b. The probe pin 100 may further comprise a contact tip 130 located in the end region of the third body 113. Furthermore, the contact tip 130 may be made of a material different from the body 110. In another aspect, the probe pin 100 may comprise a first body layer 10, a second body layer 20, and a third body layer 30. The second body layer 20 may comprise a horizontal slit 120b. At this time, the contact tip 130 may be provided on the first body layer 10. That is, the contact tip 130 may be maintained closer to the lower surface or the upper surface rather than the middle height of the body 110.

Referring to FIGS. 28c to 28l, FIGS. 29c to 29l, and FIGS. 30c to 30l, the manufacturing method of the probe pin 100 according to an embodiment of the present invention may comprise the steps of preparing a base substrate 50 comprising a hill part 50a on the upper surface; providing a contact tip 130 on the hill part 50a; providing a body 110 on at least a part of the contact tip 130 and the base substrate 50; and separating the body 110. Here, the step of providing the body 110 may comprise providing a first body layer 10 on at least a part of the contact tip 130 and the base substrate 50, providing a second body layer 20 on the first body layer 10, and providing a third body layer 30 on the second body layer 20.

First, the step of preparing a base substrate 50 comprising a hill part 50a on the upper surface is performed, and the step of providing a contact tip 130 on the hill part 50a may be performed.

In the step of preparing a base substrate 50 comprising a hill part 50a, the base substrate 50 may comprise the hill part 50a. The base substrate 50 may be integrally formed with the hill part 50a. In the base substrate 50, the hill part 50a and the region excluding the hill part 50a may be made of the same or different materials. The hill part 50a may be formed such that the cross-sectional area narrows toward the top, but is not necessarily limited thereto.

In the step of providing a contact tip 130 on the hill part 50a, the contact tip 130 may be provided on the hill part 50a. The contact tip 130 may be separately manufactured and provided on the hill part 50a or may be provided on the hill part 50a through plating. At this time, a mold (not shown) may first be provided except for a part of the upper surface of the hill part 50a for plating.

The contact tip 130 may be formed first by providing the hill part 50a on the base substrate 50. The process of polishing the contact tip 130 may be omitted by providing a first mold 11 and a first metal 12 on the first-formed contact tip 130 and polishing the first metal 12. Particularly, when the contact tip 130 is made of a material with high hardness, polishing is difficult and prone to breakage, thus having the advantage of omitting the polishing process of the contact tip 130. Specifically, the contact tip 130 may comprise rhodium, and in this case, the process of polishing rhodium may be omitted.

Referring to FIGS. 28c to 28e and FIGS. 28h to 28j, the step of providing the first body layer 10 may comprise the steps of providing a first mold 11, providing a first metal 12, and removing the first mold 11.

The process of providing the first mold 11 may be performed through the steps of providing a PR layer, exposure, and development. Here, the first mold 11 may include an opening 14 corresponding to the first body layer 10. The first mold 11 may be provided on a part of the hill portion 50a and a part of the contact tip 130. Accordingly, the opening 14 of the first mold 11 may be provided on the remaining part of the hill portion 50a and the remaining part of the contact tip 130. The first mold 11 may be an area for forming the first body layer 10.

The process of providing the first metal 12 may include a plating process of the first metal 12 and may further include a CMP process. The first metal 12 may be formed by plating in the opening 14 of the first mold 11. Subsequently, the first metal 12 may be planarized through chemical mechanical polishing.

The process of removing the first mold 11 may be performed by forming the hill portion 50a, the contact tip 130, and the first body layer 10, and removing the residual PR remaining on the sides of the first body layer 10, the contact tip 130, and the hill portion 50a. As a result, the first body layer 10 may be formed.

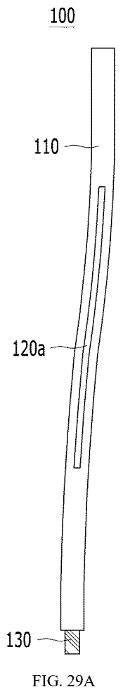

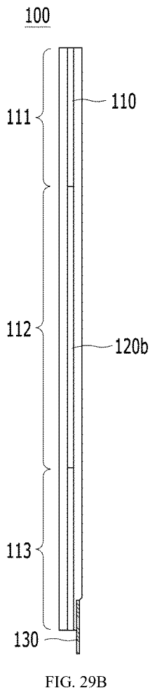

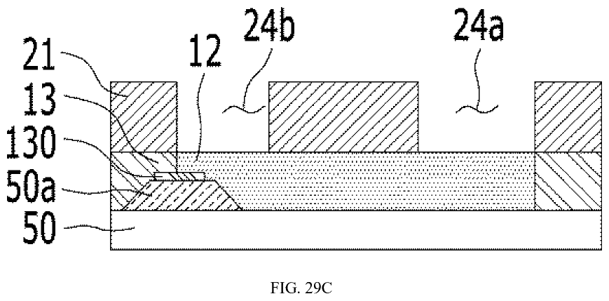

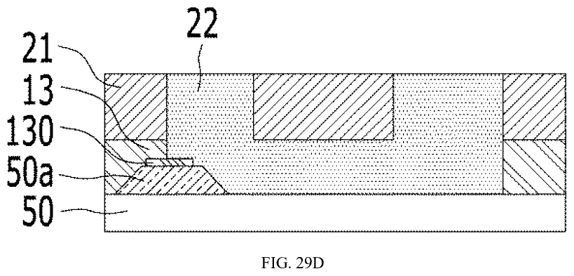

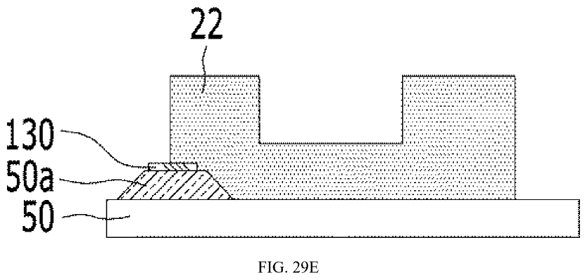

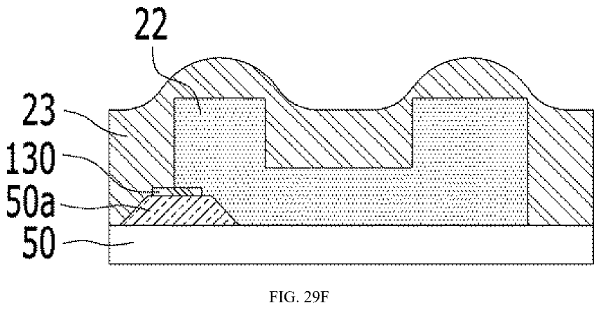

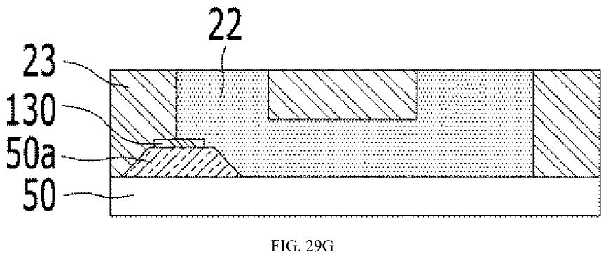

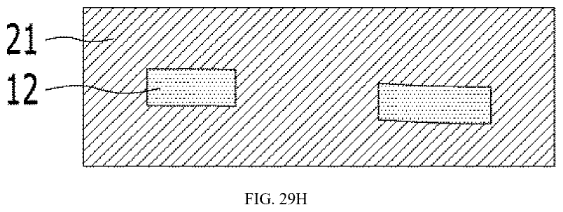

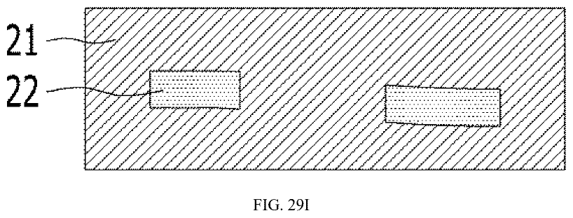

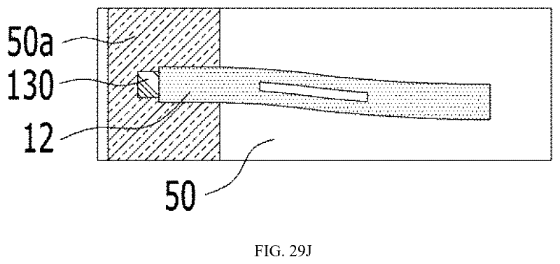

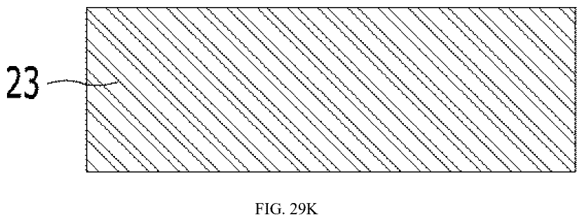

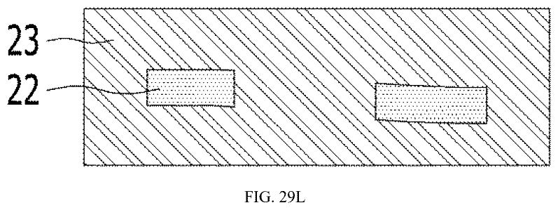

Referring to FIGS. 28f to 28g, 28k to 28l, 29c to 29e, and 29h to 29j, the process of providing the second body layer 20 may include the process of providing the first sacrificial layer 13, the process of providing the second mold 21, the process of providing the second metal 22, and the process of removing the second mold 21.

The process of providing the first sacrificial layer 13 may include a plating process of the first sacrificial layer 13 and a CMP process. The first sacrificial layer 13 may be provided to form the second mold 21 on its upper part. The first sacrificial layer 13 may be formed by plating to cover the sides and the upper part of the first body layer 10, the contact tip 130, and the hill portion 50a. The first sacrificial layer 13 may be formed with a portion protruding as shown in FIG. 28f. Subsequently, the first sacrificial layer 13 and/or the first body layer 10 may be planarized through chemical mechanical polishing.

The processes of providing the second mold 21, providing the second metal 22, and removing the second mold 21 are the same as described above, so the description will be omitted.

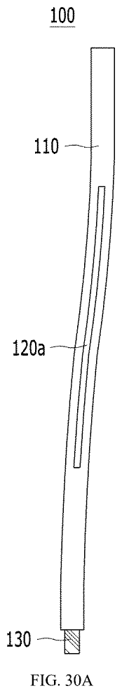

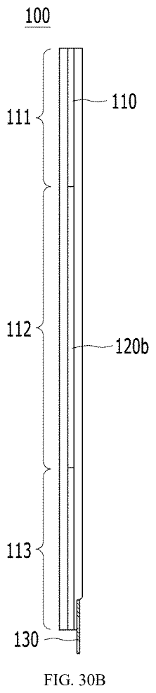

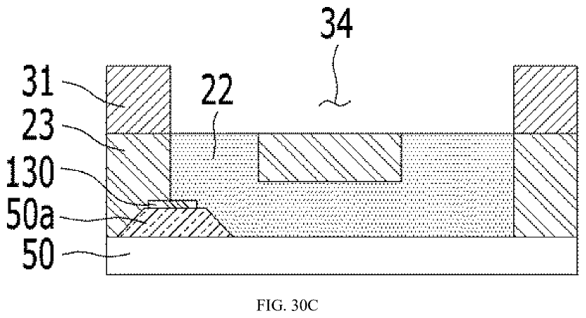

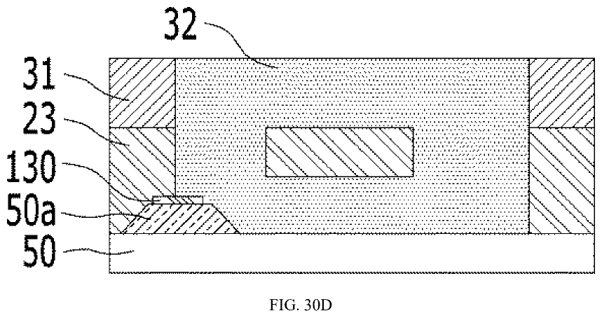

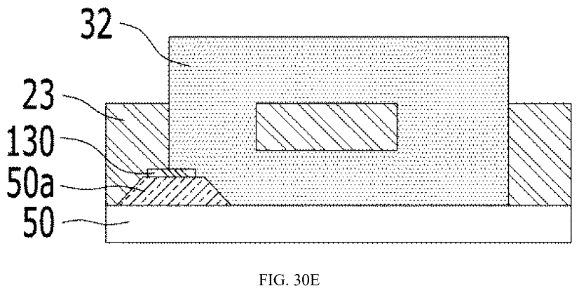

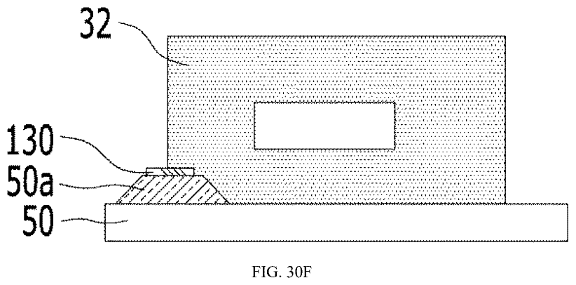

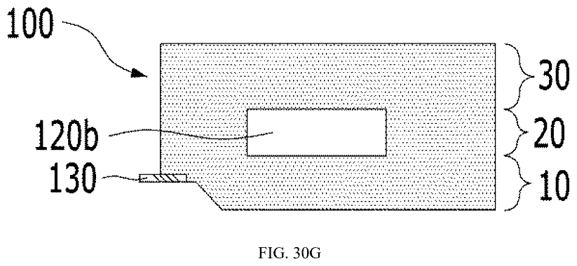

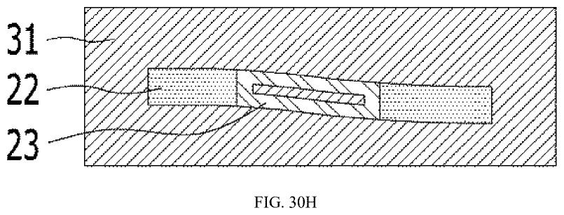

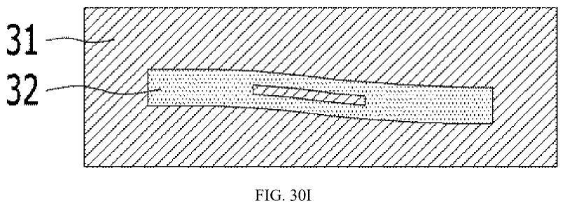

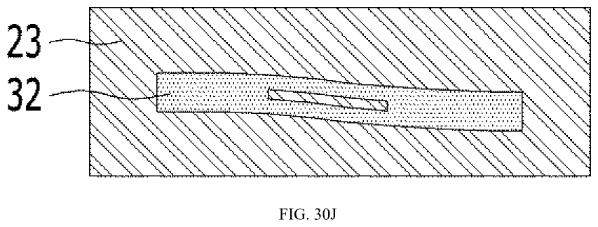

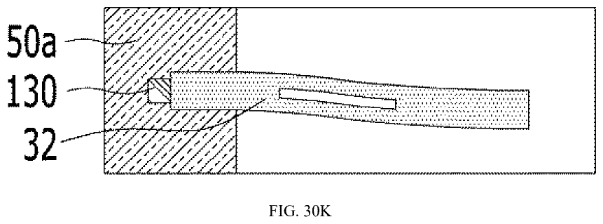

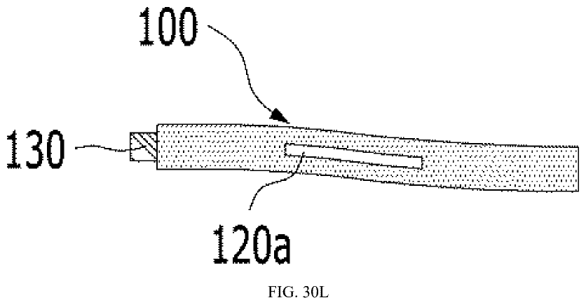

Referring to FIGS. 29f to 29g, 29k to 29l, 30c to 30e, and 30h to 30j, the process of providing the third body layer 30 may include the process of providing the second sacrificial layer 23, the process of providing the third mold 31, the process of providing the third metal 32, and the process of removing the third mold 31.

The process of providing the second sacrificial layer 23 may include a plating process of the second sacrificial layer 23 and a CMP process. The second sacrificial layer 23 may be provided to form the third mold 31 on its upper part. The second sacrificial layer 23 may be formed by plating to cover the sides and the upper part of the second body layer 20. The second sacrificial layer 23 may be formed with a portion protruding as shown in FIG. 29f. Subsequently, the second sacrificial layer 23 and/or the second body layer 20 may be planarized through chemical mechanical polishing. However, before the process of providing the second sacrificial layer 23, the process of removing the first sacrificial layer 13 may be performed.

The processes of providing the third mold 31, providing the third metal 32, and removing the third mold 31 are the same as described above, so the description will be omitted.

Meanwhile, the probe pin manufacturing method according to the above-described embodiment may further include the process of coating the entire surface of the separated probe pin 100 with a metallic material and the process of coating a part of the surface of the probe pin 100 with an insulating material.

Next, the insulating layer 118 provided on the separated body and the ground pin GP will be described.

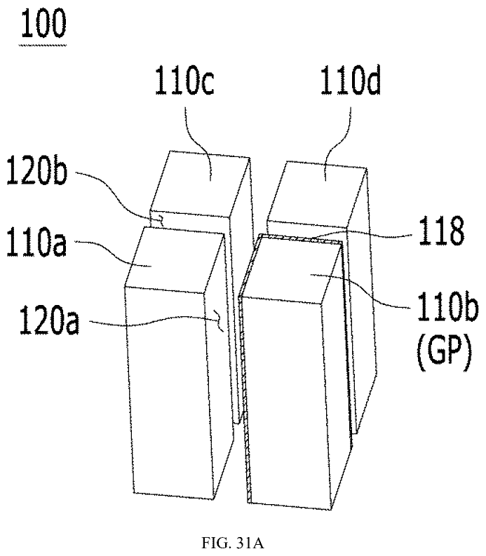

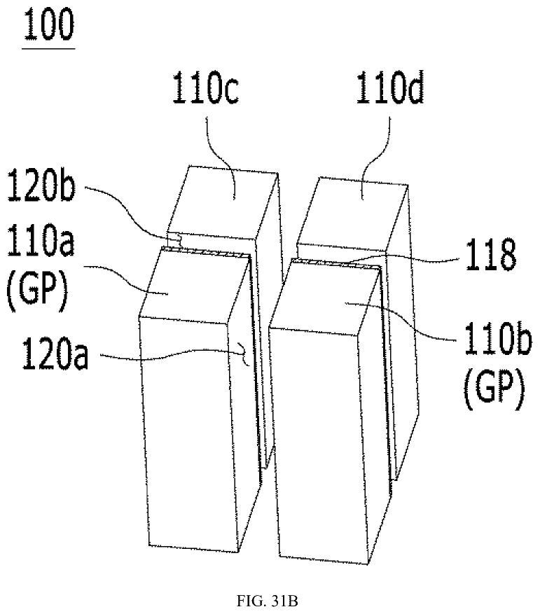

FIGS. 31a to 31d are diagrams showing the insulating layer 118 of the separated body according to an embodiment of the present invention.

Referring to FIG. 31a, the body 110 may include the first separated body 110a to the fourth separated body 110d. The first separated body 110a to the fourth separated body 110d may each include two outer surfaces forming the exterior of the body 110 and two inner surfaces forming the interior of the body 110.

The second separated body 110b may include the insulating layer 118 on at least one inner surface. That is, the second separated body 110b may include the insulating layer 118 on one or both inner surfaces. However, the insulating layer 118 is not limited to being provided on the second separated body 110b. Unlike FIG. 31a, the insulating layer 118 may be provided on at least one of the first separated body 110a to the fourth separated body 110d.

Referring to FIG. 31b, the first separated body 110a and the second separated body 110b may each include the insulating layer 118 on their inner surfaces. Specifically, the insulating layer 118 may be provided on the inner surface of the first separated body 110a facing the third separated body 110c, and the insulating layer 118 may be provided on the inner surface of the second separated body 110b facing the fourth separated body 110d. Unlike FIG. 31b, the insulating layer 118 may be provided on at least one of the first separated body 110a to the fourth separated body 110d. Additionally, unlike FIG. 31b, the insulating layer 118 may be integrally formed.

Referring to FIG. 31c, the first separated body 110a may include the insulating layer 118 on the inner surface facing the third separated body 110c and on the two outer surfaces, and the second separated body 110b may include the insulating layer 118 on the inner surface facing the fourth separated body 110d and on the two outer surfaces, and the insulating layers 118 may be connected to each other and integrally formed. Unlike FIG. 31c, the insulating layer 118 may be provided on at least two of the first separated body 110a to the fourth separated body 110d.

Referring to FIG. 31d, the second separated body 110b may include the insulating layer 118 on the two inner surfaces and the two outer surfaces. Unlike FIG. 31d, at least one of the first separated body 110a to the fourth separated body 110d may include the insulating layer 118 on all surfaces.

The separated body including the insulating layer 118 among the first separated body 110a to the fourth separated body 110d may be utilized as the ground pin GP. By configuring the probe pin 100 with the body 110 as a plurality of separated bodies rather than as an integral body, the skin effect can be reduced, thereby increasing the current-carrying capacity. Additionally, by utilizing some of the separated bodies as ground pins GP, the skin effect can be reduced even for high-frequency signals, thereby increasing the current-carrying capacity.

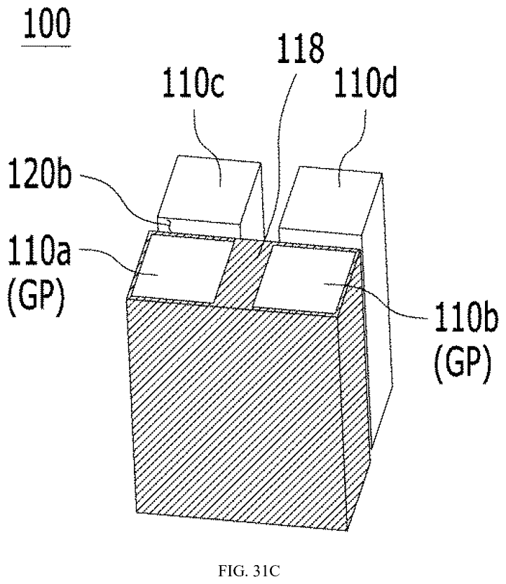

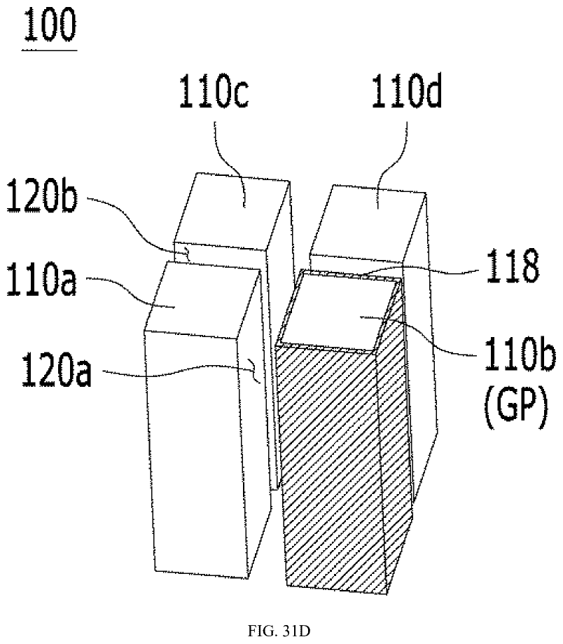

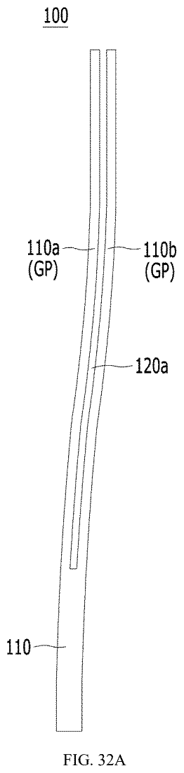

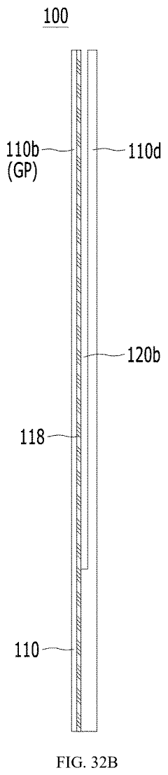

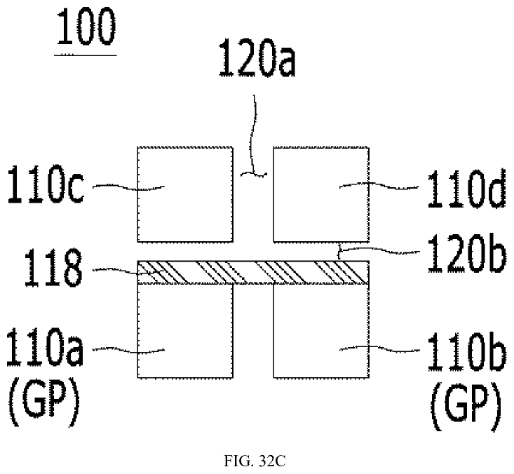

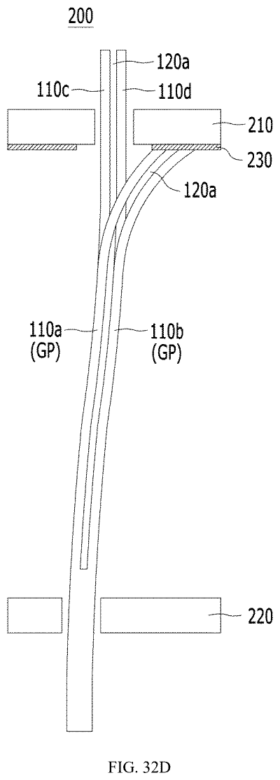

FIGS. 32a and 32b are front and side views of the probe pin 100 including the insulating layer 118 according to an embodiment of the present invention. FIG. 32c is a diagram showing the end of the first body 111 according to an embodiment of the present invention. FIG. 32d is a diagram showing the connection state of the contact tip 130 and the ground wiring 230 according to an embodiment of the present invention.

Referring to FIGS. 32a to 32c, the ground pin GP according to an embodiment of the present invention may include the first separated body 110a and the second separated body 110b. The first separated body 110a may include the insulating layer 118 on the inner surface facing the third separated body 110c, and the second separated body 110b may include the insulating layer 118 on the inner surface facing the fourth separated body 110d, and the insulating layers 118 may be integrally provided.

In an embodiment where the third body 113 does not include a slit 120, the third body 113 does not include a separated body, so the insulating layer 118 may be formed on the inner surfaces of the first separated body 110a and the second separated body 110b and may extend to the end surface of the third body 113. That is, the third body 113 may include the insulating layer 188 in the middle. This may be adopted for the separated body including the insulating layer 188 described later. As a result, the first separated body 110a and the second separated body 110b may be utilized as ground pins GP. As a result, the first separated body 110a and the second separated body 110b may be electrically insulated from the third separated body 110c and the fourth separated body 110d.

Referring to FIG. 32d, the probe card 200 according to an embodiment of the present invention may include the upper plate 210 having the upper hole 211, the lower plate 220 having the lower hole 221, and the probe pin 100. At this time, the probe pin 100 may include the body 110, the vertical slit 120a, and the horizontal slit 120b, and may include the first separated body 110a to the fourth separated body 110d partitioned by the vertical slit 120a and the horizontal slit 120b. At this time, the first separated body 110a and the second separated body 110b may include the insulating layer 118 and may be utilized as ground pins GP.

The upper plate 210 may include the ground wiring 230 on the upper or lower part. At this time, the first separated body 110a and the second separated body 110b may be formed to be bent and connected to the ground wiring 230.

The probe card 200 of this embodiment includes the probe pin 100 spaced apart into a plurality of separated bodies and connects the separated body including the insulating layer 118 to the ground wiring 230, thereby reducing the cross-sectional area of the body 110 to reduce the skin effect and increasing the current-carrying capacity even for high-frequency signals.

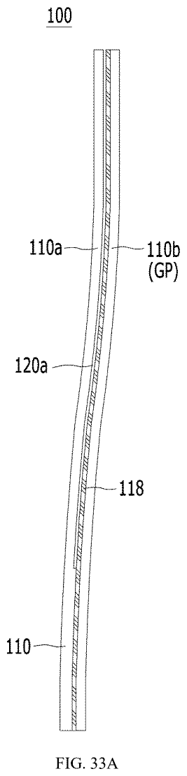

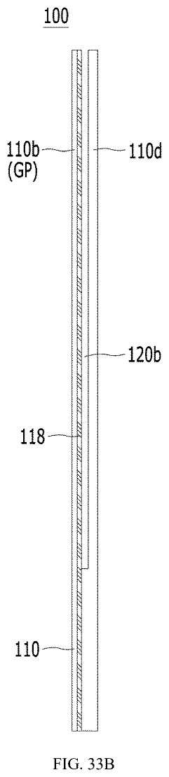

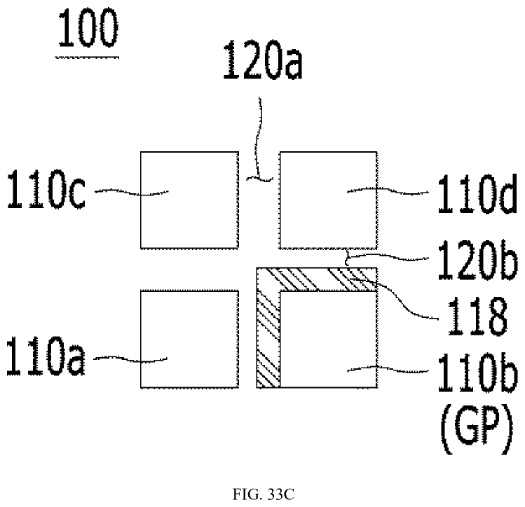

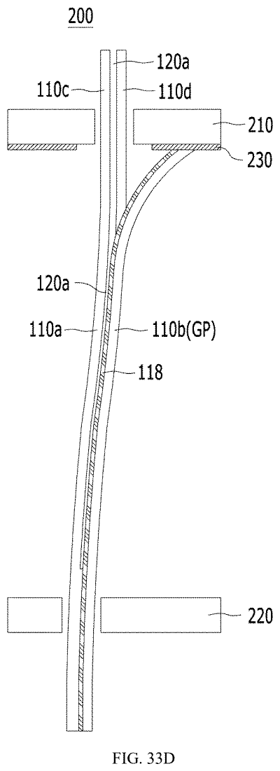

FIGS. 33a and 33b are diagrams showing the front and side views of a probe pin 100 comprising an insulating layer 118 according to an embodiment of the present invention. FIG. 33c is a diagram showing the end portion of a first body 111 according to an embodiment of the present invention. FIG. 33d is a diagram showing the connection state of a contact tip 130 and a ground wiring 230 according to an embodiment of the present invention.

Referring to FIGS. 33a to 33c, a ground pin GP according to an embodiment of the present invention may comprise a first separated body 110a and a fourth separated body 110d. The second separated body 110b may comprise an insulating layer 118 on two inner surfaces facing the first separated body 110a and the fourth separated body 110d, and the insulating layer 118 may be integrally provided.

The insulating layer 118 may be formed on the inner surface of the second separated body 110b and may extend to the end surface of the third body 113. Thus, the second separated body 110b may be utilized as a ground pin GP.

Referring to FIG. 33d, a probe card 200 according to an embodiment of the present invention may comprise an upper plate 210 comprising an upper hole 211, a lower plate 220 comprising a lower hole 221, and a probe pin 100. At this time, the probe pin 100 may comprise a body 110, a vertical slit 120a, and a horizontal slit 120b, and may comprise a first separated body 110a to a fourth separated body 110d partitioned by the vertical slit 120a and the horizontal slit 120b. At this time, the second separated body 110b may comprise an insulating layer 118 and may be utilized as a ground pin GP. Furthermore, at least one of the first separated body 110a to the fourth separated body 110d may comprise an insulating layer 118 and may be utilized as a ground pin GP.

The upper plate 210 may comprise a ground wiring 230 on the upper or lower side. At this time, the first separated body 110a and the second separated body 110b may be formed in a bent shape and may be connected to the ground wiring 230.

The probe card 200 of this embodiment comprises a probe pin 100 separated into multiple separated bodies, and by connecting the separated body comprising the insulating layer 118 to the ground wiring 230, the cross-sectional area of the body 110 can be reduced to decrease the skin effect, and the current carrying capacity can be increased even for high-frequency signals.

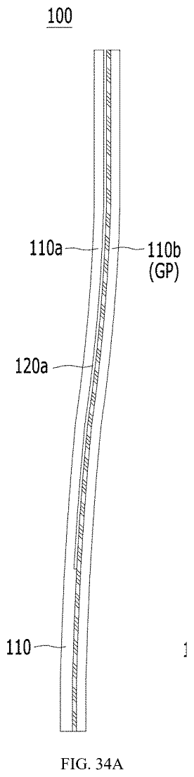

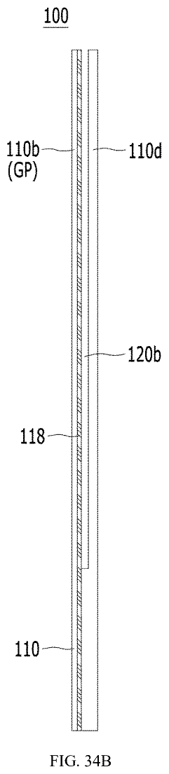

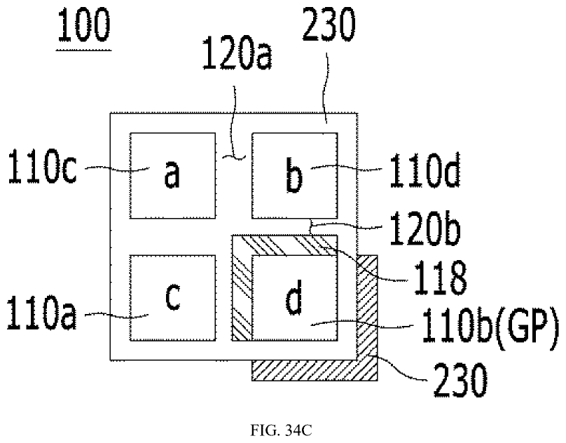

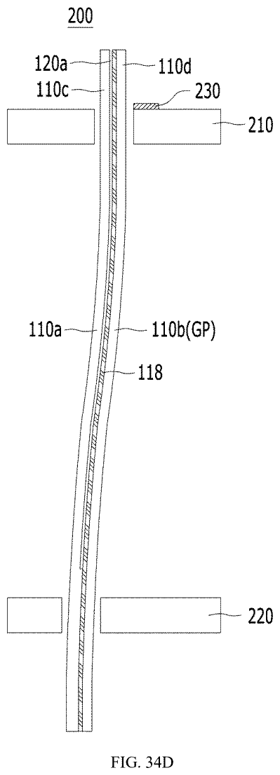

FIGS. 34a and 34b are diagrams showing the front and side views of a probe pin 100 comprising an insulating layer 118 according to an embodiment of the present invention. FIG. 34c is a diagram showing the end portion of a first body 111 and the ground wiring 230 according to an embodiment of the present invention. FIG. 34d is a diagram showing the positional state of a ground pin GP and the ground wiring 230 according to an embodiment of the present invention.

In this embodiment, the probe pin 100 is the same as shown in FIGS. 33a to 33d. Furthermore, in this embodiment, the probe card 200 comprises an upper plate 210 comprising a ground wiring 230 on the upper side. Alternatively, the ground wiring 230 may be provided on the lower side of the upper plate 210.

The ground wiring 230 may be provided to extend to the upper hole 211 of the upper plate 210. At this time, the ground wiring 230 may be formed along the two outer surfaces of the second separated body 110b. Additionally, the ground wiring 230 may be provided to extend to the inner surface of the upper hole 211 of the upper plate 210. At this time, the ground wiring 230 may be formed along the two outer surfaces of the second separated body 110b. The probe pin 100 may be connected to the ground wiring 230 in an overdrive state.

Meanwhile, the separated body comprising the insulating layer 118 may have a shorter length than other separated bodies. That is, the ground pin GP may be formed to have a shorter length than other pins.

This configuration allows the second separated body 110b utilized as a ground pin GP to be connected to the ground wiring 230 through elastic deformation in an overdrive state, even without forming the second separated body 110b in a bent shape.

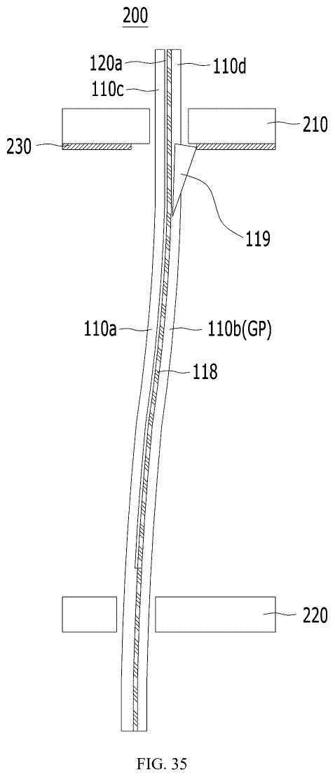

FIG. 35 is a diagram showing a probe pin 100 comprising a protrusion 119 according to an embodiment of the present invention.

Referring to FIG. 35, the probe pin 100 in this embodiment is the same as shown in FIGS. 33a to 33d. Furthermore, in this embodiment, the probe card 200 comprises an upper plate 210 comprising a ground wiring 230 on the lower side. At this time, the second separated body 110b may comprise a protrusion 119 and may be connected to the ground wiring 230. This configuration allows the second separated body 110b utilized as a ground pin GP to be connected to the ground wiring 230 through elastic deformation in a normal or overdrive state, even without forming the second separated body 110b in a bent shape.

As described above, although the preferred embodiments of the present invention have been described with reference to the accompanying drawings, those skilled in the art may variously modify or change the present invention without departing from the spirit and scope of the invention as set forth in the following claims.

### DESCRIPTION OF THE REFERENCE NUMERALS IN THE DRAWINGS

10: First body layer
11: First mold
12: First metal
13: First sacrificial layer
20: Second body layer
21: Second mold
22: Second metal
23: Second sacrificial layer
30: Third body layer
31: Third mold
32: Third metal
50: Base substrate
50a: Hill portion
100: Probe pin
110: Body
110a: First separated body
110b: Second separated body
110c: Third separated body
110d: Fourth separated body
110e: Fifth separated body
110f: Sixth separated body
110g: Seventh separated body
110h: Eighth separated body
111: First body
112: Second body
113: Third body
116: Over-spaced portion
117: Tie portion
117a: Recessed portion
118: Insulating layer
119: Protrusion
120: Slit
120a: Vertical slit
120b: Horizontal slit
130: Contact tip
200: Probe card
210: Upper plate
211: Upper hole
220: Lower plate
221: Lower hole
230: Ground wiring
GP: Ground pin

1. A probe pin comprising:
a body extending in one direction; and
a slit formed through a portion of the body, wherein the body includes:
a first body constituting one side of the body;
a second body extending from the first body and constituting a middle portion of the body; and
a third body extending from the second body and constituting the other side of the body, wherein the slit includes:
a vertical slit formed in a vertical direction through a horizontal plane of the body; and
a horizontal slit formed in a horizontal direction through a vertical plane of the body.

2. The probe pin of claim 1, wherein at least one of the vertical slit and the horizontal slit is formed in the second body.

3. The probe pin of claim 1, wherein at least one of the vertical slit and the horizontal slit extends from the second body to an end of the first body, opening one side of the first body.

4. The probe pin of claim 1, wherein the vertical slit and the horizontal slit intersect each other.

5. The probe pin of claim 1, wherein the body includes a first separated body, a second separated body, a third separated body, and a fourth separated body spaced apart from each other by the vertical slit and the horizontal slit,
at least one of the first separated body to the fourth separated body include an over-spaced portion curved in a direction in which a separation distance from at least one of the others excluding the at least one increases, and
the over-spaced portion contacts an upper plate into which the body is inserted to prevent separation of the body.

6. The probe pin of claim 1, wherein the body includes a first separated body, a second separated body, a third separated body, and a fourth separated body separated from each other by the vertical slit and the horizontal slit,
further comprising:
a tie portion connecting an inner surface of the first separated body and an inner surface of at least one of the second to fourth separated bodies; and
a recessed portion recessed in at least one of an outer surface facing the inner surface of the first separated body to which the tie portion is connected and an outer surface facing the inner surface of the at least one.

7. The probe pin of claim 1, wherein at least one of the vertical slit and the horizontal slit is provided in plural.

8. The probe pin of claim 1, wherein the vertical slit and the horizontal slit have different widths or lengths.

9. The probe pin of claim 1, further comprising a contact tip located in an end region of the third body and contacting an object to be inspected.

10. The probe pin of claim 9, wherein the contact tip is made of a different material from the body.

11. The probe pin of claim 9, wherein the contact tip includes a rhodium layer composed of a material containing rhodium.

12. The probe pin of claim 11, wherein the contact tip further includes a protective layer located on the rhodium layer and composed of a material having a lower hardness than the rhodium.

13. The probe pin of claim 9, wherein a thickness of the contact tip is greater than a thickness of the horizontal slit.

14. The probe pin of claim 9, wherein the horizontal slit and the contact tip are located at different heights so as not to form an overlapping region.

15. The probe pin of claim 1, wherein the body includes a first separated body, a second separated body, a third separated body, and a fourth separated body separated from each other by the vertical slit and the horizontal slit,
further comprising an insulating layer formed such that at least one of the first to fourth separated bodies is insulated from the others excluding the at least one,
wherein the insulating layer is formed on an inner surface of the at least one facing the others and extends from the first body to the third body.

16. The probe pin of claim 15, wherein the at least one of the first to fourth separated bodies is curved or has a protrusion to be connected to a ground line as a ground pin.

17. A probe pin comprising:
a body extending in one direction;
a vertical slit formed in a vertical direction through a horizontal plane of the body;
a horizontal slit formed in a horizontal direction through a vertical plane of the body; and
a contact tip formed on one side of the body.

18. The probe pin of claim 17, wherein the contact tip is formed at a height closer to a lower surface than an upper surface of the body.

19. A probe card comprising:
a probe pin including a body, a vertical slit formed in a vertical direction through a horizontal plane of the body, and a horizontal slit formed in a horizontal direction through a vertical plane of the body;
an upper plate having an upper hole through which the probe pin passes; and
a lower plate having a lower hole through which the probe pin passes,
wherein the body includes a first body located in the upper hole, a third body located in the lower hole, and a second body formed between the first body and the third body.

20. The probe card of claim 19, wherein the body includes a first separated body, a second separated body, a third separated body, and a fourth separated body separated from each other by the vertical slit and the horizontal slit,
at least one of the first to fourth separated bodies includes an over-spaced portion curved in a direction in which a separation distance from at least one of the others excluding the at least one increases, and
the over-spaced portion contacts the upper plate into which the body is inserted to prevent separation of the body.

21. The probe card of claim 19, wherein the body includes a first separated body, a second separated body, a third separated body, and a fourth separated body separated from each other by the vertical slit and the horizontal slit,
at least one of the first to fourth separated bodies further includes an insulating layer formed such that the at least one is insulated from the others excluding the at least one,
the insulating layer is formed on an inner surface of the at least one facing the others and extends from the first body to the third body, and
the upper plate includes a ground line on an upper surface or a lower surface, and
at least one of the first to fourth separated bodies is connected to the ground line.

22-30. (canceled)
